(19) United States
(12) Patent Application Publication
(10) Pub. No.: US 2022/0246501 A1
(43) Pub. Date: Aug. 4, 2022

(54) PACKAGE STRUCTURE

(71) Applicant: Integrated Silicon Solution Inc., Milpitas, CA (US)

(72) Inventors: Cheng-Fu YU, Milpitas, CA (US); Kai-Jih SHIH, Milpitas, CA (US); Chi-Yi WU, Milpitas, CA (US)

(21) Appl. No.: 17/723,536

(22) Filed: Apr. 19, 2022

Related U.S. Application Data
(63) Continuation-in-part of application No. 17/109,255, filed on Dec. 2, 2020.
(60) Provisional application No. 63/000,545, filed on Mar. 27, 2020.

(30) Foreign Application Priority Data
Sep. 3, 2020 (TW) 109130281
Jan. 3, 2022 (TW) 111100156

(51) Int. Cl. H01L 23/495; H01L 23/31

(52) U.S. Cl. CPC H01L 23/49503; H01L 23/49582; H01L 23/3107

(57) ABSTRACT

A package structure includes a leadframe, a semiconductor die and a plastic package material. The leadframe includes a die pad and a plurality of leads. The leads are disposed on four peripheral regions of the die pad, and each of the leads includes a main body, at least one extending portion and a plurality of plating surfaces. The extending portion is connected to the main body, and the main body and the extending portion are integrally formed. The plating surfaces are disposed on the main body and the extending portion. The semiconductor die is disposed on the die pad of the leadframe. The plastic package material is disposed on the leadframe. The main body and the extending portion of each of the leads protrude a peripheral region of the plastic package material.

### RELATED APPLICATIONS

This application is a continuation-in-part of the application Ser. No. 17/109,255, filed on Dec. 2, 2020, which claims priority to U.S. Provisional Application Ser. No. 63/000,545, filed Mar. 27, 2020, and Taiwan Application Serial Number 109130281, filed Sep. 3, 2020, and Taiwan Application Serial Number 111100156, filed Jan. 3, 2022, which are herein incorporated by reference.

### BACKGROUND

### Technical Field

The present disclosure relates to a package structure. More particularly, the present disclosure relates to a package structure which solderable areas can be increased.

### Description of Related Art

In recent years, a quad flat no leads (QFN) has less solderable area on sides of leads thereof. Hence, the QFN has the worse solderable effect when the QFN is disposed on a circuit board.

To solve the aforementioned problem, a structure of each of leads of a QFN being concave relative to a bottom thereof has been developed, so a solderable area of sides of the leads can be enhanced. However, an area of a bottom of the leads disposed on the circuit board is shrunken, and then the stability of the QFN disposed on the circuit board is worse to lower the lifetime of the QFN disposed on the circuit board. Therefore, a package, which the solderable area of leads can be enhanced and can be firmly disposed on the circuit board, needs to be developed.

### SUMMARY

According to one aspect of the present disclosure, a package structure includes a leadframe, a semiconductor die and a plastic package material. The leadframe includes a die pad and a plurality of leads. The leads are disposed on four peripheral regions of the die pad, and each of the leads includes a main body, at least one extending portion and a plurality of plating surfaces. The extending portion is connected to the main body, and the main body and the extending portion are integrally formed. The plating surfaces are disposed on the main body and the extending portion. The semiconductor die is disposed on the die pad of the leadframe. The plastic package material is disposed on the leadframe. The main body and the extending portion of each of the leads protrude a peripheral region of the plastic package material.

According to one aspect of the present disclosure, a package structure includes a leadframe, a semiconductor die and a plastic package material. The leadframe includes a die pad and a plurality of leads. The leads are disposed on four peripheral regions of the die pad, and each of the leads includes a main body, at least one extending portion and a plurality of plating surfaces. The extending portion is connected to the main body, and the main body and the extending portion are integrally formed. The plating surfaces are disposed on the main body and the extending portion. The semiconductor die is disposed on the die pad of the leadframe. The plastic package material is disposed on the leadframe. The main body of each of the leads is aligned to a peripheral region of the plastic package material, and the extending portion of each of the leads protrudes the peripheral region of the plastic package material.

### BRIEF DESCRIPTION OF THE DRAWINGS

FIG. 1 is a top view of a package structure according to the 1st embodiment of the present disclosure.

FIG. 2 is a bottom view of the package structure according to the 1st embodiment in FIG. 1.

FIG. 3 is a partial schematic view of the package structure according to the 1st embodiment in FIG. 1.

FIG. 4 is a side view of the package structure according to the 1st embodiment in FIG. 1.

FIG. 5 is a side view of the package structure after soldering according to the 1st embodiment in FIG. 1.

FIG. 6 is a partial side view of the package structure after soldering according to the 1st embodiment in FIG. 5.

FIG. 7 is a top view of a package structure according to the 2nd embodiment of the present disclosure.

FIG. 8 is a bottom view of the package structure according to the 2nd embodiment in FIG. 7.

FIG. 9 is a partial schematic view of the package structure according to the 2nd embodiment in FIG. 7.

FIG. 10 is a side view of the package structure according to the 2nd embodiment in FIG. 7.

FIG. 11 is a side view of the package structure after soldering according to the 2nd embodiment in FIG. 7.

FIG. 12 is a partial side view of the package structure after soldering according to the 2nd embodiment in FIG. 11.

FIG. 13 is a top view of a package structure according to the 3rd embodiment of the present disclosure.

FIG. 14 is a bottom view of the package structure according to the 3rd embodiment in FIG. 13.

FIG. 15 is a partial schematic view of the package structure according to the 3rd embodiment in FIG. 13.

FIG. 16 is a side view of the package structure according to the 3rd embodiment in FIG. 13.

FIG. 17 is a side view of the package structure after soldering according to the 3rd embodiment in FIG. 13.

FIG. 18 is a partial side view of the package structure after soldering according to the 3rd embodiment in FIG. 17.

FIG. 19 is a top view of a package structure according to the 4th embodiment of the present disclosure.

FIG. 20 is a bottom view of the package structure according to the 4th embodiment in FIG. 19.

FIG. 21 is a partial schematic view of the package structure according to the 4th embodiment in FIG. 19.

FIG. 22 is a side view of the package structure according to the 4th embodiment in FIG. 19.

FIG. 23 is a side view of the package structure after soldering according to the 4th embodiment in FIG. 19.

FIG. 24 is a partial side view of the package structure after soldering according to the 4th embodiment in FIG. 23.

FIG. 25 is a top view of a package structure according to the 5th embodiment of the present disclosure.

FIG. 26 is a bottom view of the package structure according to the 5th embodiment in FIG. 25.

FIG. 27 is a partial schematic view of the package structure according to the 5th embodiment in FIG. 25.

FIG. 28 is a side view of the package structure according to the 5th embodiment in FIG. 25.

FIG. 29 is a side view of the package structure after soldering according to the 5th embodiment in FIG. 25.

FIG. 30 is a partial side view of the package structure after soldering according to the 5th embodiment in FIG. 29.

FIG. 31 is a top view of a package structure according to the 6th embodiment of the present disclosure.

FIG. 32 is a bottom view of the package structure according to the 6th embodiment in FIG. 31.

FIG. 33 is a partial schematic view of the package structure according to the 6th embodiment in FIG. 31.

FIG. 34 is a side view of the package structure according to the 6th embodiment in FIG. 31.

FIG. 35 is a side view of the package structure after soldering according to the 6th embodiment in FIG. 31.

FIG. 36 is a partial side view of the package structure after soldering according to the 6th embodiment in FIG. 35.

FIG. 37 is a top view of a package structure according to the 7th embodiment of the present disclosure.

FIG. 38 is a bottom view of the package structure according to the 7th embodiment in FIG. 37.

FIG. 39 is a partial schematic view of the package structure according to the 7th embodiment in FIG. 37.

FIG. 40 is a side view of the package structure according to the 7th embodiment in FIG. 37.

FIG. 41 is a cross-sectional schematic view of the package structure along a 41-41 line in FIG. 40.

FIG. 42 is a side view of the package structure after soldering according to the 7th embodiment in FIG. 37.

FIG. 43 is a partial side view of the package structure after soldering according to the 7th embodiment in FIG. 42.

FIG. 44 is a top view of a package structure according to the 8th embodiment of the present disclosure.

FIG. 45 is a bottom view of the package structure according to the 8th embodiment in FIG. 44.

FIG. 46 is a partial schematic view of the package structure according to the 8th embodiment in FIG. 44.

FIG. 47 is a side view of the package structure according to the 8th embodiment in FIG. 44.

FIG. 48 is a cross-sectional schematic view of the package structure along a 48-48 line in FIG. 47.

FIG. 49 is a side view of the package structure after soldering according to the 8th embodiment in FIG. 44.

FIG. 50 is a partial side view of the package structure after soldering according to the 8th embodiment in FIG. 49.

FIG. 51 is a top view of a package structure according to the 9th embodiment of the present disclosure.

FIG. 52 is a bottom view of the package structure according to the 9th embodiment in FIG. 51.

FIG. 53 is a partial schematic view of the package structure according to the 9th embodiment in FIG. 51.

FIG. 54 is a side view of the package structure according to the 9th embodiment in FIG. 51.

FIG. 55 is a cross-sectional schematic view of the package structure along a 55-55 line in FIG. 54.

FIG. 56 is a side view of the package structure after soldering according to the 9th embodiment in FIG. 51.

FIG. 57 is a partial side view of the package structure after soldering according to the 9th embodiment in FIG. 56.

FIG. 58 is a top view of a package structure according to the 10th embodiment of the present disclosure.

FIG. 59 is a bottom view of the package structure according to the 10th embodiment in FIG. 58.

FIG. 60 is a partial schematic view of the package structure according to the 10th embodiment in FIG. 58.

FIG. 61 is a side view of the package structure according to the 10th embodiment in FIG. 58.

FIG. 62 is a cross-sectional schematic view of the package structure along a 62-62 line in FIG. 61.

FIG. 63 is a side view of the package structure after soldering according to the 10th embodiment in FIG. 58.

FIG. 64 is a partial side view of the package structure after soldering according to the 10th embodiment in FIG. 63.

FIG. 65 is a top view of a package structure according to the 11th embodiment of the present disclosure.

FIG. 66 is a bottom view of the package structure according to the 11th embodiment in FIG. 65.

FIG. 67 is a partial schematic view of the package structure according to the 11th embodiment in FIG. 65.

FIG. 68 is a side view of the package structure according to the 11th embodiment in FIG. 65.

FIG. 69 is a cross-sectional schematic view of the package structure along a 69-69 line in FIG. 68.

FIG. 70 is a side view of the package structure after soldering according to the 11th embodiment in FIG. 65.

FIG. 71 is a partial side view of the package structure after soldering according to the 11th embodiment in FIG. 70.

FIG. 72 is a top view of a package structure according to the 12th embodiment of the present disclosure.

FIG. 73 is a bottom view of the package structure according to the 12th embodiment in FIG. 72.

FIG. 74 is a partial schematic view of the package structure according to the 12th embodiment in FIG. 72.

FIG. 75 is a side view of the package structure according to the 12th embodiment in FIG. 72.

FIG. 76 is a cross-sectional schematic view of the package structure along a 76-76 line in FIG. 75.

FIG. 77 is a side view of the package structure after soldering according to the 12th embodiment in FIG. 72.

FIG. 78 is a partial side view of the package structure after soldering according to the 12th embodiment in FIG. 77.

FIG. 79 is a top view of a package structure according to the 13th embodiment of the present disclosure.

FIG. 80 is a bottom view of the package structure according to the 13th embodiment in FIG. 79.

FIG. 81 is a partial schematic view of the package structure according to the 13th embodiment in FIG. 79.

FIG. 82 is a side view of the package structure according to the 13th embodiment in FIG. 79.

FIG. 83 is a cross-sectional schematic view of the package structure along an 83-83 line in FIG. 82.

FIG. 84 is a side view of the package structure after soldering according to the 13th embodiment in FIG. 79.

FIG. 85 is a partial side view of the package structure after soldering according to the 13th embodiment in FIG. 84.

FIG. 86 is a top view of a package structure according to the 14th embodiment of the present disclosure.

FIG. 87 is a bottom view of the package structure according to the 14th embodiment in FIG. 86.

FIG. 88 is a partial schematic view of the package structure according to the 14th embodiment in FIG. 86.

FIG. 89 is a side view of the package structure according to the 14th embodiment in FIG. 86.

FIG. 90 is a top view of the package structure after soldering according to the 14th embodiment in FIG. 86.

FIG. 91 is a bottom view of the package structure after soldering according to the 14th embodiment in FIG. 86.

FIG. 92 is a partial side view of the package structure after soldering according to the 14th embodiment in FIG. 86.

FIG. 93 is a side view of the package structure after soldering according to the 14th embodiment in FIG. 86.

FIG. 94 is a partial side view of the package structure after soldering according to the 14th embodiment in FIG. 93.

FIG. 95 is a top view of a package structure according to the 15th embodiment of the present disclosure.

FIG. 96 is a bottom view of the package structure according to the 15th embodiment in FIG. 95.

FIG. 97 is a partial schematic view of the package structure according to the 15th embodiment in FIG. 95.

FIG. 98 is a side view of the package structure according to the 15th embodiment in FIG. 95.

FIG. 99 is a top view of the package structure after soldering according to the 15th embodiment in FIG. 95.

FIG. 100 is a bottom view of the package structure after soldering according to the 15th embodiment in FIG. 95.

FIG. 101 is a partial side view of the package structure after soldering according to the 15th embodiment in FIG. 95.

FIG. 102 is a side view of the package structure after soldering according to the 15th embodiment in FIG. 95.

FIG. 103 is a partial side view of the package structure after soldering according to the 15th embodiment in FIG. 102.

FIG. 104 is a top view of a package structure according to the 16th embodiment of the present disclosure.

FIG. 105 is a bottom view of the package structure according to the 16th embodiment in FIG. 104.

FIG. 106 is a partial schematic view of the package structure according to the 16th embodiment in FIG. 104.

FIG. 107 is a side view of the package structure according to the 16th embodiment in FIG. 104.

FIG. 108 is a top view of the package structure after soldering according to the 16th embodiment in FIG. 104.

FIG. 109 is a bottom view of the package structure after soldering according to the 16th embodiment in FIG. 104.

FIG. 110 is a partial side view of the package structure after soldering according to the 16th embodiment in FIG. 104.

FIG. 111 is a side view of the package structure after soldering according to the 16th embodiment in FIG. 104.

FIG. 112 is a partial side view of the package structure after soldering according to the 16th embodiment in FIG. 111.

FIG. 113 is a top view of a package structure according to the 17th embodiment of the present disclosure.

FIG. 114 is a bottom view of the package structure according to the 17th embodiment in FIG. 113.

FIG. 115 is a partial schematic view of the package structure according to the 17th embodiment in FIG. 113.

FIG. 116 is a side view of the package structure according to the 17th embodiment in FIG. 113.

FIG. 117 is a top view of the package structure after soldering according to the 17th embodiment in FIG. 113.

FIG. 118 is a bottom view of the package structure after soldering according to the 17th embodiment in FIG. 113.

FIG. 119 is a partial side view of the package structure after soldering according to the 17th embodiment in FIG. 113.

FIG. 120 is a side view of the package structure after soldering according to the 17th embodiment in FIG. 113.

FIG. 121 is a partial side view of the package structure after soldering according to the 17th embodiment in FIG. 120.

FIG. 122 is a top view of a package structure according to the 18th embodiment of the present disclosure.

FIG. 123 is a bottom view of the package structure according to the 18th embodiment in FIG. 122.

FIG. 124 is a partial schematic view of the package structure according to the 18th embodiment in FIG. 122.

FIG. 125 is a side view of the package structure according to the 18th embodiment in FIG. 122.

FIG. 126 is a top view of the package structure after soldering according to the 18th embodiment in FIG. 122.

FIG. 127 is a bottom view of the package structure after soldering according to the 18th embodiment in FIG. 122.

FIG. 128 is a partial side view of the package structure after soldering according to the 18th embodiment in FIG. 122.

FIG. 129 is a side view of the package structure after soldering according to the 18th embodiment in FIG. 122.

FIG. 130 is a partial side view of the package structure after soldering according to the 18th embodiment in FIG. 129.

FIG. 131 is a top view of a package structure according to the 19th embodiment of the present disclosure.

FIG. 132 is a bottom view of the package structure according to the 19th embodiment in FIG. 131.

FIG. 133 is a partial schematic view of the package structure according to the 19th embodiment in FIG. 131.

FIG. 134 is a side view of the package structure according to the 19th embodiment in FIG. 131.

FIG. 135 is a top view of the package structure after soldering according to the 19th embodiment in FIG. 131.

FIG. 136 is a bottom view of the package structure after soldering according to the 19th embodiment in FIG. 131.

FIG. 137 is a partial side view of the package structure after soldering according to the 19th embodiment in FIG. 131.

FIG. 138 is a side view of the package structure after soldering according to the 19th embodiment in FIG. 131.

FIG. 139 is a partial side view of the package structure after soldering according to the 19th embodiment in FIG. 138.

### DETAILED DESCRIPTION

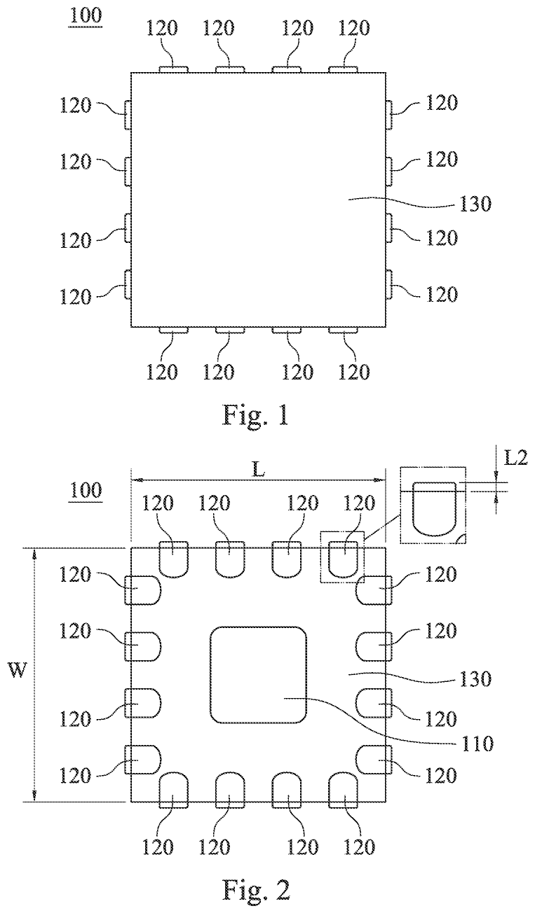

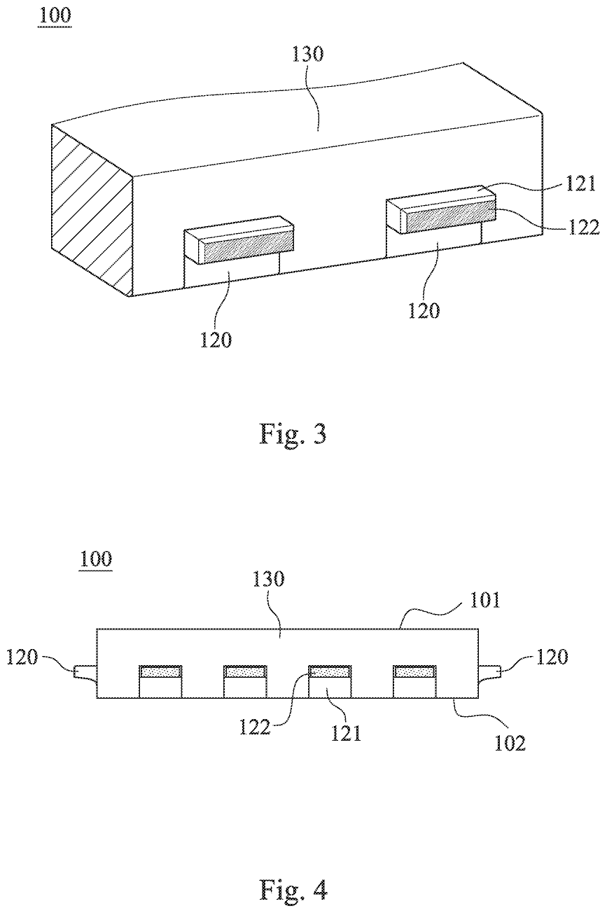

FIG. 1 is a top view of a package structure 100 according to the 1st embodiment of the present disclosure. FIG. 2 is a bottom view of the package structure 100 according to the 1st embodiment in FIG. 1. FIG. 3 is a partial schematic view of the package structure 100 according to the 1st embodiment in FIG. 1. In FIGS. 1 to 3, the package structure 100 includes a leadframe (its reference numeral is omitted), a semiconductor die (not shown) and a plastic package material 130, wherein the leadframe is for carrying the semiconductor die, the plastic package material 130 is disposed on the leadframe, and the semiconductor die is covered via the plastic package material 130 to form the package structure 100.

Moreover, the leadframe includes a die pad 110 and a plurality of leads, wherein each of the leads can be a step-shaped lead 120, the step-shaped leads 120 are disposed on four sides of the die pad 110, and each of the step-shaped leads 120 includes a plurality of plating surfaces 121 and at least one non-plating surface 122. The semiconductor die is disposed on the die pad 110 of the leadframe, the plastic package material 130 is disposed on the leadframe, and each of the step-shaped leads 120 protrudes an outer region of the plastic package material 130. Therefore, the step-shaped leads 120 which protrude sides of the package structure 100 are favorable for enhancing the solderable area of the sides of the package structure 100.

According to the 1st embodiment, the package structure 100 can be obtained by an etching step, a molding step, two laser steps, a plating step and a singulation step. In the etching step, a lower surface of the leadframe is etched. In the molding step, the plastic package material 130 is disposed on and covers the semiconductor die. In the laser steps, each of a portion of the plastic package material 130 on an upper surface of the leadframe and a portion of the plastic package material 130 on the lower surface of the leadframe is removed via a laser beam. In the plating step, the plating surfaces 121 are disposed on a surface of the leadframe without the plastic package material 130 after the laser steps. In the singulation step, the package structure 100 is formed. Moreover, a number of the laser steps can be more than two, and it depends on the energy and the parameters of the laser beam, but the aforementioned steps are not limited.

In FIG. 2, when a length of the plastic package material 130 is L, a width of the plastic package material 130 is W, and a maximum protruding length of each of the leads (according to the 1st embodiment, each of the leads is the step-shaped lead 120) is L2, the following conditions can be satisfied: W≤L, 0.01 W≤L2, and L2≤≤0.5 L. In particular, the plastic package material 130 can be square or rectangle, and the maximum protruding length depends on the disposition of the circuit board, and is not limited thereto. Further, the maximum protruding lengths of the step-shaped leads 120 can be the same. Therefore, the solderable area of the step-shaped leads 120 at the sides of the package structure 100 can be consistent. Moreover, the soldering difference is less easily generated when the package structure 100 soldered on the circuit board (not shown), and the package structure 100 can be firmly disposed on the circuit board.

In detail, the plating surfaces 121 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu); the leadframe can be made of an iron-nickel alloy or a copper alloy; the plastic package material 130 can be made of an epoxy resin, but are not limited thereto.

FIG. 4 is a side view of the package structure 100 according to the 1st embodiment in FIG. 1. In FIGS. 3 and 4, a protruding length of a portion of each of the step-shaped leads 120 close to a lower surface 102 of the package structure 100 is smaller than a protruding length of another portion of each of the step-shaped leads 120 close to an upper surface 101 of the package structure 100. Moreover, the portion of each of the step-shaped leads 120 close to the lower surface 102 of the package structure 100 does not protrude an edge of the plastic package material 130. Therefore, according to the 1st embodiment, the package outline drawing (POD) does not need to be changed, and the process of redrawing the POD can be reduced. Furthermore, a thickness of each of the step-shaped leads 120 is thinner, so the burr can be reduced.

Moreover, a minimum protruding length of each of the step-shaped leads 120 is aligned to the edge of the plastic package material 130 (that is, the portion of each of the step-shaped leads 120 close to the lower surface 102 of the package structure 100), and a length of a bottom of each of the step-shaped leads 120 contact with the circuit board is not reduced. Therefore, according to the 1st embodiment, not only can the solderable area of the side of the each of the step-shaped leads 120 be increased, the connection strength between the bottom of the step-shaped leads 120 and the circuit board can also be simultaneously maintained to increase the lifetime of the package structure 100 disposed on the circuit board.

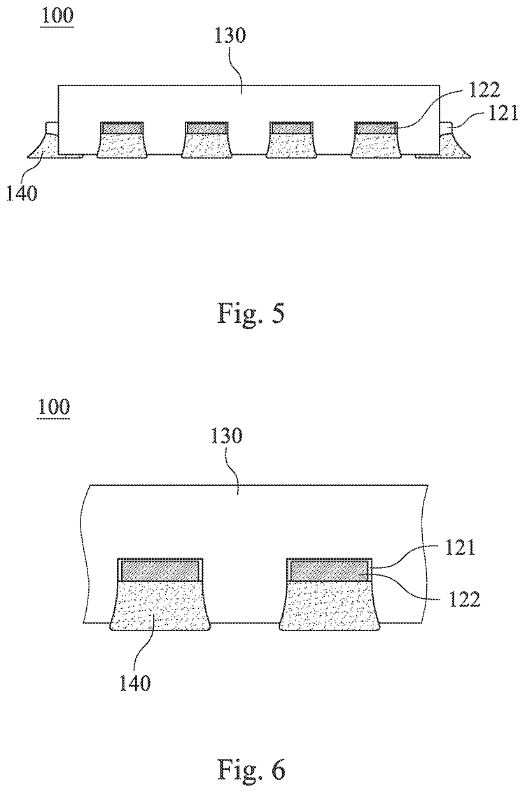

FIG. 5 is a side view of the package structure 100 after soldering according to the 1st embodiment in FIG. 1. FIG. 6 is a partial side view of the package structure 100 after soldering according to the 1st embodiment in FIG. 5. A number of the plating surfaces 121 can be at least four. In FIGS. 3 to 6, according to the 1st embodiment, the number of the plating surfaces 121 is five, but is not limited thereto. Further, in FIGS. 5 and 6, soldering portions 140 of the package structure 100 can be only disposed on the plating surfaces 121. Therefore, the soldering strength between the package structure 100 and the circuit board is increased when the package structure 100 is disposed on the circuit board because of the enhancement of the solderable area of the side of each of the step-shaped leads 120.

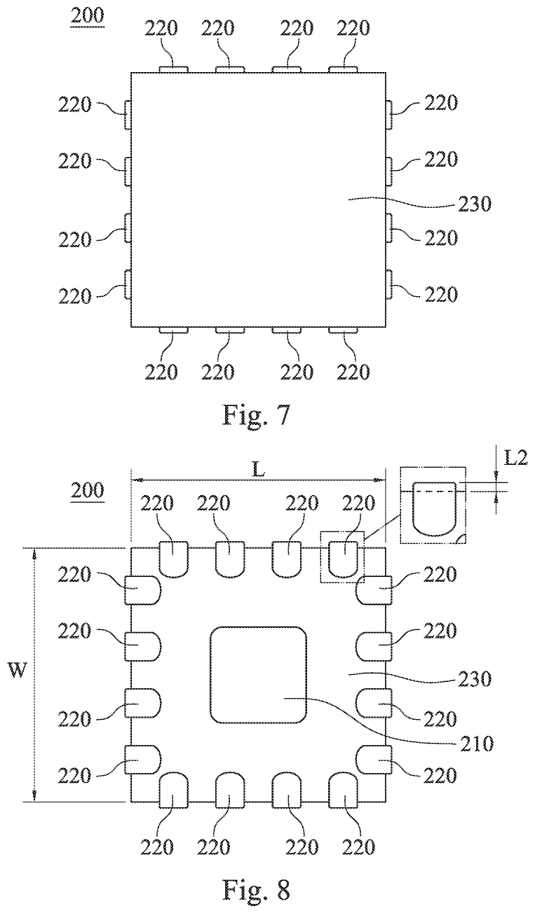

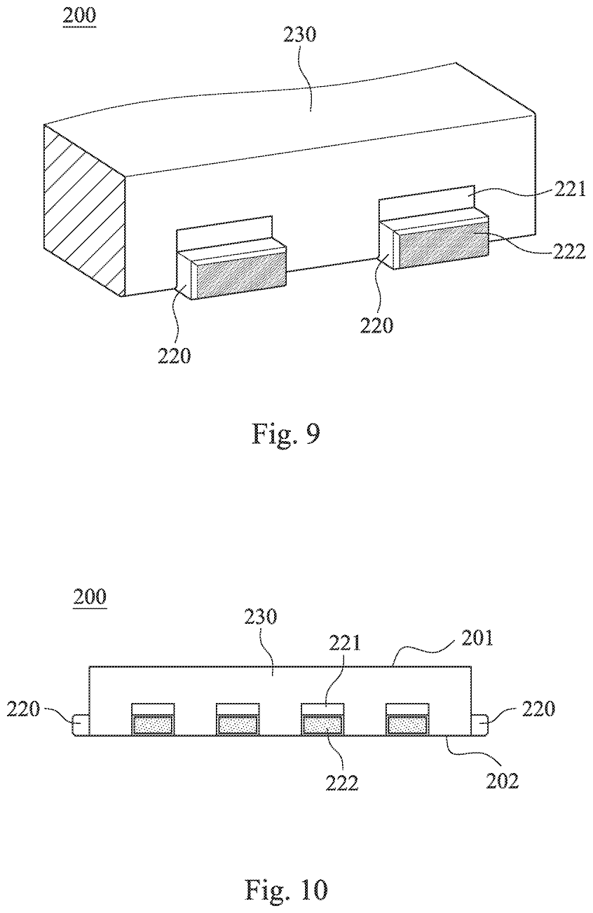

FIG. 7 is a top view of a package structure 200 according to the 2nd embodiment of the present disclosure. FIG. 8 is a bottom view of the package structure 200 according to the 2nd embodiment in FIG. 7. FIG. 9 is a partial schematic view of the package structure 200 according to the 2nd embodiment in FIG. 7. In FIGS. 7 to 9, the package structure 200 includes a leadframe (its reference numeral is omitted), a semiconductor die (not shown) and a plastic package material 230, wherein the leadframe is for carrying the semiconductor die, the plastic package material 230 is disposed on the leadframe, and the semiconductor die is covered via the plastic package material 230 to form the package structure 200.

Moreover, the leadframe includes a die pad 210 and a plurality of leads, wherein each of the leads can be a step-shaped lead 220, the step-shaped leads 220 are disposed on four sides of the die pad 210, and each of the step-shaped leads 220 includes a plurality of plating surfaces 221 and at least one non-plating surface 222. The semiconductor die is disposed on the die pad 210 of the leadframe, the plastic package material 230 is disposed on the leadframe, and each of the step-shaped leads 220 protrudes an outer region of the plastic package material 230. Therefore, the step-shaped leads 220 which protrude sides of the package structure 200 are favorable for enhancing the solderable area of the sides of the package structure 200.

According to the 2nd embodiment, the package structure 200 can be obtained by an etching step, a molding step, a laser step, a plating step and a singulation step. In the etching step, a lower surface of the leadframe is etched. In the molding step, the plastic package material 230 is disposed on and covers the semiconductor die. In the laser step, each of a portion of the plastic package material 230 and a portion of the leadframe on an upper surface of the leadframe is removed via a laser beam. In the plating step, the plating surfaces 221 are disposed on a surface of the leadframe without the plastic package material 230 after the laser step. In the singulation step, the package structure 200 is formed. Moreover, a number of the laser step can be more than two, and it depends on the energy and the parameters of the laser beam, but the aforementioned steps are not limited.

In FIG. 8, when a length of the plastic package material 230 is L, a width of the plastic package material 230 is W, and a maximum protruding length of each of the leads (according to the 2nd embodiment, each of the leads is the step-shaped lead 220) is L2, the following conditions can be satisfied: W≤L, 0.01 W≤L2, and L2≤≤0.5 L. In particular, the plastic package material 230 can be square or rectangle, and the maximum protruding length depends on the disposition of the circuit board, and is not limited thereto. Further, the maximum protruding lengths of the step-shaped leads 220 can be the same. Therefore, the solderable area of the step-shaped leads 220 at the sides of the package structure 200 can be consistent. Moreover, the soldering difference is less easily generated when the package structure 200 soldered on the circuit board (not shown), and the package structure 200 can be firmly disposed on the circuit board.

In detail, the plating surfaces 221 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu); the leadframe can be made of an iron-nickel alloy or a copper alloy; the plastic package material 230 can be made of an epoxy resin, but are not limited thereto.

FIG. 10 is a side view of the package structure 200 according to the 2nd embodiment in FIG. 7. In FIGS. 9 and 10, a protruding length of a portion of each of the step-shaped leads 220 close to an upper surface 201 of the package structure 200 is smaller than a protruding length of another portion of each of the step-shaped leads 220 close to a lower surface 202 of the package structure 200. Moreover, the portion of each of the step-shaped leads 220 close to the upper surface 201 of the package structure 200 does not protrude an edge of the plastic package material 230. Furthermore, a protruding width of each of the step-shaped leads 220 is wider, and a thickness of each of the step-shaped leads 220 is thinner, so the burr can be reduced.

Moreover, the protruding length of another portion of each of the step-shaped leads 220 close to the lower surface 202 of the package structure 200 protrudes an edge of the plastic package material 230. Therefore, according to the 2nd embodiment, not only can the solderable area of the side of the each of the step-shaped leads 220 be increased, the connection strength between the bottom of the step-shaped leads 220 and the circuit board can also be simultaneously maintained to increase the lifetime of the package structure 200 disposed on the circuit board.

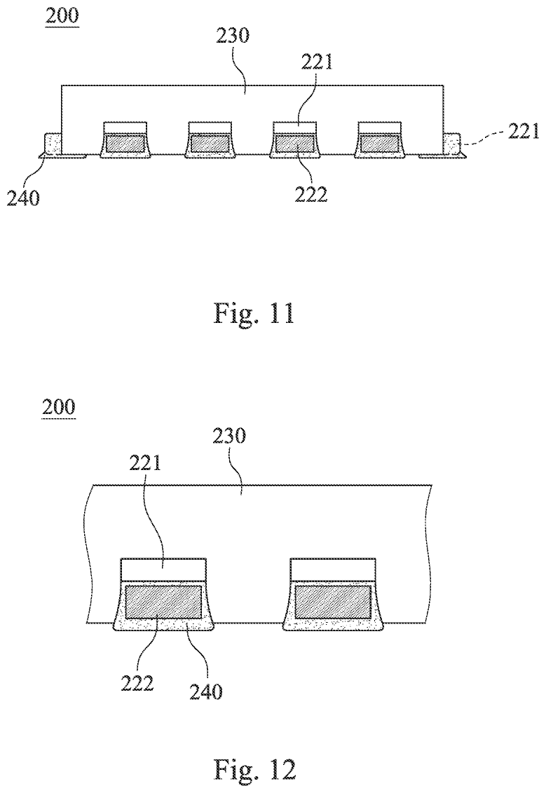

FIG. 11 is a side view of the package structure 200 after soldering according to the 2nd embodiment in FIG. 7. FIG. 12 is a partial side view of the package structure 200 after soldering according to the 2nd embodiment in FIG. 11. A number of the plating surfaces 221 can be at least four. In FIGS. 9 to 12, according to the 2nd embodiment, the number of the plating surfaces 221 is five, but is not limited thereto. Further, in FIGS. 11 and 12, soldering portions 240 of the package structure 200 can be only disposed on the plating surfaces 221. Therefore, the soldering strength between the package structure 200 and the circuit board is increased when the package structure 200 is disposed on the circuit board because of the enhancement of the solderable area of the side of each of the step-shaped leads 220.

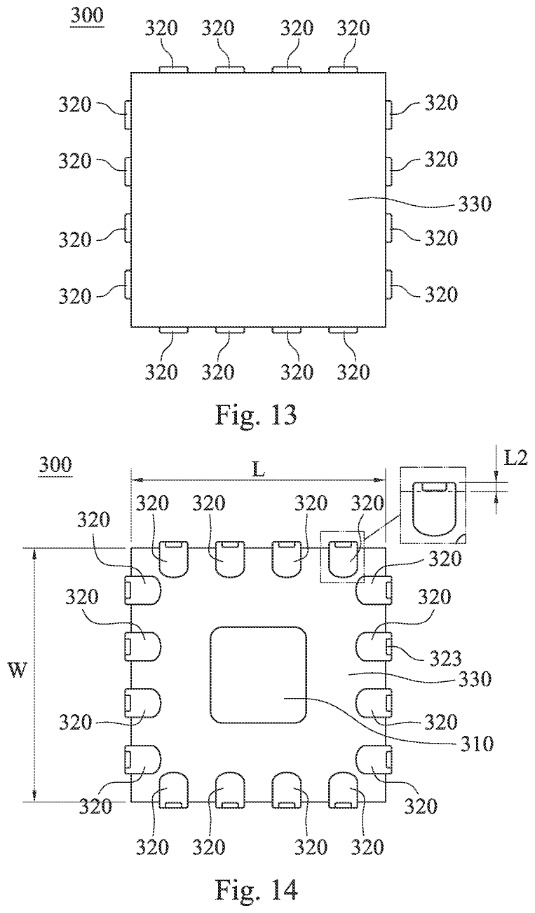

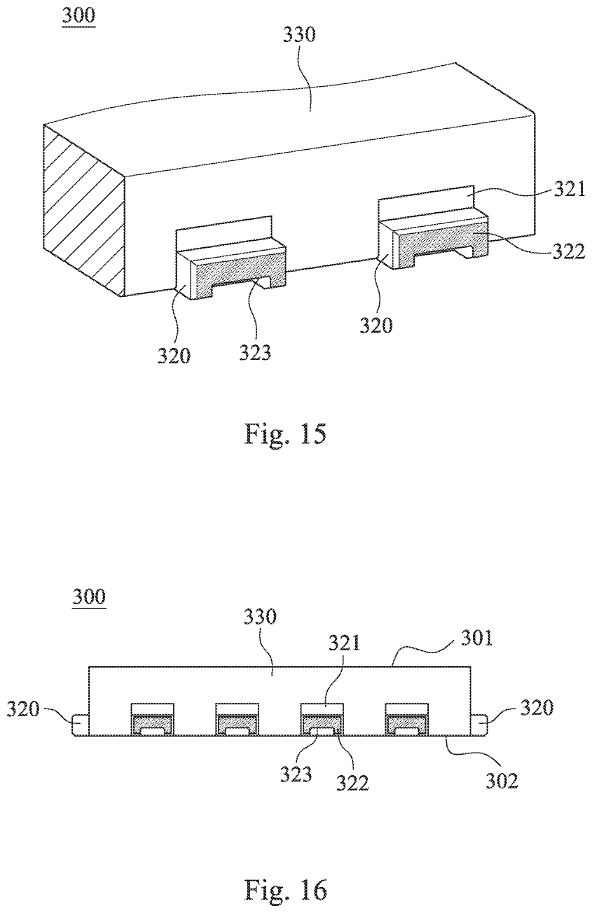

FIG. 13 is a top view of a package structure 300 according to the 3rd embodiment of the present disclosure. FIG. 14 is a bottom view of the package structure 300 according to the 3rd embodiment in FIG. 13. FIG. 15 is a partial schematic view of the package structure 300 according to the 3rd embodiment in FIG. 13. In FIGS. 13 to 15, the package structure 300 includes a leadframe (its reference numeral is omitted), a semiconductor die (not shown) and a plastic package material 330, wherein the leadframe is for carrying the semiconductor die, the plastic package material 330 is disposed on the leadframe, and the semiconductor die is covered via the plastic package material 330 to form the package structure 300.

Moreover, the leadframe includes a die pad 310 and a plurality of leads, wherein each of the leads can be a step-shaped lead 320, the step-shaped leads 320 are disposed on four sides of the die pad 310, and each of the step-shaped leads 320 includes a plurality of plating surfaces 321, at least one non-plating surface 322 and a concave portion 323, wherein the concave portion 323 is located on a surface of each of the step-shaped leads 320, and the plating surfaces 321 are disposed on each of the step-shaped leads 320 and the concave portion 323. The semiconductor die is disposed on the die pad 310 of the leadframe, the plastic package material 330 is disposed on the leadframe, and each of the step-shaped leads 320 protrudes an outer region of the plastic package material 330. Therefore, the step-shaped leads 320 which protrude sides of the package structure 300 are favorable for enhancing the solderable area of the sides of the package structure 300.

According to the 3rd embodiment, the package structure 300 can be obtained by an etching step, a molding step, a laser step, a plating step and a singulation step. In the etching step, a lower surface of the leadframe is etched. In the molding step, the plastic package material 330 is disposed on and covers the semiconductor die. In the laser step, each of a portion of the plastic package material 330 and a portion of the leadframe on an upper surface of the leadframe is removed via a laser beam. In the plating step, the plating surfaces 321 are disposed on a surface of the leadframe without the plastic package material 330 after the laser step. In the singulation step, the package structure 300 is formed. Moreover, a number of the laser step can be more than two, and it depends on the energy and the parameters of the laser beam, but the aforementioned steps are not limited.

In FIG. 14, when a length of the plastic package material 330 is L, a width of the plastic package material 330 is W, and a maximum protruding length of each of the leads (according to the 3rd embodiment, each of the leads is the step-shaped lead 320) is L2, the following conditions can be satisfied: W≤L, 0.01 W≤L2, and L2≤≤0.5 L. In particular, the plastic package material 330 can be square or rectangle, and the maximum protruding length depends on the disposition of the circuit board, and is not limited thereto. Further, the maximum protruding lengths of the step-shaped leads 320 can be the same. Therefore, the solderable area of the step-shaped leads 320 at the sides of the package structure 300 can be consistent. Moreover, the soldering difference is less easily generated when the package structure 300 soldered on the circuit board (not shown), and the package structure 300 can be firmly disposed on the circuit board.

In detail, the plating surfaces 321 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu); the leadframe can be made of an iron-nickel alloy or a copper alloy; the plastic package material 330 can be made of an epoxy resin, but are not limited thereto.

FIG. 16 is a side view of the package structure 300 according to the 3rd embodiment in FIG. 13. In FIGS. 15 and 16, a protruding length of a portion of each of the step-shaped leads 320 close to an upper surface 301 of the package structure 300 is smaller than a protruding length of another portion of each of the step-shaped leads 320 close to a lower surface 302 of the package structure 300. Moreover, a concave depth of the concave portion 323 of each of the step-shaped leads 320 can be equal to half of a thickness of another portion of each of the step-shaped leads 320 close to the lower surface 302 of the package structure 300. Further, a thickness of each of the step-shaped leads 320 is thinner, so the burr can be reduced.

Moreover, the protruding length of another portion of each of the step-shaped leads 320 close to the lower surface 302 of the package structure 300 protrudes an edge of the plastic package material 330. Therefore, according to the 3rd embodiment, not only can the solderable area of the side of the each of the step-shaped leads 320 be increased, the connection strength between the bottom of the step-shaped leads 320 and the circuit board can also be simultaneously maintained to increase the lifetime of the package structure 300 disposed on the circuit board.

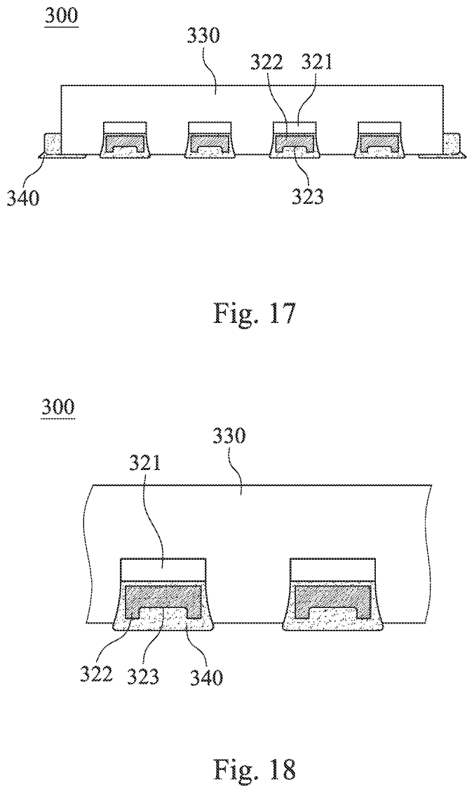

FIG. 17 is a side view of the package structure 300 after soldering according to the 3rd embodiment in FIG. 13. FIG. 18 is a partial side view of the package structure 300 after soldering according to the 3rd embodiment in FIG. 17. A number of the plating surfaces 321 can be at least four. In FIGS. 15 to 18, according to the 3rd embodiment, the number of the plating surfaces 321 is eight, but is not limited thereto. Further, in FIGS. 17 and 18, soldering portions 340 of the package structure 300 can be only disposed on the plating surfaces 321. Therefore, the soldering strength between the package structure 300 and the circuit board is increased when the package structure 300 is disposed on the circuit board because of the enhancement of the solderable area of the side of each of the step-shaped leads 320.

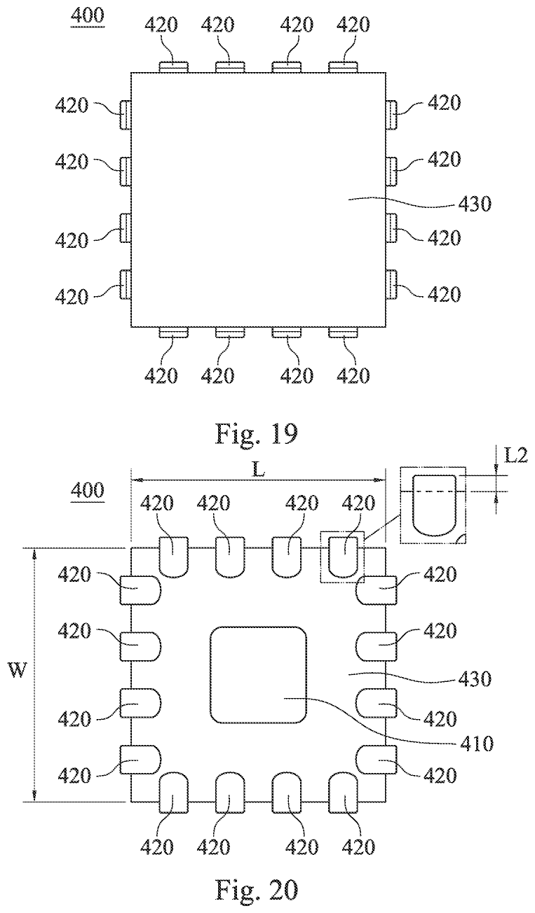

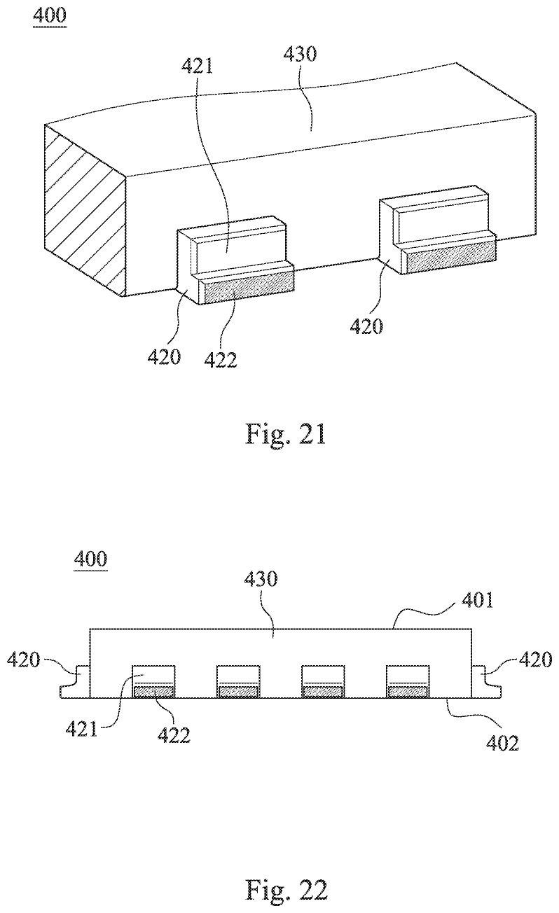

FIG. 19 is a top view of a package structure 400 according to the 4th embodiment of the present disclosure. FIG. 20 is a bottom view of the package structure 400 according to the 4th embodiment in FIG. 19. FIG. 21 is a partial schematic view of the package structure 400 according to the 4th embodiment in FIG. 19. In FIGS. 19 to 21, the package structure 400 includes a leadframe (its reference numeral is omitted), a semiconductor die (not shown) and a plastic package material 430, wherein the leadframe is for carrying the semiconductor die, the plastic package material 430 is disposed on the leadframe, and the semiconductor die is covered via the plastic package material 430 to form the package structure 400.

Moreover, the leadframe includes a die pad 410 and a plurality of leads, wherein each of the leads can be a step-shaped lead 420, the step-shaped leads 420 are disposed on four sides of the die pad 410, and each of the step-shaped leads 420 includes a plurality of plating surfaces 421 and at least one non-plating surface 422. The semiconductor die is disposed on the die pad 410 of the leadframe, the plastic package material 430 is disposed on the leadframe, and each of the step-shaped leads 420 protrudes an outer region of the plastic package material 430. Therefore, the step-shaped leads 420 which protrude sides of the package structure 400 are favorable for enhancing the solderable area of the sides of the package structure 400.

According to the 4th embodiment, the package structure 400 can be obtained by an etching step, a molding step, a laser step, a plating step and a singulation step. In the etching step, an upper surface of the leadframe is etched. In the molding step, the plastic package material 430 is disposed on and covers the semiconductor die. In the laser step, a portion of the plastic package material 430 on an upper surface of the leadframe is removed via a laser beam. In the plating step, the plating surfaces 421 are disposed on a surface of the leadframe without the plastic package material 430 after the laser step. In the singulation step, the package structure 400 is formed. Moreover, a number of the laser step can be more than two, and it depends on the energy and the parameters of the laser beam, but the aforementioned steps are not limited.

In FIG. 20, when a length of the plastic package material 430 is L, a width of the plastic package material 430 is W, and a maximum protruding length of each of the leads (according to the 4th embodiment, each of the leads is the step-shaped lead 420) is L2, the following conditions can be satisfied: W≤L, 0.01 W≤L2, and L2≤≤0.5 L. In particular, the plastic package material 430 can be square or rectangle, and the maximum protruding length depends on the disposition of the circuit board, and is not limited thereto. Further, the maximum protruding lengths of the step-shaped leads 420 can be the same. Therefore, the solderable area of the step-shaped leads 420 at the sides of the package structure 400 can be consistent. Moreover, the soldering difference is less easily generated when the package structure 400 soldered on the circuit board (not shown), and the package structure 400 can be firmly disposed on the circuit board.

In detail, the plating surfaces 421 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu); the leadframe can be made of an iron-nickel alloy or a copper alloy; the plastic package material 430 can be made of an epoxy resin, but are not limited thereto.

FIG. 22 is a side view of the package structure 400 according to the 4th embodiment in FIG. 19. In FIGS. 21 and 22, a protruding length of a portion of each of the step-shaped leads 420 close to an upper surface 401 of the package structure 400 is smaller than a protruding length of another portion of each of the step-shaped leads 420 close to a lower surface 402 of the package structure 400. Further, a protruding width of each of the step-shaped leads 420 is wider, and a thickness of each of the step-shaped leads 420 is thinner, so the burr can be reduced.

Moreover, the protruding length of another portion of each of the step-shaped leads 420 close to the lower surface 402 of the package structure 400 protrudes an edge of the plastic package material 430. Therefore, according to the 4th embodiment, not only can the solderable area of the side of the each of the step-shaped leads 420 be increased, the connection strength between the bottom of the step-shaped leads 420 and the circuit board can only be simultaneously maintained to increase the lifetime of the package structure 400 disposed on the circuit board.

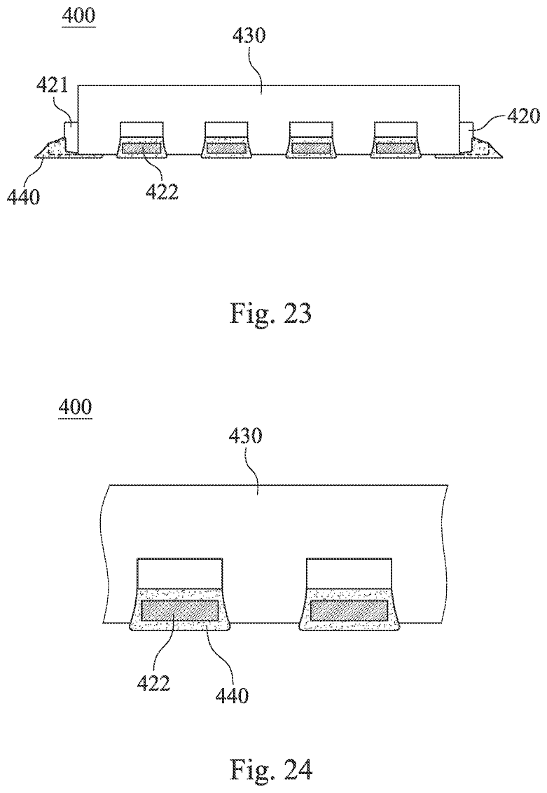

FIG. 23 is a side view of the package structure 400 after soldering according to the 4th embodiment in FIG. 19. FIG. 24 is a partial side view of the package structure 400 after soldering according to the 4th embodiment in FIG. 23. A number of the plating surfaces 421 can be at least four. In FIGS. 21 to 24, according to the 4th embodiment, the number of the plating surfaces 421 is six, but is not limited thereto. Further, in FIGS. 23 and 24, soldering portions 440 of the package structure 400 can be only disposed on the plating surfaces 421. Therefore, the soldering strength between the package structure 400 and the circuit board is increased when the package structure 400 is disposed on the circuit board because of the enhancement of the solderable area of the side of each of the step-shaped leads 420.

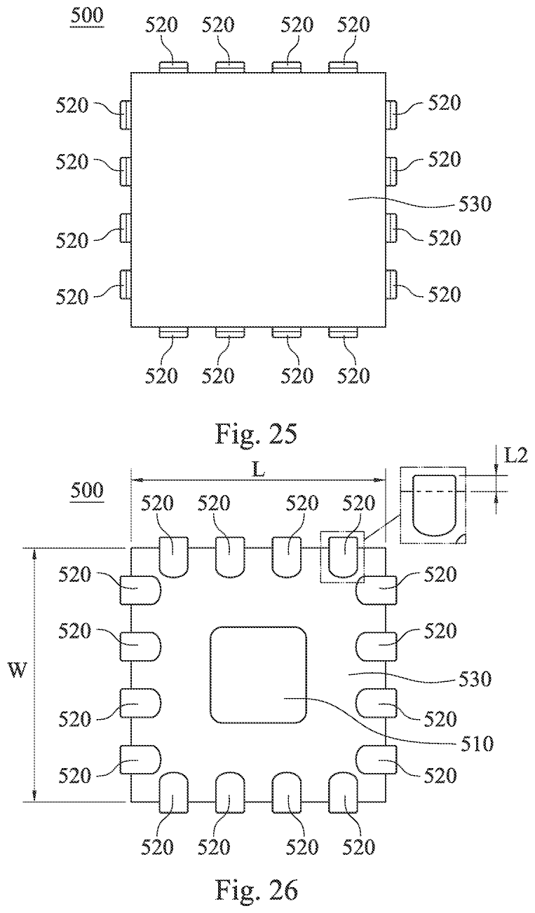

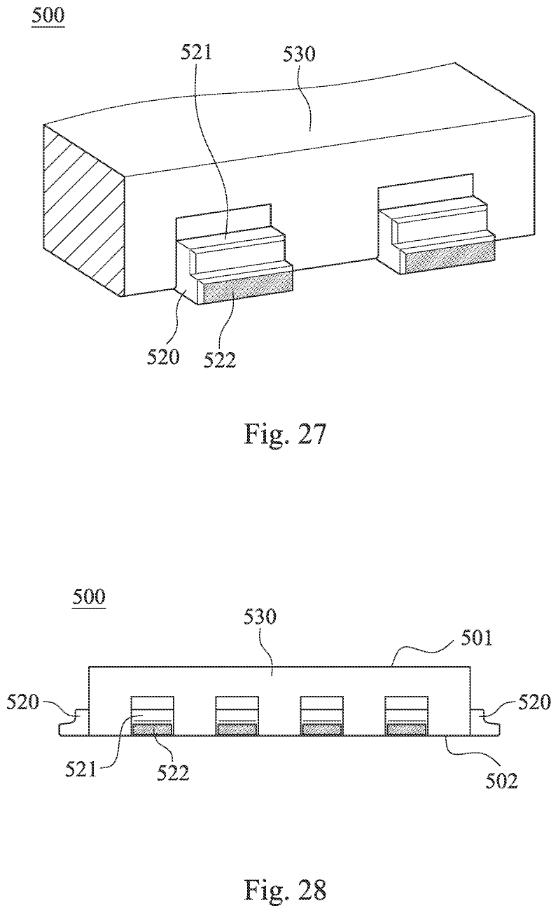

FIG. 25 is a top view of a package structure 500 according to the 5th embodiment of the present disclosure. FIG. 26 is a bottom view of the package structure 500 according to the 5th embodiment in FIG. 25. FIG. 27 is a partial schematic view of the package structure 500 according to the 5th embodiment in FIG. 25. In FIGS. 25 to 27, the package structure 500 includes a leadframe (its reference numeral is omitted), a semiconductor die (not shown) and a plastic package material 530, wherein the leadframe is for carrying the semiconductor die, the plastic package material 530 is disposed on the leadframe, and the semiconductor die is covered via the plastic package material 530 to form the package structure 500.

Moreover, the leadframe includes a die pad 510 and a plurality of leads, wherein each of the leads can be a step-shaped lead 520, the step-shaped leads 520 are disposed on four sides of the die pad 510, and each of the step-shaped leads 520 includes a plurality of plating surfaces 521 and at least one non-plating surface 522. The semiconductor die is disposed on the die pad 510 of the leadframe, the plastic package material 530 is disposed on the leadframe, and each of the step-shaped leads 520 protrudes an outer region of the plastic package material 530. Therefore, the step-shaped leads 520 which protrude sides of the package structure 500 are favorable for enhancing the solderable area of sides of the package structure 500.

According to the 5th embodiment, the package structure 500 can be obtained by an etching step, a molding step, a laser step, a plating step and a singulation step. In the etching step, an upper surface of the leadframe is etched. In the molding step, the plastic package material 530 is disposed on and covers the semiconductor die. In the laser step, each of a portion of the plastic package material 530 and a portion of the leadframe on an upper surface of the leadframe is removed via a laser beam. In the plating step, the plating surfaces 521 are disposed on a surface of the leadframe without the plastic package material 530 after the laser step. In the singulation step, the package structure 500 is formed. Moreover, a number of the laser step can be more than two, and it depends on the energy and the parameters of the laser beam, but the aforementioned steps are not limited.

In FIG. 26, when a length of the plastic package material 530 is L, a width of the plastic package material 530 is W, and a maximum protruding length of each of the leads (according to the 5th embodiment, each of the leads is the step-shaped lead 520) is L2, the following conditions can be satisfied: W≤L, 0.01 W≤L2, and L2≤≤0.5 L. In particular, the plastic package material 530 can be square or rectangle, and the maximum protruding length depends on the disposition of the circuit board, and is not limited thereto. Further, the maximum protruding lengths of the step-shaped leads 520 can be the same. Therefore, the solderable area of the step-shaped leads 520 at the sides of the package structure 500 can be consistent. Moreover, the soldering difference is less easily generated when the package structure 500 soldered on the circuit board (not shown), and the package structure 500 can be firmly disposed on the circuit board.

In detail, the plating surfaces 521 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu); the leadframe can be made of an iron-nickel alloy or a copper alloy; the plastic package material 530 can be made of an epoxy resin, but are not limited thereto.

FIG. 28 is a side view of the package structure 500 according to the 5th embodiment in FIG. 25. In FIGS. 27 and 28, a protruding length of a portion of each of the step-shaped leads 520 close to an upper surface 501 of the package structure 500 is smaller than a protruding length of another portion of each of the step-shaped leads 520 close to a lower surface 502 of the package structure 500. Moreover, the portion of each of the step-shaped leads 520 close to the upper surface 501 of the package structure 500 does not protrude an edge of the plastic package material 530, and the protruding length of another portion of each of the step-shaped leads 520 close to the lower surface 502 of the package structure 500 is tapered to the protruding length of the portion of each of the step-shaped leads 520 close to the upper surface 501 of the package structure 500. Furthermore, a protruding width of each of the step-shaped leads 520 is wider, and a thickness of each of the step-shaped leads 520 is thinner, so the burr can be reduced.

Moreover, the protruding length of another portion of each of the step-shaped leads 520 close to the lower surface 502 of the package structure 500 protrudes an edge of the plastic package material 530. Therefore, according to the 5th embodiment, not only can the solderable area of the side of the each of the step-shaped leads 520 be increased, the connection strength between the bottom of the step-shaped leads 520 and the circuit board can also be simultaneously maintained to increase the lifetime of the package structure 500 disposed on the circuit board.

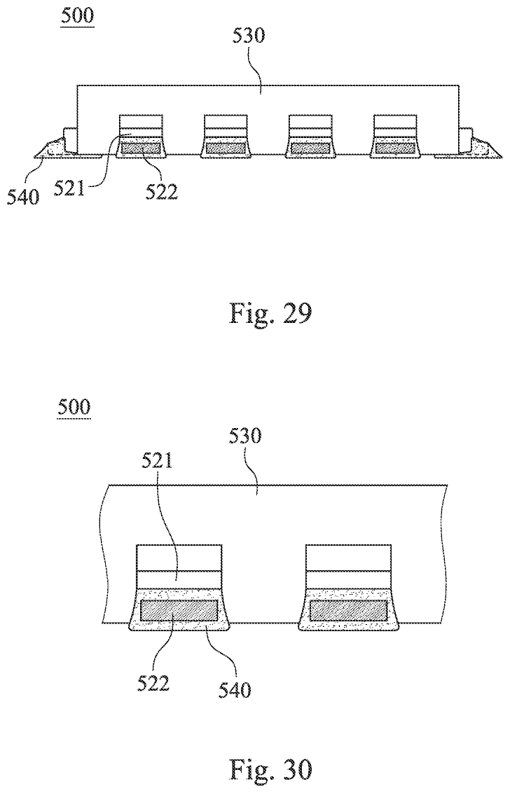

FIG. 29 is a side view of the package structure 500 after soldering according to the 5th embodiment in FIG. 25. FIG. 30 is a partial side view of the package structure 500 after soldering according to the 5th embodiment in FIG. 29. A number of the plating surfaces 521 can be at least four. In FIGS. 27 to 30, according to the 5th embodiment, the number of the plating surfaces 521 is seven, but is not limited thereto. Further, in FIGS. 29 and 30, soldering portions 540 of the package structure 500 can be only disposed on the plating surfaces 521. Therefore, the soldering strength between the package structure 500 and the circuit board is increased when the package structure 500 is disposed on the circuit board because of the enhancement of the solderable area of the side of each of the step-shaped leads 520.

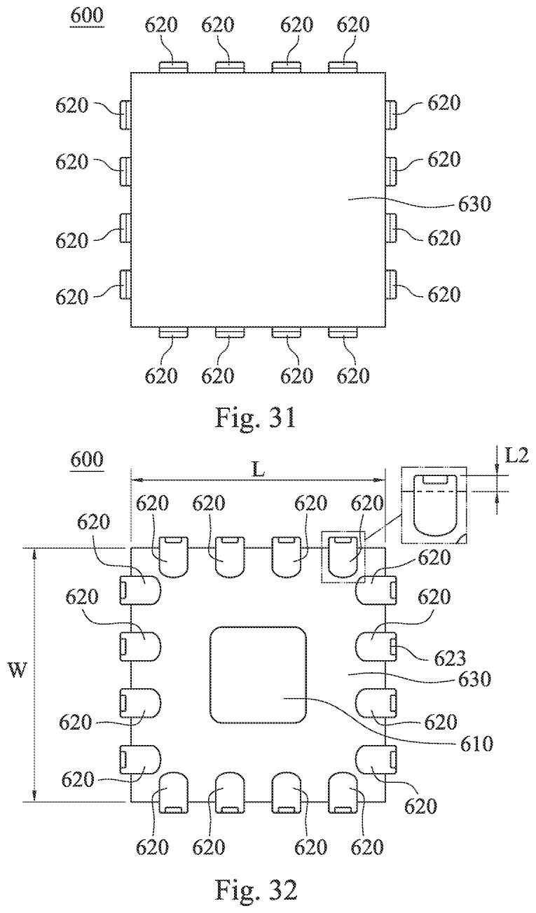

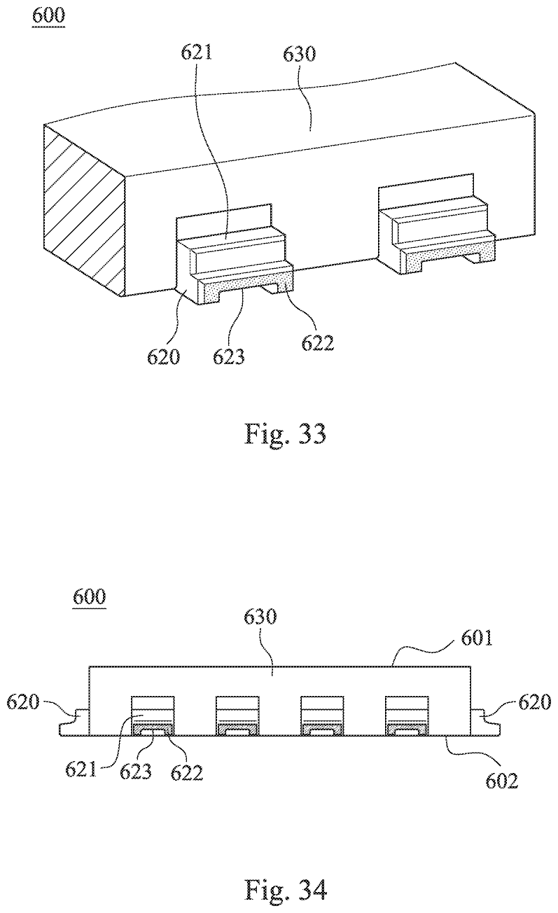

FIG. 31 is a top view of a package structure 600 according to the 6th embodiment of the present disclosure. FIG. 32 is a bottom view of the package structure 600 according to the 6th embodiment in FIG. 31. FIG. 33 is a partial schematic view of the package structure 600 according to the 6th embodiment in FIG. 31. In FIGS. 31 to 33, the package structure 600 includes a leadframe (its reference numeral is omitted), a semiconductor die (not shown) and a plastic package material 630, wherein the leadframe is for carrying the semiconductor die, the plastic package material 630 is disposed on the leadframe, and the semiconductor die is covered via the plastic package material 630 to form the package structure 600.

Moreover, the leadframe includes a die pad 610 and a plurality of leads, wherein each of the leads can be a step-shaped lead 620, the step-shaped leads 620 are disposed on four sides of the die pad 610, and each of the step-shaped leads 620 includes a plurality of plating surfaces 621, at least one non-plating surface 622 and a concave portion 623, wherein the concave portion 623 is located on a surface of each of the step-shaped leads 620, and the plating surfaces 621 are disposed on each of the step-shaped leads 620 and the concave portion 623. The semiconductor die is disposed on the die pad 610 of the leadframe, the plastic package material 630 is disposed on the leadframe, and each of the step-shaped leads 620 protrudes an outer region of the plastic package material 630. Therefore, the step-shaped leads 620 which protrude sides of the package structure 600 are favorable for enhancing the solderable area of sides of the package structure 600.

According to the 6th embodiment, the package structure 600 can be obtained by an etching step, a molding step, a laser step, a plating step and a singulation step. In the etching step, an upper surface of the leadframe is etched. In the molding step, the plastic package material 630 is disposed on and covers the semiconductor die. In the laser step, each of a portion of the plastic package material 630 and a portion of the leadframe on an upper surface of the leadframe is removed via a laser beam. In the plating step, the plating surfaces 621 are disposed on a surface of the leadframe without the plastic package material 630 after the laser step. In the singulation step, the package structure 600 is formed. Moreover, a number of the laser step can be more than two, and it depends on the energy and the parameters of the laser beam, but the aforementioned steps are not limited.

In FIG. 32, when a length of the plastic package material 630 is L, a width of the plastic package material 630 is W, and a maximum protruding length of each of the leads (according to the 6th embodiment, each of the leads is the step-shaped lead 620) is L2, the following conditions can be satisfied: W≤L, 0.01 W≤L2, and L2≤≤0.5 L. In particular, the plastic package material 630 can be square or rectangle, and the maximum protruding length depends on the disposition of the circuit board, and is not limited thereto. Further, the maximum protruding lengths of the step-shaped leads 620 can be the same. Therefore, the solderable area of the step-shaped leads 620 at the sides of the package structure 600 can be consistent. Moreover, the soldering difference is less easily generated when the package structure 600 soldered on the circuit board (not shown), and the package structure 600 can be firmly disposed on the circuit board.

In detail, the plating surfaces 621 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu); the leadframe can be made of an iron-nickel alloy or a copper alloy; the plastic package material 630 can be made of an epoxy resin, but are not limited thereto.

FIG. 34 is a side view of the package structure 600 according to the 6th embodiment in FIG. 31. In FIGS. 33 and 34, a protruding length of a portion of each of the step-shaped leads 620 close to an upper surface 601 of the package structure 600 is smaller than a protruding length of another portion of each of the step-shaped leads 620 close to a lower surface 602 of the package structure 600. Moreover, the portion of each of the step-shaped leads 620 close to the upper surface 601 of the package structure 600 does not protrude an edge of the plastic package material 630, and the protruding length of another portion of each of the step-shaped leads 620 close to the lower surface 602 of the package structure 600 is tapered to the protruding length of the portion of each of the step-shaped leads 620 close to the upper surface 601 of the package structure 600. Furthermore, a protruding width of each of the step-shaped leads 620 is wider, and a thickness of each of the step-shaped leads 620 is thinner, so the burr can be reduced. Further, a concave depth of the concave portion 623 of each of the step-shaped leads 620 can be equal to half of a thickness of another portion of each of the step-shaped leads 620 close to the lower surface 602 of the package structure 600.

Moreover, the protruding length of another portion of each of the step-shaped leads 620 close to the lower surface 602 of the package structure 600 protrudes an edge of the plastic package material 630. Therefore, according to the 6th embodiment, not only can the solderable area of the side of the each of the step-shaped leads 620 be increased, the connection strength between the bottom of the step-shaped leads 620 and the circuit board can also be simultaneously maintained to increase the lifetime of the package structure 600 disposed on the circuit board.

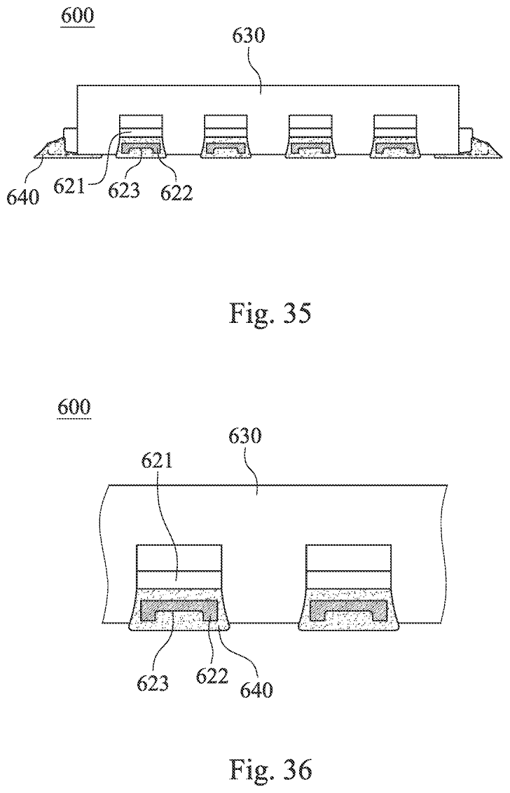

FIG. 35 is a side view of the package structure 600 after soldering according to the 6th embodiment in FIG. 31. FIG. 36 is a partial side view of the package structure 600 after soldering according to the 6th embodiment in FIG. 35. A number of the plating surfaces 621 can be at least four. In FIGS. 33 to 36, according to the 6th embodiment, the number of the plating surfaces 621 is ten, but is not limited thereto. Further, in FIGS. 35 and 36, soldering portions 640 of the package structure 600 can be only disposed on the plating surfaces 621. Therefore, the soldering strength between the package structure 600 and the circuit board is increased when the package structure 600 is disposed on the circuit board because of the enhancement of the solderable area of the side of each of the step-shaped leads 620.

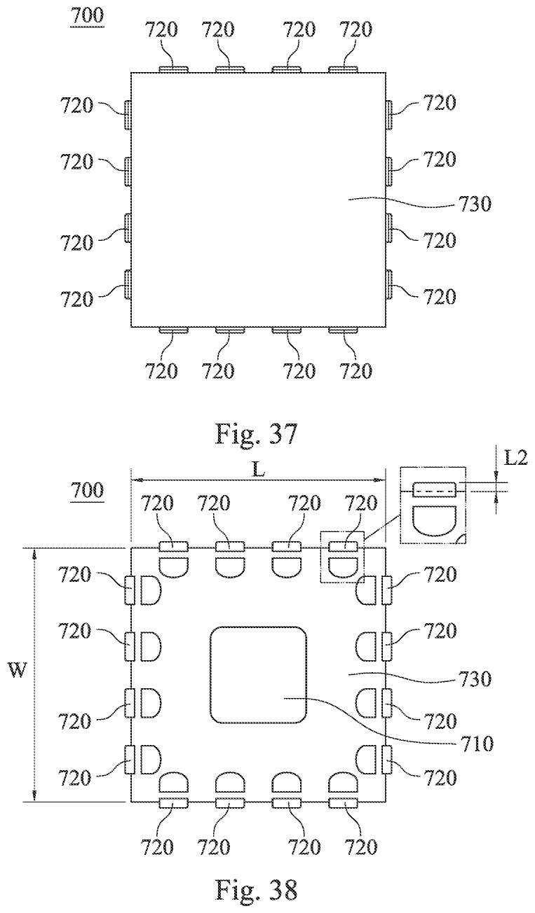

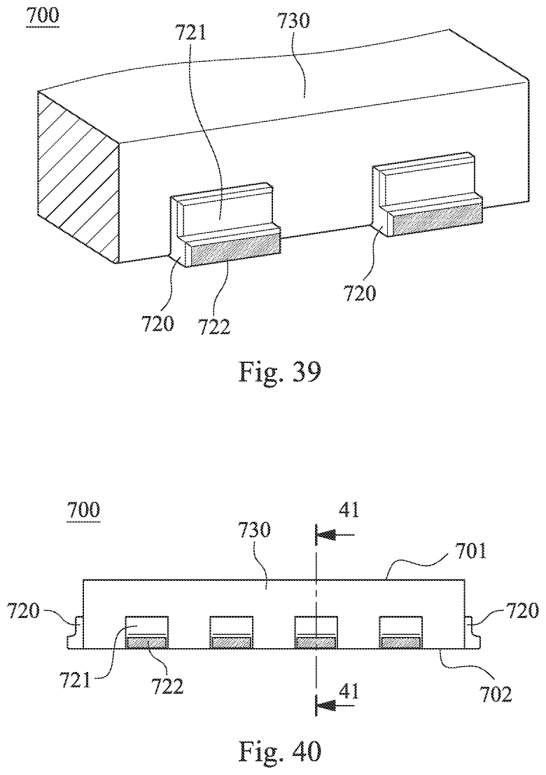

FIG. 37 is a top view of a package structure 700 according to the 7th embodiment of the present disclosure. FIG. 38 is a bottom view of the package structure 700 according to the 7th embodiment in FIG. 37. FIG. 39 is a partial schematic view of the package structure 700 according to the 7th embodiment in FIG. 37. In FIGS. 37 to 39, the package structure 700 includes a leadframe (its reference numeral is omitted), a semiconductor die (not shown) and a plastic package material 730, wherein the leadframe is for carrying the semiconductor die, the plastic package material 730 is disposed on the leadframe, and the semiconductor die is covered via the plastic package material 730 to form the package structure 700.

Moreover, the leadframe includes a die pad 710 and a plurality of leads, wherein each of the leads can be a protruding lead 720, the protruding leads 720 are disposed on four sides of the die pad 710, and each of the protruding leads 720 includes a plurality of plating surfaces 721 and at least one non-plating surface 722, wherein the plating surfaces 721 are disposed on each of the protruding leads 720. The semiconductor die is disposed on the die pad 710 of the leadframe, the plastic package material 730 is disposed on the leadframe, and each of the protruding leads 720 protrudes an outer region of the plastic package material 730. Therefore, the protruding leads 720 are favorable for enhancing the solderable area of sides of the package structure 700.

According to the 7th embodiment, the package structure 700 can be obtained by an etching step, a molding step, a laser step, a plating step and a singulation step. In the etching step, an upper surface of the leadframe is etched. In the molding step, the plastic package material 730 is disposed on and covers the semiconductor die. In the laser step, a portion of the plastic package material 730 on an upper surface of the leadframe is removed via a laser beam. In the plating step, the plating surfaces 721 are disposed on a surface of the leadframe without the plastic package material 730 after the laser step. In the singulation step, the package structure 700 is formed. Moreover, a number of the laser step can be more than two, and it depends on the energy and the parameters of the laser beam, but the aforementioned steps are not limited.

In FIG. 38, when a length of the plastic package material 730 is L, a width of the plastic package material 730 is W, and a maximum protruding length of each of the leads (according to the 7th embodiment, each of the leads is the protruding lead 720) is L2, the following conditions can be satisfied: W≤L, 0.01 W≤L2, and L2≤≤0.5 L. In particular, the plastic package material 730 can be square or rectangle, and the maximum protruding length depends on the disposition of the circuit board, and is not limited thereto. Further, the maximum protruding lengths of the protruding leads 720 can be the same. Therefore, the solderable area of the protruding leads 720 at the sides of the package structure 700 can be consistent. Moreover, the soldering difference is less easily generated when the package structure 700 soldered on the circuit board (not shown), and the package structure 700 can be firmly disposed on the circuit board.

In detail, the plating surfaces 721 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu); the leadframe can be made of an iron-nickel alloy or a copper alloy; the plastic package material 730 can be made of an epoxy resin, but are not limited thereto.

FIG. 40 is a side view of the package structure 700 according to the 7th embodiment in FIG. 37. In FIGS. 39 and 40, a protruding length of a portion of each of the protruding leads 720 close to an upper surface 701 of the package structure 700 is smaller than a protruding length of another portion of each of the protruding leads 720 close to a lower surface 702 of the package structure 700. Furthermore, a protruding width of each of the protruding leads 720 is wider, and a thickness of each of the protruding leads 720 is thinner, so the burr can be reduced.

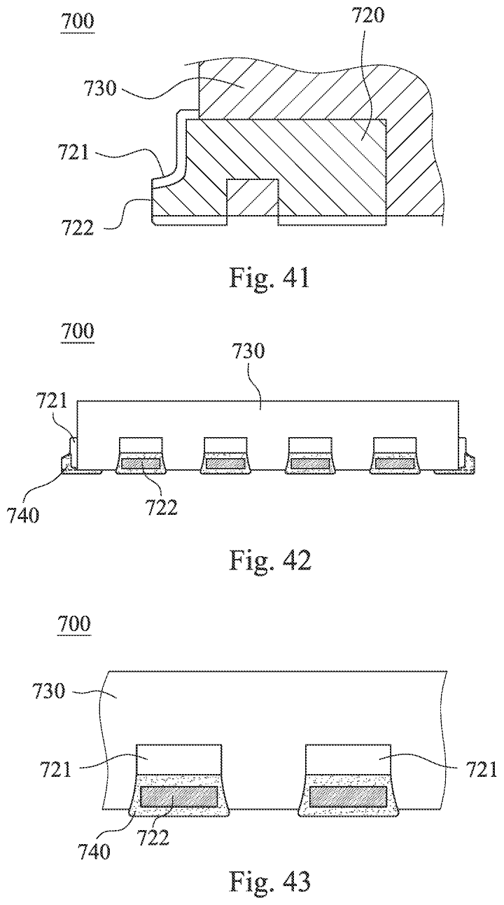

In FIG. 38, not only does the protruding leads 720 protrudes an edge of the plastic package material 730, each of the protruding leads 720 on the lower surface 702 of the package structure 700 also further includes a portion of the plating surfaces 721. FIG. 41 is a cross-sectional schematic view of the package structure 700 along a 41-41 line in FIG. 40. Furthermore, in FIG. 41, a portion of each of the protruding leads 720 protruding the plastic package material 730 and covered via the plastic package material 730 is like gull-wing shape. Therefore, the protruding leads 720 can be more flexible to increase the reliability of the board level. When the plastic package material 730 covers the package structure 700, the mechanical strength of the protruding leads 720 can be more robust. When the solderable area of sides of each of the protruding leads 720 is enhanced, the connection strength of the wire bonding between the semiconductor die and the protruding leads 720 can be simultaneously kept.

FIG. 42 is a side view of the package structure 700 after soldering according to the 7th embodiment in FIG. 37. FIG. 43 is a partial side view of the package structure 700 after soldering according to the 7th embodiment in FIG. 42. A number of the plating surfaces 721 can be at least four. In FIGS. 42 to 43, according to the 7th embodiment, the number of the plating surfaces 721 is seven, but is not limited thereto. Further, in FIGS. 42 and 43, soldering portions 740 of the package structure 700 can be only disposed on the plating surfaces 721. Therefore, the soldering strength between the package structure 700 and the circuit board is increased when the package structure 700 is disposed on the circuit board because of the enhancement of the solderable area of the side of each of the protruding leads 720.

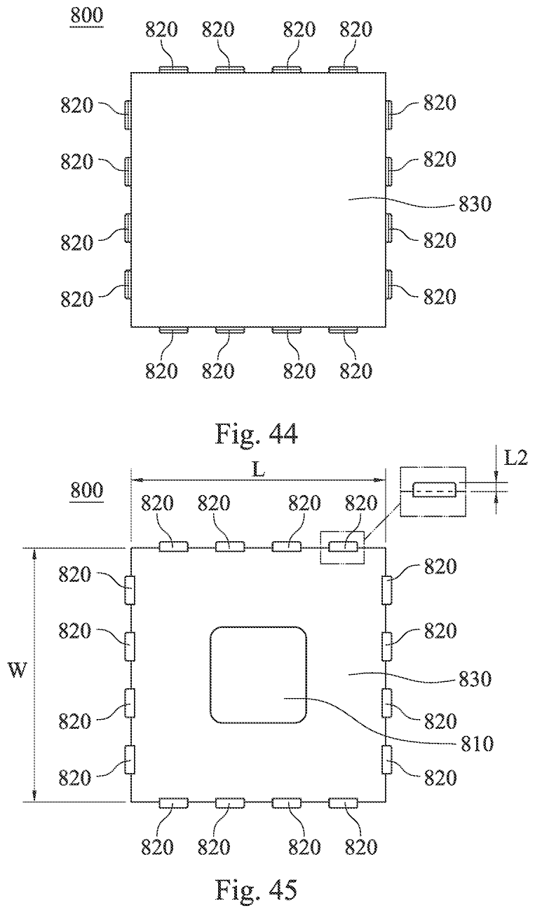

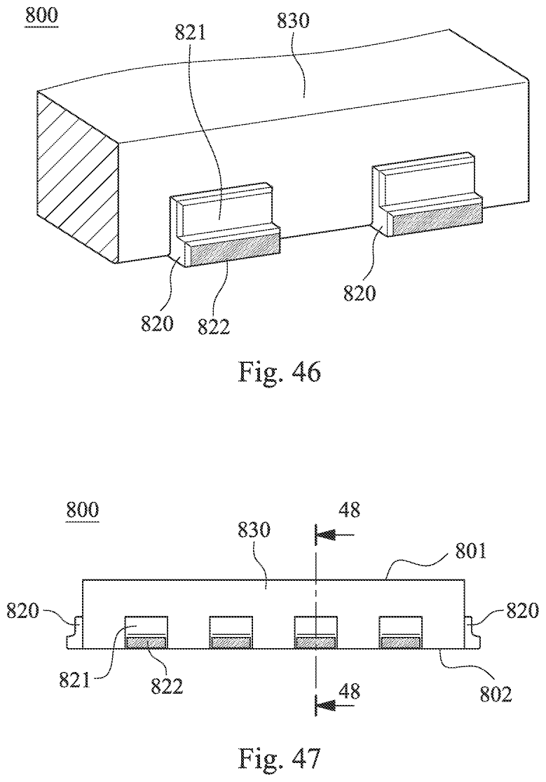

FIG. 44 is a top view of a package structure 800 according to the 8th embodiment of the present disclosure. FIG. 45 is a bottom view of the package structure 800 according to the 8th embodiment in FIG. 44. FIG. 46 is a partial schematic view of the package structure 800 according to the 8th embodiment in FIG. 44. In FIGS. 44 to 46, the package structure 800 includes a leadframe (its reference numeral is omitted), a semiconductor die (not shown) and a plastic package material 830, wherein the leadframe is for carrying the semiconductor die, the plastic package material 830 is disposed on the leadframe, and the semiconductor die is covered via the plastic package material 830 to form the package structure 800.

Moreover, the leadframe includes a die pad 810 and a plurality of leads, wherein each of the leads can be a step-shaped lead 820, the step-shaped leads 820 are disposed on four sides of the die pad 810, and each of the step-shaped leads 820 includes a plurality of plating surfaces 821 and at least one non-plating surface 822. The semiconductor die is disposed on the die pad 810 of the leadframe, the plastic package material 830 is disposed on the leadframe, and each of the step-shaped leads 820 protrudes an outer region of the plastic package material 830. Therefore, the step-shaped leads 820 which protrude sides of the package structure 800 are favorable for enhancing the solderable area of the sides of the package structure 800.

According to the 8th embodiment, the package structure 800 can be obtained by an etching step, a molding step, a laser step, a plating step and a singulation step. In the etching step, an upper surface of the leadframe is etched. In the molding step, the plastic package material 830 is disposed on and covers the semiconductor die. In the laser step, a portion of the plastic package material 830 on an upper surface of the leadframe is removed via a laser beam. In the plating step, the plating surfaces 821 are disposed on a surface of the leadframe without the plastic package material 830 after the laser step. In the singulation step, the package structure 800 is formed. Moreover, a number of the laser step can be more than two, and it depends on the energy and the parameters of the laser beam, but the aforementioned steps are not limited.

In FIG. 45, when a length of the plastic package material 830 is L, a width of the plastic package material 830 is W, and a maximum protruding length of each of the leads (according to the 8th embodiment, each of the leads is the step-shaped lead 820) is L2, the following conditions can be satisfied: W≤L, 0.01 W≤L2, and L2≤≤0.5 L. In particular, the plastic package material 830 can be square or rectangle, and the maximum protruding length depends on the disposition of the circuit board, and is not limited thereto. Further, the maximum protruding lengths of the step-shaped leads 820 can be the same. Therefore, the solderable area of the step-shaped leads 820 at the sides of the package structure 800 can be consistent. Moreover, the soldering difference is less easily generated when the package structure 800 soldered on the circuit board (not shown), and the package structure 800 can be firmly disposed on the circuit board.

In detail, the plating surfaces 821 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu); the leadframe can be made of an iron-nickel alloy or a copper alloy; the plastic package material 830 can be made of an epoxy resin, but are not limited thereto.

FIG. 47 is a side view of the package structure 800 according to the 8th embodiment in FIG. 44. In FIGS. 46 and 47, a protruding length of a portion of each of the step-shaped leads 820 close to an upper surface 801 of the package structure 800 is smaller than a protruding length of another portion of each of the step-shaped leads 820 close to a lower surface 802 of the package structure 800. Furthermore, a protruding width of each of the step-shaped leads 820 is wider, and a thickness of each of the step-shaped leads 820 is thinner, so the burr can be reduced.

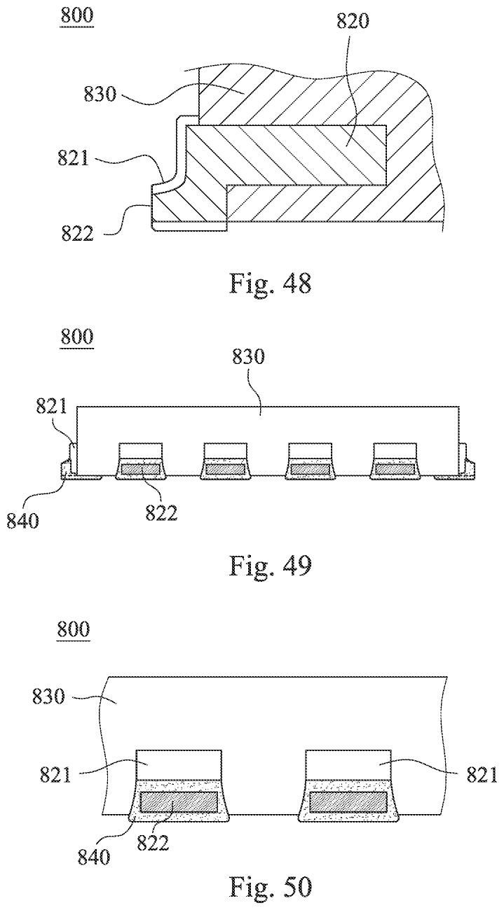

FIG. 48 is a cross-sectional schematic view of the package structure 800 along a 48-48 line in FIG. 47. Furthermore, in FIG. 48, a portion of each of the step-shaped leads 820 protruding the plastic package material 830 and covered via the plastic package material 830 is like gull-wing shape. Therefore, the step-shaped leads 820 can be more flexible to increase the reliability of the board level. When the plastic package material 830 covers the package structure 800, the mechanical strength of the step-shaped leads 820 can be more robust. When the solderable area of sides of each of the step-shaped leads 820 is enhanced, the connection strength of the wire bonding between the semiconductor die and the step-shaped leads 820 can be simultaneously kept.

FIG. 49 is a side view of the package structure 800 after soldering according to the 8th embodiment in FIG. 44. FIG. 50 is a partial side view of the package structure 800 after soldering according to the 8th embodiment in FIG. 49. A number of the plating surfaces 821 can be at least four. In FIGS. 49 to 50, according to the 8th embodiment, the number of the plating surfaces 821 is six, but is not limited thereto. Further, in FIGS. 49 and 50, soldering portions 840 of the package structure 800 can be only disposed on the plating surfaces 821. Therefore, the soldering strength between the package structure 800 and the circuit board is increased when the package structure 800 is disposed on the circuit board because of the enhancement of the solderable area of the side of each of the step-shaped leads 820.

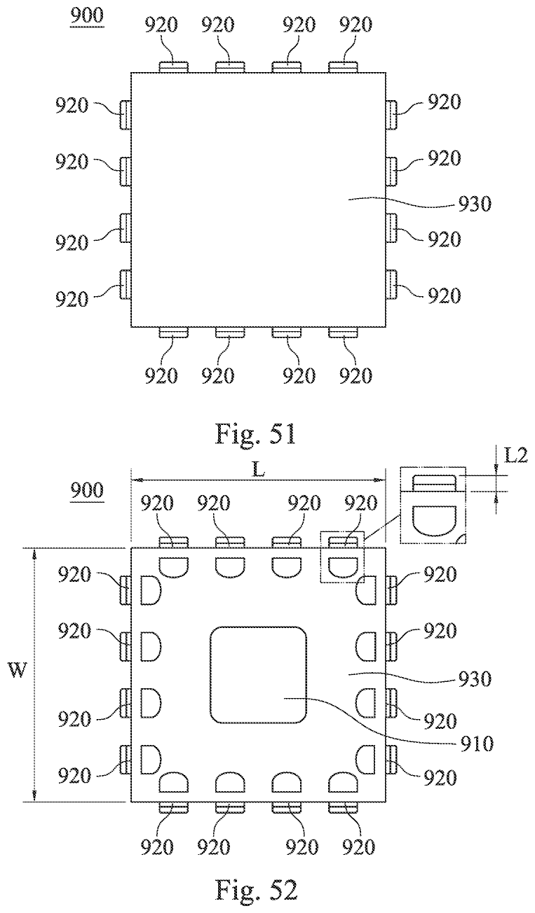

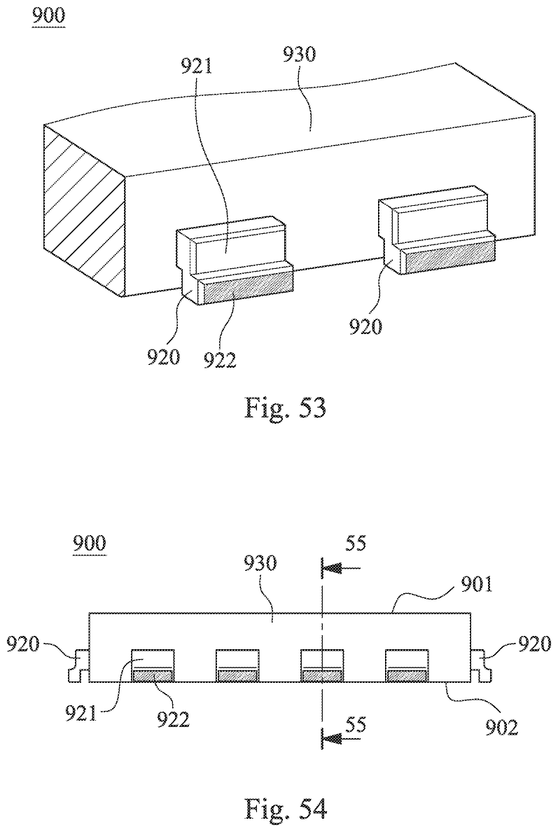

FIG. 51 is a top view of a package structure 900 according to the 9th embodiment of the present disclosure. FIG. 52 is a bottom view of the package structure 900 according to the 9th embodiment in FIG. 51. FIG. 53 is a partial schematic view of the package structure 900 according to the 9th embodiment in FIG. 51. In FIGS. 51 to 53, the package structure 900 includes a leadframe (its reference numeral is omitted), a semiconductor die (not shown) and a plastic package material 930, wherein the leadframe is for carrying the semiconductor die, the plastic package material 930 is disposed on the leadframe, and the semiconductor die is covered via the plastic package material 930 to form the package structure 900.

Moreover, the leadframe includes a die pad 910 and a plurality of leads, wherein each of the leads can be a protruding lead 920, the protruding leads 920 are disposed on four sides of the die pad 910, and each of the protruding leads 920 includes a plurality of plating surfaces 921 and at least one non-plating surface 922, wherein the plating surfaces 921 are disposed on each of the protruding leads 920. The semiconductor die is disposed on the die pad 910 of the leadframe, the plastic package material 930 is disposed on the leadframe, and each of the protruding leads 920 protrudes an outer region of the plastic package material 930. Therefore, the protruding leads 920 are favorable for enhancing the solderable area of sides of the package structure 900.

According to the 9th embodiment, the package structure 900 can be obtained by an etching step, a molding step, two laser steps, a plating step and a singulation step. In the etching step, an upper surface of the leadframe is etched. In the molding step, the plastic package material 930 is disposed on and covers the semiconductor die. In the laser steps, each of a portion of the plastic package material 930 on the upper surface of the leadframe and a portion of the plastic package material 930 on a lower surface of the leadframe is removed via a laser beam. In the plating step, the plating surfaces 921 are disposed on a surface of the leadframe without the plastic package material 930 after the laser steps. In the singulation step, the package structure 900 is formed. Moreover, a number of the laser steps can be more than two, and it depends on the energy and the parameters of the laser beam, but the aforementioned steps are not limited.

In FIG. 52, when a length of the plastic package material 930 is L, a width of the plastic package material 930 is W, and a maximum protruding length of each of the leads (according to the 9th embodiment, each of the leads is the protruding lead 920) is L2, the following conditions can be satisfied: W≤L, 0.01 W≤L2, and L2≤≤0.5 L. In particular, the plastic package material 930 can be square or rectangle, and the maximum protruding length depends on the disposition of the circuit board, and is not limited thereto. Further, the maximum protruding lengths of the protruding leads 920 can be the same. Therefore, the solderable area of the protruding leads 920 at the sides of the package structure 900 can be consistent. Moreover, the soldering difference is less easily generated when the package structure 900 soldered on the circuit board (not shown), and the package structure 900 can be firmly disposed on the circuit board.

In detail, the plating surfaces 921 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu); the leadframe can be made of an iron-nickel alloy or a copper alloy; the plastic package material 930 can be made of an epoxy resin, but are not limited thereto.

FIG. 54 is a side view of the package structure 900 according to the 9th embodiment in FIG. 51. In FIGS. 53 and 54, a protruding length of a portion of each of the protruding leads 920 close to an upper surface 901 of the package structure 900 is smaller than a protruding length of another portion of each of the protruding leads 920 close to a lower surface 902 of the package structure 900. Furthermore, a protruding width of each of the protruding leads 920 is wider, and a thickness of each of the protruding leads 920 is thinner, so the burr can be reduced.

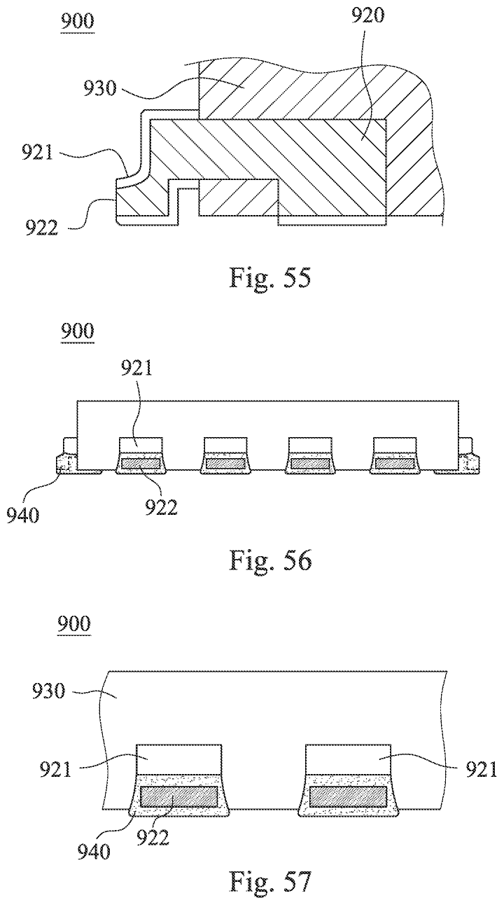

In FIG. 52, not only does each of the protruding leads 920 protrudes an edge of the plastic package material 930, each of the protruding leads 920 on the lower surface 902 of the package structure 900 also further includes a portion of the plating surfaces 921. FIG. 55 is a cross-sectional schematic view of the package structure 900 along a 55-55 line in FIG. 54. Furthermore, in FIGS. 53 to 55, a portion of each of the protruding leads 920 protruding the plastic package material 930 and covered via the plastic package material 930 is like gull-wing shape. Therefore, the protruding leads 920 can be more flexible to increase the reliability of the board level. When the plastic package material 930 covers the package structure 900, the mechanical strength of the protruding leads 920 can be more robust. When the solderable area of sides of each of the protruding leads 920 is enhanced, the connection strength of the wire bonding between the semiconductor die and the protruding leads 920 can be simultaneously kept.

FIG. 56 is a side view of the package structure 900 after soldering according to the 9th embodiment in FIG. 51. FIG. 57 is a partial side view of the package structure 900 after soldering according to the 9th embodiment in FIG. 56. A number of the plating surfaces 921 can be at least four. In FIGS. 56 to 57, according to the 9th embodiment, the number of the plating surfaces 921 is nine, but is not limited thereto. Further, in FIGS. 56 and 57, soldering portions 940 of the package structure 900 can be only disposed on the plating surfaces 921. Therefore, the soldering strength between the package structure 900 and the circuit board is increased when the package structure 900 is disposed on the circuit board because of the enhancement of the solderable area of the side of each of the protruding leads 920.

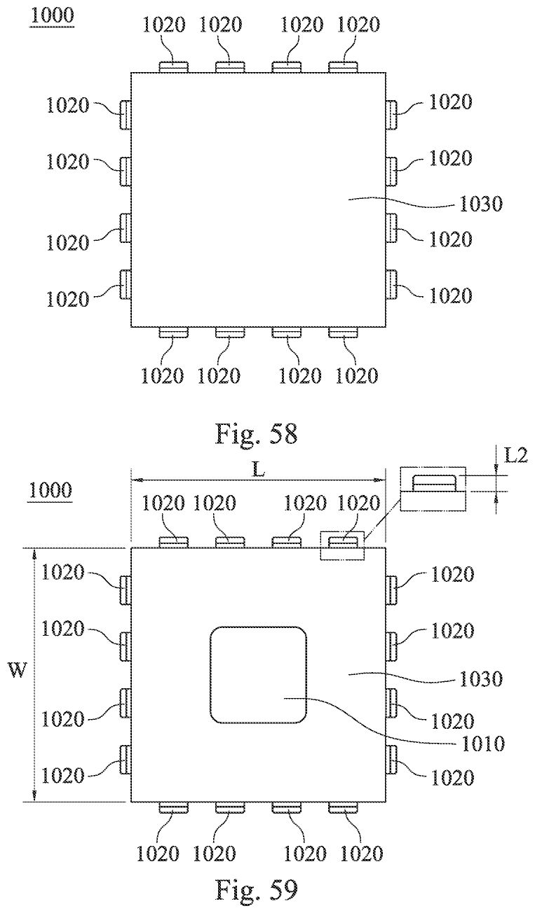

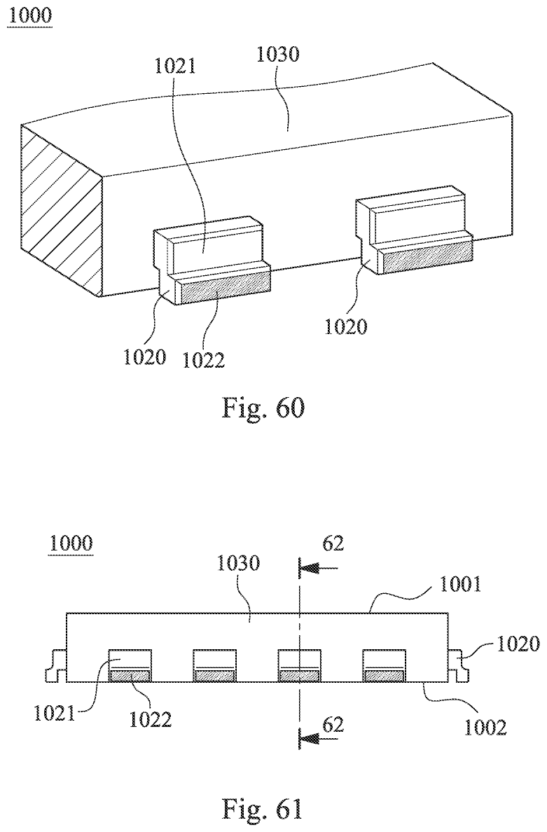

FIG. 58 is a top view of a package structure 1000 according to the 10th embodiment of the present disclosure. FIG. 59 is a bottom view of the package structure 1000 according to the 10th embodiment in FIG. 58. FIG. 60 is a partial schematic view of the package structure 1000 according to the 10th embodiment in FIG. 58. In FIGS. 58 to 60, the package structure 1000 includes a leadframe (its reference numeral is omitted), a semiconductor die (not shown) and a plastic package material 1030, wherein the leadframe is for carrying the semiconductor die, the plastic package material 1030 is disposed on the leadframe, and the semiconductor die is covered via the plastic package material 1030 to form the package structure 1000.

Moreover, the leadframe includes a die pad 1010 and a plurality of leads, wherein each of the leads can be a protruding lead 1020, the protruding leads 1020 are disposed on four sides of the die pad 1010, and each of the protruding leads 1020 includes a plurality of plating surfaces 1021 and at least one non-plating surface 1022, wherein the plating surfaces 1021 are disposed on each of the protruding leads 1020. The semiconductor die is disposed on the die pad 1010 of the leadframe, the plastic package material 1030 is disposed on the leadframe, and each of the protruding leads 1020 protrudes an outer region of the plastic package material 1030. Therefore, the protruding leads 1020 are favorable for enhancing the solderable area of sides of the package structure 1000.

According to the 10th embodiment, the package structure 1000 can be obtained by an etching step, a molding step, two laser steps, a plating step and a singulation step. In the etching step, an upper surface of the leadframe is etched. In the molding step, the plastic package material 1030 is disposed on and covers the semiconductor die. In the laser steps, each of a portion of the plastic package material 1030 on the upper surface of the leadframe and a portion of the plastic package material 1030 on a lower surface of the leadframe is removed via a laser beam. In the plating step, the plating surfaces 1021 are disposed on a surface of the leadframe without the plastic package material 1030 after the laser steps. In the singulation step, the package structure 1000 is formed. Moreover, a number of the laser steps can be more than two, and it depends on the energy and the parameters of the laser beam, but the aforementioned steps are not limited.

In FIG. 59, when a length of the plastic package material 1030 is L, a width of the plastic package material 1030 is W, and a maximum protruding length of each of the leads (according to the 10th embodiment, each of the leads is the protruding lead 1020) is L2, the following conditions can be satisfied: W≤L, 0.01 W≤L2, and L2≤≤0.5 L. In particular, the plastic package material 1030 can be square or rectangle, and the maximum protruding length depends on the disposition of the circuit board, and is not limited thereto. Further, the maximum protruding lengths of the protruding leads 1020 can be the same. Therefore, the solderable area of the protruding leads 1020 at the sides of the package structure 1000 can be consistent. Moreover, the soldering difference is less easily generated when the package structure 1000 soldered on the circuit board (not shown), and the package structure 1000 can be firmly disposed on the circuit board.

In detail, the plating surfaces 1021 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu); the leadframe can be made of an iron-nickel alloy or a copper alloy; the plastic package material 1030 can be made of an epoxy resin, but are not limited thereto.

FIG. 61 is a side view of the package structure 1000 according to the 10th embodiment in FIG. 58. In FIGS. 60 and 61, a protruding length of a portion of each of the protruding leads 1020 close to an upper surface 1001 of the package structure 1000 is smaller than a protruding length of another portion of each of the protruding leads 1020 close to a lower surface 1002 of the package structure 1000. Furthermore, a protruding width of each of the protruding leads 1020 is wider, and a thickness of each of the protruding leads 1020 is thinner, so the burr can be reduced.

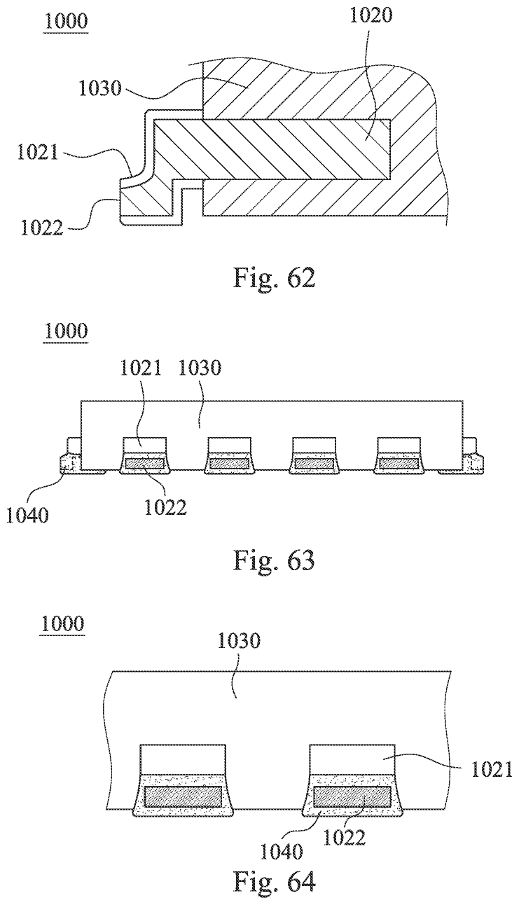

FIG. 62 is a cross-sectional schematic view of the package structure 1000 along a 62-62 line in FIG. 61. Furthermore, in FIG. 62, a portion of each of the protruding leads 1020 protruding the plastic package material 1030 and covered via the plastic package material 1030 is like gull-wing shape. Therefore, the protruding leads 1020 can be more flexible to increase the reliability of the board level. When the plastic package material 1030 covers the package structure 1000, the mechanical strength of the protruding leads 1020 can be more robust. When the solderable area of sides of each of the protruding leads 1020 is enhanced, the connection strength of the wire bonding between the semiconductor die and the protruding leads 1020 can be simultaneously kept.

FIG. 63 is a side view of the package structure 1000 after soldering according to the 10th embodiment in FIG. 58. FIG. 64 is a partial side view of the package structure 1000 after soldering according to the 10th embodiment in FIG. 63. A number of the plating surfaces 1021 can be at least four. In FIGS. 63 to 64, according to the 10th embodiment, the number of the plating surfaces 1021 is eight, but is not limited thereto. Further, in FIGS. 63 and 64, soldering portions 1040 of the package structure 1000 can be only disposed on the plating surfaces 1021. Therefore, the soldering strength between the package structure 1000 and the circuit board is increased when the package structure 1000 is disposed on the circuit board because of the enhancement of the solderable area of the side of each of the protruding leads 1020.

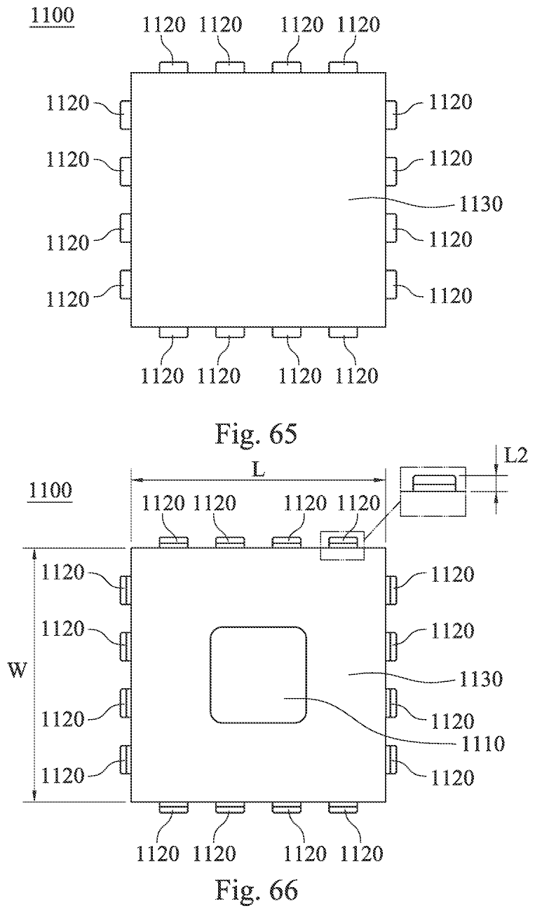

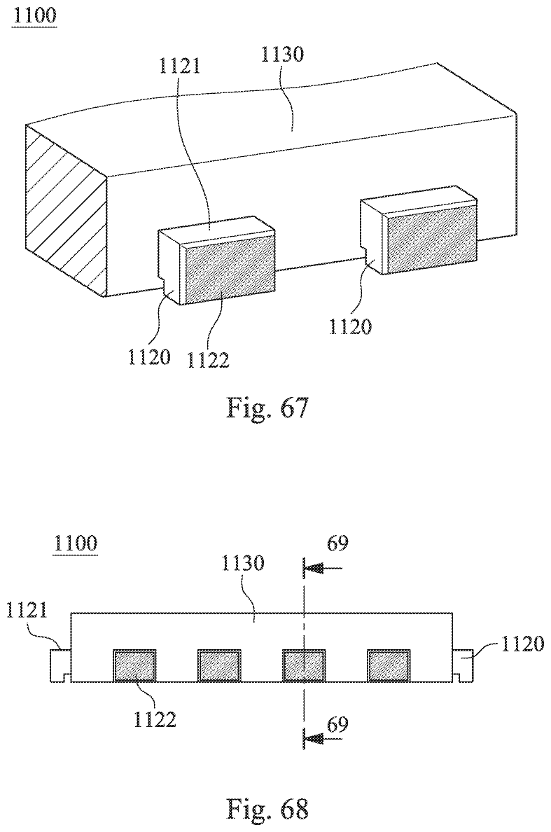

FIG. 65 is a top view of a package structure 1100 according to the 11th embodiment of the present disclosure. FIG. 66 is a bottom view of the package structure 1100 according to the 11th embodiment in FIG. 65. FIG. 67 is a partial schematic view of the package structure 1100 according to the 11th embodiment in FIG. 65. In FIGS. 65 to 67, the package structure 1100 includes a leadframe (its reference numeral is omitted), a semiconductor die (not shown) and a plastic package material 1130, wherein the leadframe is for carrying the semiconductor die, the plastic package material 1130 is disposed on the leadframe, and the semiconductor die is covered via the plastic package material 1130 to form the package structure 1100.

Moreover, the leadframe includes a die pad 1110 and a plurality of leads, wherein each of the leads can be a protruding lead 1120, the protruding leads 1120 are disposed on four sides of the die pad 1110, and each of the protruding leads 1120 includes a plurality of plating surfaces 1121 and at least one non-plating surface 1122, wherein the plating surfaces 1121 are disposed on each of the protruding leads 1120. The semiconductor die is disposed on the die pad 1110 of the leadframe, the plastic package material 1130 is disposed on the leadframe, and each of the protruding leads 1120 protrudes an outer region of the plastic package material 1130. Therefore, the protruding leads 1120 are favorable for enhancing the solderable area of sides of the package structure 1100.

According to the 11th embodiment, the package structure 1100 can be obtained by an etching step, a molding step, two laser steps, a plating step and a singulation step. In the etching step, a lower surface of the leadframe is etched. In the molding step, the plastic package material 1130 is disposed on and covers the semiconductor die. In the laser steps, each of a portion of the plastic package material 1130 on an upper surface of the leadframe and a portion of the plastic package material 1130 on the lower surface of the leadframe is removed via a laser beam. In the plating step, the plating surfaces 1121 are disposed on a surface of the leadframe without the plastic package material 1130 after the laser steps. In the singulation step, the package structure 1100 is formed. Moreover, a number of the laser steps can be more than two, and it depends on the energy and the parameters of the laser beam, but the aforementioned steps are not limited.

In FIG. 66, when a length of the plastic package material 1130 is L, a width of the plastic package material 1130 is W, and a maximum protruding length of each of the leads (according to the 11th embodiment, each of the leads is the protruding lead 1120) is L2, the following conditions can be satisfied: W≤L, 0.01 W≤L2, and L2≤≤0.5 L. In particular, the plastic package material 1130 can be square or rectangle, and the maximum protruding length depends on the disposition of the circuit board, and is not limited thereto. Further, the maximum protruding lengths of the protruding leads 1120 can be the same. Therefore, the solderable area of the protruding leads 1120 at the sides of the package structure 1100 can be consistent. Moreover, the soldering difference is less easily generated when the package structure 1100 soldered on the circuit board (not shown), and the package structure 1100 can be firmly disposed on the circuit board.

In detail, the plating surfaces 1121 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu); the leadframe can be made of an iron-nickel alloy or a copper alloy; the plastic package material 1130 can be made of an epoxy resin, but are not limited thereto.

FIG. 68 is a side view of the package structure 1100 according to the 11th embodiment in FIG. 65. In FIGS. 67 and 68, a protruding width of each of the protruding leads 1120 is wider, so the burr can be reduced.

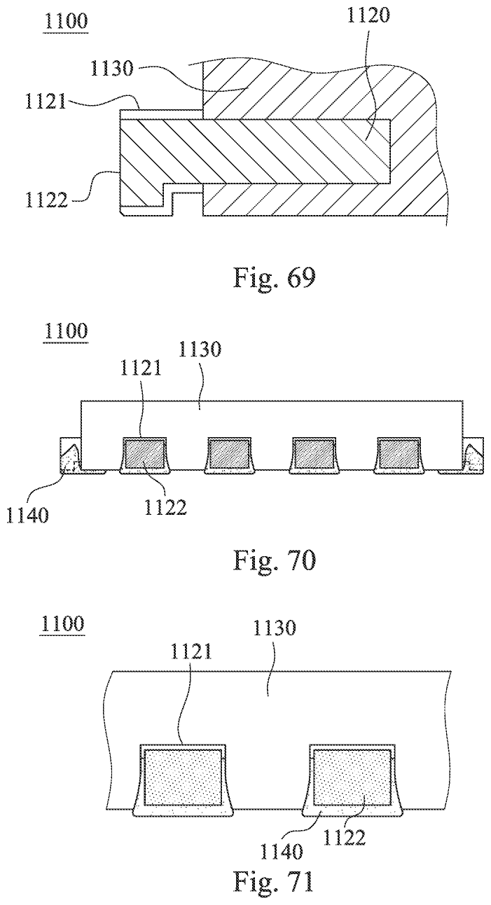

FIG. 69 is a cross-sectional schematic view of the package structure 1100 along a 69-69 line in FIG. 68. Furthermore, in FIG. 69, a portion of each of the protruding leads 1120 protruding the plastic package material 1130 and covered via the plastic package material 1130 is like gull-wing shape. Therefore, the protruding leads 1120 can be more flexible to increase the reliability of the board level. When the plastic package material 1130 covers the package structure 1100, the mechanical strength of the protruding leads 1120 can be more robust. When the solderable area of sides of each of the protruding leads 1120 is enhanced, the connection strength of the wire bonding between the semiconductor die and the protruding leads 1120 can be simultaneously kept.

FIG. 70 is a side view of the package structure 1100 after soldering according to the 11th embodiment in FIG. 65. FIG. 71 is a partial side view of the package structure 1100 after soldering according to the 11th embodiment in FIG. 70. A number of the plating surfaces 1121 can be at least four. In FIGS. 70 to 71, according to the 11th embodiment, the number of the plating surfaces 1121 is six, but is not limited thereto. Further, in FIGS. 70 and 71, soldering portions 1140 of the package structure 1100 can be only disposed on the plating surfaces 1121. Therefore, the soldering strength between the package structure 1100 and the circuit board is increased when the package structure 1100 is disposed on the circuit board because of the enhancement of the solderable area of the side of each of the protruding leads 1120.

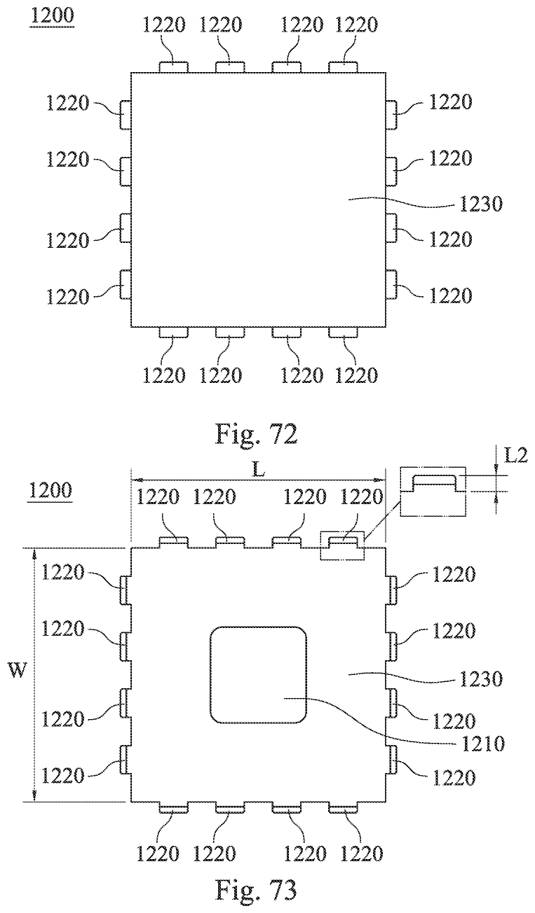

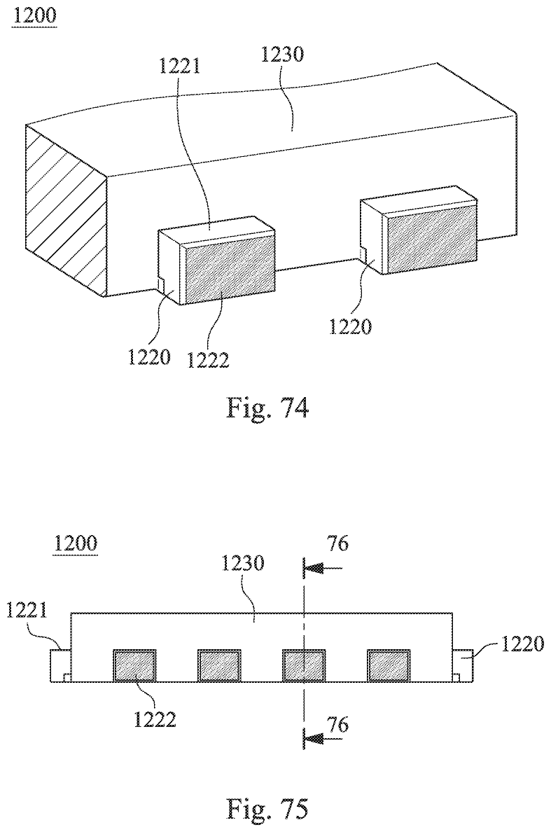

FIG. 72 is a top view of a package structure 1200 according to the 12th embodiment of the present disclosure. FIG. 73 is a bottom view of the package structure 1200 according to the 12th embodiment in FIG. 72. FIG. 74 is a partial schematic view of the package structure 1200 according to the 12th embodiment in FIG. 72. In FIGS. 72 to 74, the package structure 1200 includes a leadframe (its reference numeral is omitted), a semiconductor die (not shown) and a plastic package material 1230, wherein the leadframe is for carrying the semiconductor die, the plastic package material 1230 is disposed on the leadframe, and the semiconductor die is covered via the plastic package material 1230 to form the package structure 1200.

Moreover, the leadframe includes a die pad 1210 and a plurality of leads, wherein each of the leads can be a protruding lead 1220, the protruding leads 1220 are disposed on four sides of the die pad 1210, and each of the protruding leads 1220 includes a plurality of plating surfaces 1221 and at least one non-plating surface 1222, wherein the plating surfaces 1221 are disposed on each of the protruding leads 1220. The semiconductor die is disposed on the die pad 1210 of the leadframe, the plastic package material 1230 is disposed on the leadframe, and each of the protruding leads 1220 protrudes an outer region of the plastic package material 1230. Therefore, the protruding leads 1220 are favorable for enhancing the solderable area of sides of the package structure 1200.

According to the 12th embodiment, the package structure 1200 can be obtained by an etching step, a molding step, a laser step, a plating step and a singulation step. In the etching step, a lower surface of the leadframe is etched. In the molding step, the plastic package material 1230 is disposed on and covers the semiconductor die. In the laser step, a portion of the plastic package material 1230 on an upper surface of the leadframe is removed via a laser beam. In the plating step, the plating surfaces 1221 are disposed on a surface of the leadframe without the plastic package material 1230 after the laser steps. In the singulation step, the package structure 1200 is formed. Moreover, a number of the laser steps can be more than two, and it depends on the energy and the parameters of the laser beam, but the aforementioned steps are not limited.

In FIG. 73, when a length of the plastic package material 1230 is L, a width of the plastic package material 1230 is W, and a maximum protruding length of each of the leads (according to the 12th embodiment, each of the leads is the protruding lead 1220) is L2, the following conditions can be satisfied: W≤L, 0.01 W≤L2, and L2≤≤0.5 L. In particular, the plastic package material 1230 can be square or rectangle, and the maximum protruding length depends on the disposition of the circuit board, and is not limited thereto. Further, the maximum protruding lengths of the protruding leads 1220 can be the same. Therefore, the solderable area of the protruding leads 1220 at the sides of the package structure 1200 can be consistent. Moreover, the soldering difference is less easily generated when the package structure 1200 soldered on the circuit board (not shown), and the package structure 1200 can be firmly disposed on the circuit board.

In detail, the plating surfaces 1221 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu); the leadframe can be made of an iron-nickel alloy or a copper alloy; the plastic package material 1230 can be made of an epoxy resin, but are not limited thereto.

FIG. 75 is a side view of the package structure 1200 according to the 12th embodiment in FIG. 72. In FIGS. 74 and 75, a protruding width of each of the protruding leads 1220 is wider, so the burr can be reduced.

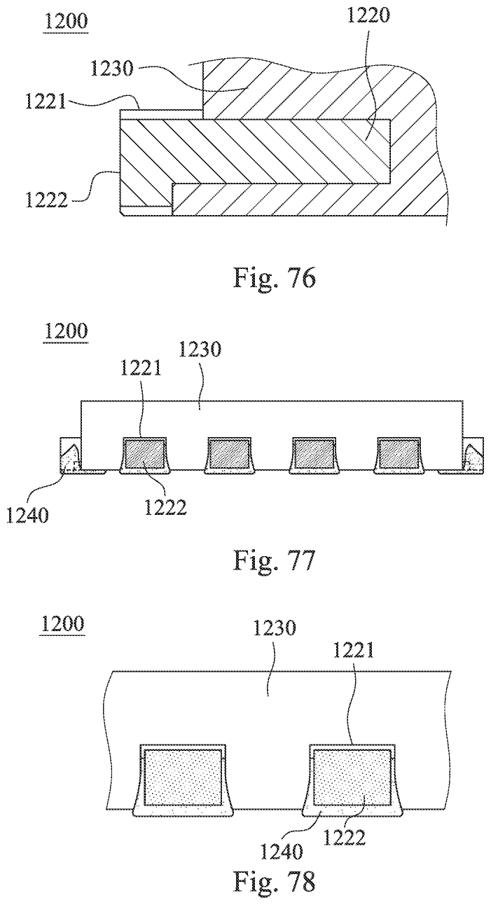

FIG. 76 is a cross-sectional schematic view of the package structure 1200 along a 76-76 line in FIG. 75. In FIG. 76, a portion of each of the protruding leads 1220 protruding the plastic package material 1230 and covered via the plastic package material 1230 is like gull-wing shape. Therefore, the protruding leads 1220 can be more flexible to increase the reliability of the board level. When the plastic package material 1230 covers the package structure 1200, the mechanical strength of the protruding leads 1220 can be more robust. When the solderable area of sides of each of the protruding leads 1220 is enhanced, the connection strength of the wire bonding between the semiconductor die and the protruding leads 1220 can be simultaneously kept.

FIG. 77 is a side view of the package structure 1200 after soldering according to the 12th embodiment in FIG. 72. FIG. 78 is a partial side view of the package structure 1200 after soldering according to the 12th embodiment in FIG. 77. A number of the plating surfaces 1221 can be at least four. In FIGS. 77 to 78, according to the 12th embodiment, the number of the plating surfaces 1221 is four, but is not limited thereto. Further, in FIGS. 77 and 78, soldering portions 1240 of the package structure 1200 can be only disposed on the plating surfaces 1221. Therefore, the soldering strength between the package structure 1200 and the circuit board is increased when the package structure 1200 is disposed on the circuit board because of the enhancement of the solderable area of the side of each of the protruding leads 1220.

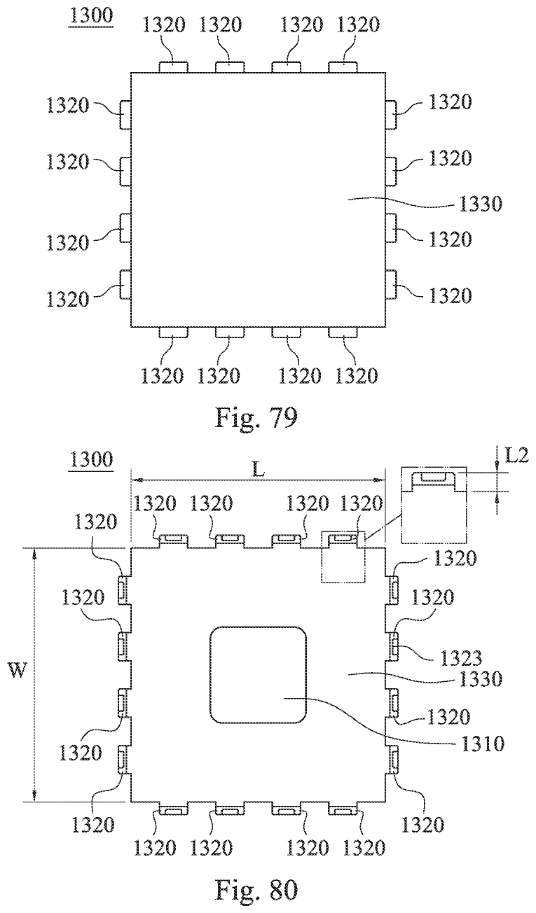

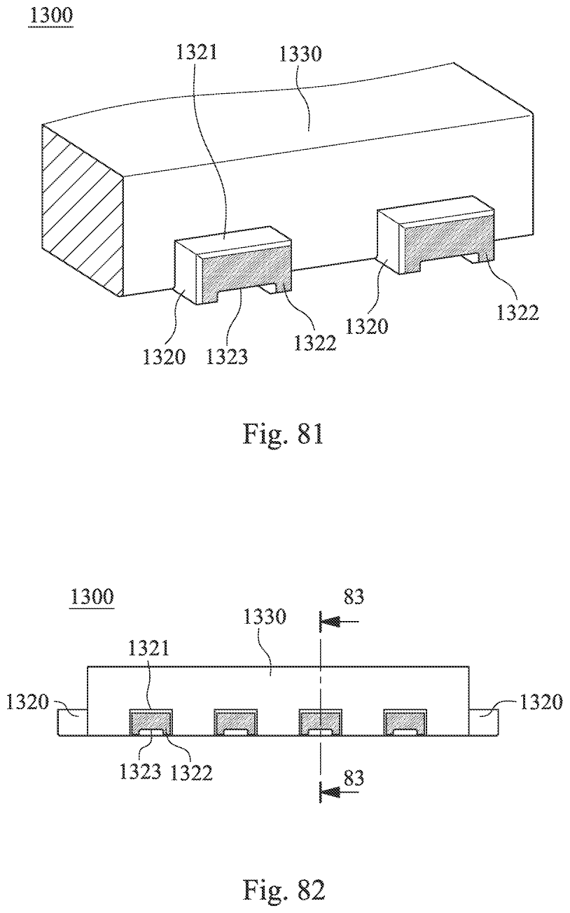

FIG. 79 is a top view of a package structure 1300 according to the 13th embodiment of the present disclosure. FIG. 80 is a bottom view of the package structure 1300 according to the 13th embodiment in FIG. 79. FIG. 81 is a partial schematic view of the package structure 1300 according to the 13th embodiment in FIG. 79. In FIGS. 79 to 81, the package structure 1300 includes a leadframe (its reference numeral is omitted), a semiconductor die (not shown) and a plastic package material 1330, wherein the leadframe is for carrying the semiconductor die, the plastic package material 1330 is disposed on the leadframe, and the semiconductor die is covered via the plastic package material 1330 to form the package structure 1300.

Moreover, the leadframe includes a die pad 1310 and a plurality of leads, wherein each of the leads can be a protruding lead 1320, the protruding leads 1320 are disposed on four sides of the die pad 1310, and each of the protruding leads 1320 includes a plurality of plating surfaces 1321, at least one non-plating surface 1322 and a concave portion 1323, wherein the concave portion 1323 is located on a surface of each of the protruding lead 1320, and the plating surfaces 1321 are disposed on each of the protruding leads 1320 and the concave portion 1323. The semiconductor die is disposed on the die pad 1310 of the leadframe, the plastic package material 1330 is disposed on the leadframe, and each of the protruding leads 1320 protrudes an outer region of the plastic package material 1330. Therefore, the protruding leads 1320 are favorable for enhancing the solderable area of sides of the package structure 1300.

According to the 13th embodiment, the package structure 1300 can be obtained by an etching step, a molding step, a laser step, a plating step and a singulation step. In the etching step, a lower surface of the leadframe is etched. In the molding step, the plastic package material 1330 is disposed on and covers the semiconductor die. In the laser step, a portion of the plastic package material 1330 on an upper surface of the leadframe is removed via a laser beam. In the plating step, the plating surfaces 1321 are disposed on a surface of the leadframe without the plastic package material 1330 after the laser step. In the singulation step, the package structure 1300 is formed. Moreover, a number of the laser step can be more than two, and it depends on the energy and the parameters of the laser beam, but the aforementioned steps are not limited.

In FIG. 80, when a length of the plastic package material 1330 is L, a width of the plastic package material 1330 is W, and a maximum protruding length of each of the leads (according to the 13th embodiment, each of the leads is the protruding lead 1320) is L2, the following conditions can be satisfied: W≤L, 0.01 W≤L2, and L2≤≤0.5 L. In particular, the plastic package material 1330 can be square or rectangle, and the maximum protruding length depends on the disposition of the circuit board, and is not limited thereto. Further, the maximum protruding lengths of the protruding leads 1320 can be the same. Therefore, the solderable area of the protruding leads 1320 at the sides of the package structure 1300 can be consistent. Moreover, the soldering difference is less easily generated when the package structure 1300 soldered on the circuit board (not shown), and the package structure 1300 can be firmly disposed on the circuit board.

In detail, the plating surfaces 1321 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu); the leadframe can be made of an iron-nickel alloy or a copper alloy; the plastic package material 1330 can be made of an epoxy resin, but are not limited thereto.

FIG. 82 is a side view of the package structure 1300 according to the 13th embodiment in FIG. 79. In FIGS. 81 and 82, a protruding width of each of the protruding leads 1320 is wider, so the burr can be reduced. Further, a concave depth of the concave portion 1323 of each of the protruding leads 1320 can be smaller than half of a thickness of the protruding leads 1320.

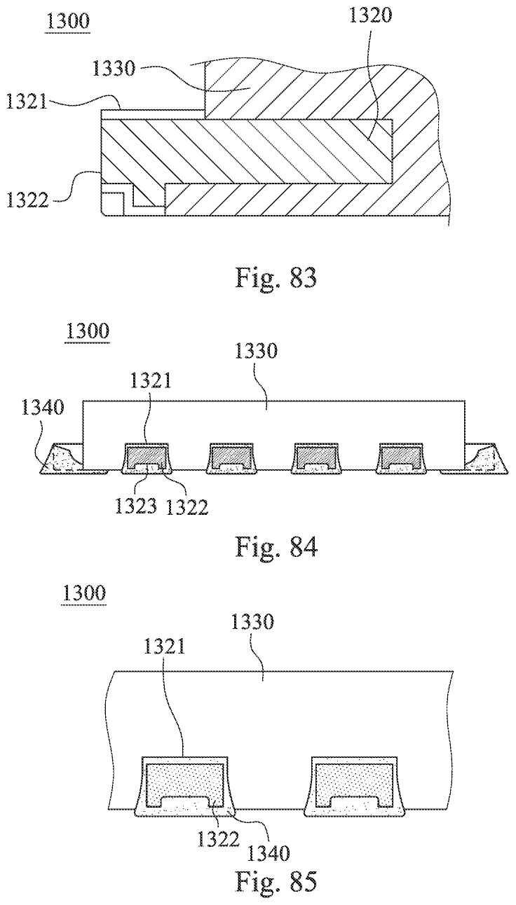

FIG. 83 is a cross-sectional schematic view of the package structure 1300 along an 83-83 line in FIG. 82. In FIG. 83, a portion of each of the protruding leads 1320 protruding the plastic package material 1330 and covered via the plastic package material 1330 is like gull-wing shape. Therefore, the protruding leads 1320 can be more flexible to increase the reliability of the board level. When the plastic package material 1330 covers the package structure 1300, the mechanical strength of the protruding leads 1320 can be more robust. When the solderable area of sides of each of the protruding leads 1320 is enhanced, the connection strength of the wire bonding between the semiconductor die and the protruding leads 1320 can be simultaneously kept.

FIG. 84 is a side view of the package structure 1300 after soldering according to the 13th embodiment in FIG. 79. FIG. 85 is a partial side view of the package structure 1300 after soldering according to the 13th embodiment in FIG. 84. A number of the plating surfaces 1321 can be at least four. In FIGS. 84 to 85, according to the 13th embodiment, the number of the plating surfaces 1321 is eight, but is not limited thereto. Further, in FIGS. 84 and 85, soldering portions 1340 of the package structure 1300 can be only disposed on the plating surfaces 1321. Therefore, the soldering strength between the package structure 1300 and the circuit board is increased when the package structure 1300 is disposed on the circuit board because of the enhancement of the solderable area of the side of each of the protruding leads 1320.

In summary, it is favorable for enhancing the solderable area via the package structure of the present disclosure, and the soldering strength between the circuit board and the package structure can be further enhanced. Moreover, the package structure can be firmly disposed on the circuit board after soldering. Therefore, it is favorable for increasing the lifetime of the package structure disposed on the circuit board to enhance the reliability of the board level.

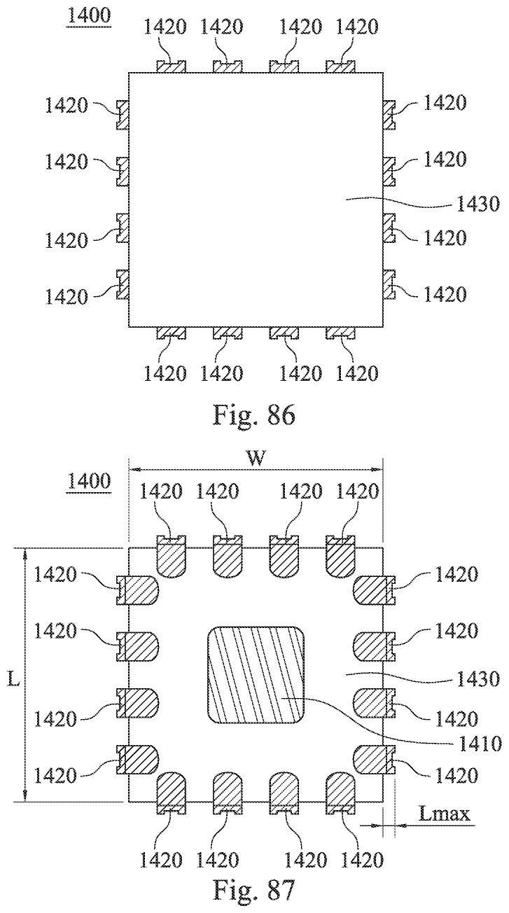

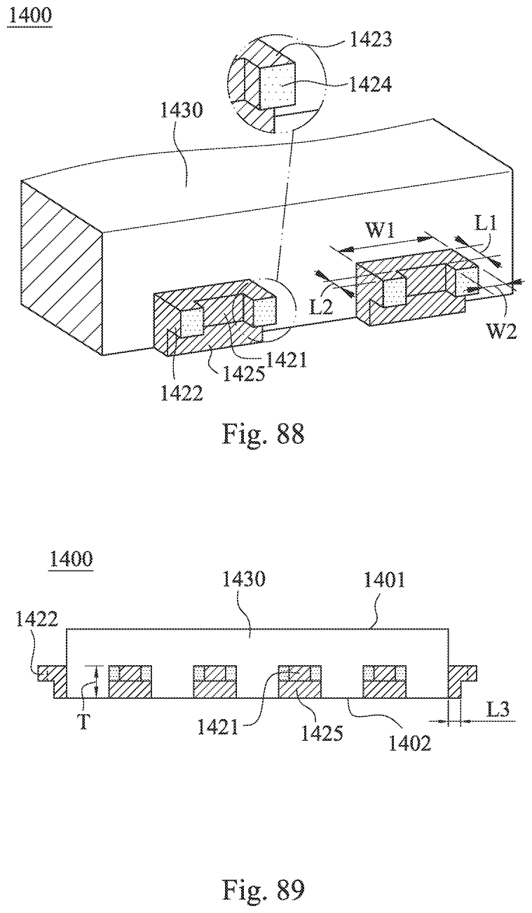

FIG. 86 is a top view of a package structure 1400 according to the 14th embodiment of the present disclosure. FIG. 87 is a bottom view of the package structure 1400 according to the 14th embodiment in FIG. 86. FIG. 88 is a partial schematic view of the package structure 1400 according to the 14th embodiment in FIG. 86. FIG. 89 is a side view of the package structure 1400 according to the 14th embodiment in FIG. 86. In FIGS. 86 to 89, the package structure 1400 has an upper surface 1401 and a lower surface 1402, and includes leadframe (its reference numeral is omitted), a semiconductor die (not shown) and a plastic package material 1430, wherein the leadframe is for carrying the semiconductor die, the plastic package material 1430 is disposed on the leadframe, and the semiconductor die is covered via the plastic package material 1430 to form the package structure 1400.

The leadframe includes a die pad 1410 and a plurality of leads 1420, wherein the semiconductor die is disposed on the die pad 1410 of the leadframe, the leads 1420 are disposed on four peripheral regions of the die pad 1410, and each of the leads 1420 includes a main body 1421, at least one extending portion 1422, a plurality of plating surfaces 1423, at least one non-plating surface 1424 and a protruding portion 1425.

The extending portion 1422 is connected to the main body 1421, the protruding portion 1425 is connected to the main body 1421, and the main body 1421, the extending portion 1422 and the protruding portion 1425 are integrally formed, wherein the plating surfaces 1423 are disposed on the main body 1421, the extending portion 1422 and the protruding portion 1425, and the non-plating surface 1424 is disposed on the extending portion 1422. The main body 1421, the extending portion 1422 and the protruding portion 1425 of each of the leads 1420 protrude a peripheral region of the plastic package material 1430, and the main body 1421 and the extending portion 1422 are farther from the lower surface 1402 of the package structure 1400 than the protruding portion 1425 from the lower surface 1402 of the package structure 1400. Therefore, the leads 1420 which protrude an outer periphery of the plastic package material 1430 are favorable for enhancing the solderable area of sides of the package structure 1400. Moreover, the thermal cycle life of board level can be enhanced over 20% by the package structure 1400 compared with the package structure, of which the leads do not protrude the outer periphery of the plastic package material, of prior art.

According to the 14th embodiment, a number of the extending portion 1422 of each of the leads 1420 is two, a number of the plating surfaces 1423 of each of the leads 1420 is nine, a number of the non-plating surface 1424 of each of the leads 1420 is two, and each of the leads 1420 is a step-shaped lead. Furthermore, the plating surfaces 1423 can be made of a tin alloy or a nickel-gold alloy, wherein the nickel-gold alloy can be nickel-palladium-gold (NiPdAu), nickel-palladium-silver-gold (NiPdAgAu) or nickel-gold (NiAu), the leadframe can be made of an iron-nickel alloy or a copper alloy, and the plastic package material 1430 can be made of an epoxy resin, but are not limited thereto.

According to the 14th embodiment, the package structure 1400 can be obtained by an etching step, a molding step, a laser step, a plating step and a singulation step, but the present disclosure is not limited thereto. In the etching step, a lower surface of the leadframe is etched. In the molding step, the plastic package material 1430 is disposed on and covers the semiconductor die. In the laser step, a portion of the plastic package material 1430 on an upper surface and the lower surface of the leadframe is removed via a laser beam. In the plating step, the plating surfaces 1423 are disposed on a surface of the leadframe without the plastic package material 1430 after the laser steps. In the singulation step, the package structure 1400 is formed. Moreover, a number of the laser steps can be more than two, and it depends on the energy and the parameters of the laser beam, but the aforementioned steps are not limited.

In FIG. 87, when a length of the package structure 1400 is L, a width of the package structure 1400 is W, and a maximum protruding length of each of the leads 1420 is Lmax, the following conditions are satisfied: W≤0.01 W≤Lmax; and Lmax≤0.5 L. In particular, the plastic package material 1430 can be square or rectangle, and the maximum protruding length depends on the disposition of the circuit board, and is not limited thereto. Further, the maximum protruding lengths of the leads 1420 can be the same. Therefore, the solderable area of the leads 1420 at the sides of the package structure 1400 can be consistent. Moreover, the soldering difference is less easily generated when the package structure 1400 soldered on the circuit board (not shown), and the package structure 1400 can be firmly disposed on the circuit board.

In FIGS. 87 to 89, when an extending length of the main body 1421 is L1, an extending length of each of the extending portions 1422 is L2, an extending length of the protruding portion 1425 is L3, a width of the main body 1421 is W1, a width of each of the extending portions 1422 is W2, a thickness of each of the leads 1420 is T, the length of the package structure 1400 is L, and the maximum protruding length of each of the leads 1420 is Lmax, the following conditions are satisfied: 0<L2≤0.5 L; 0<L3≤≤0.5 L; 0.25 T≤W2<W1, and 0<Lmax=L1+L2. Therefore, the structural stability of the leads 1420 can be maintained, and the condition of insufficient soldering on sides of the leads is not easily happened so as to enhance the reliability.

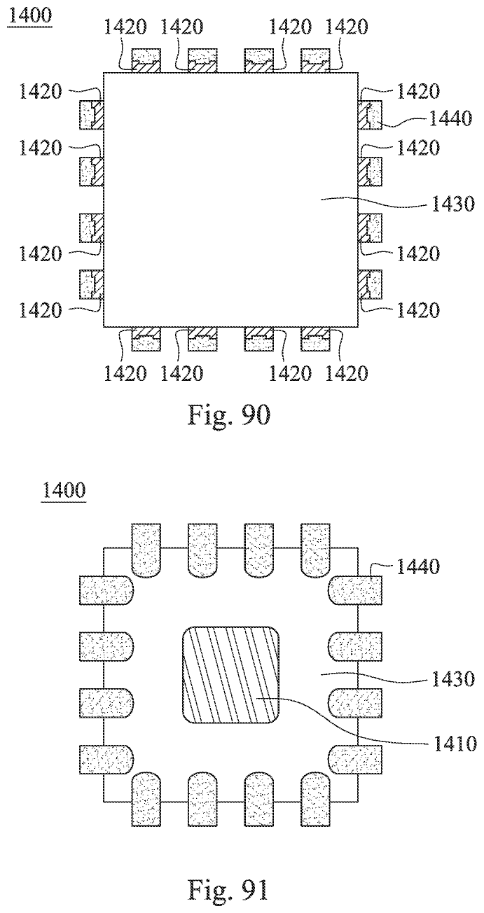

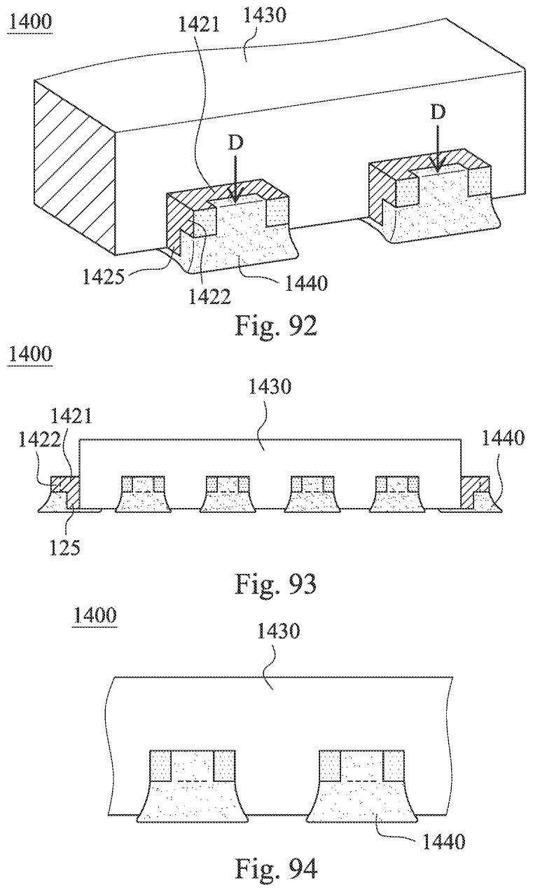

FIG. 90 is a top view of the package structure 1400 after soldering according to the 14th embodiment in FIG. 86. FIG. 91 is a bottom view of the package structure 1400 after soldering according to the 14th embodiment in FIG. 86. FIG. 92 is a partial side view of the package structure 1400 after soldering according to the 14th embodiment in FIG. 86. FIG. 93 is a side view of the package structure 1400 after soldering according to the 14th embodiment in FIG. 86. FIG. 94 is a partial side view of the package structure 1400 after soldering according to the 14th embodiment in FIG. 93. In FIGS. 90 to 94, soldering portions 1440 can be only disposed on the plating surfaces 1423, wherein the soldering portions 1440 are contacted with the main body 1421, the extending portions 1422 and the protruding portion 1425, which the plating surfaces 1423 are disposed on. Therefore, the solderable area of a bottom of the package structure 1400 can be maintained, and the solderable area of the sides of the package structure 1400 can be simultaneously enhanced, so that the soldering strength between the package structure 1400 and the circuit board can be enhanced.

In FIG. 92, the inspectors can check the soldering condition from a detecting direction D via an automated optical inspection (AOI) after the soldering process of the package structure 1400. In particular, the detecting direction D is a direction from the upper surface 1401 to the lower surface 1402 of the package structure 1400, and the inspectors can directly check the soldering condition from a top-down perspective. By operating the AOI from the top-down perspective, the detecting efficiency can be enhanced.

It should be mentioned that the disposing position of the soldering portion 1440 in FIGS. 90 to 94 is only configured to illustrate that the soldering portion 1440 is only disposed on the plating surfaces 1423 rather than the non-plating surfaces 1424, but the disposing position of the soldering portion 1440 is not limited to FIGS. 90 to 94.

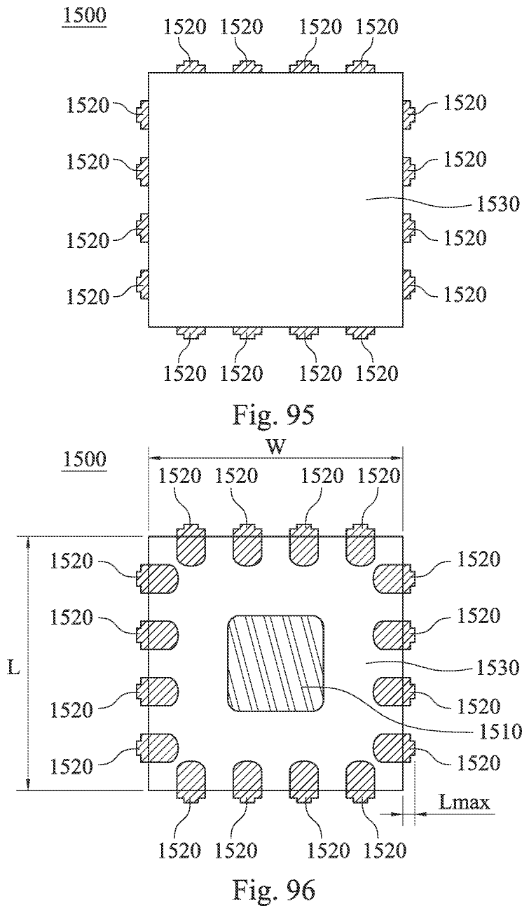

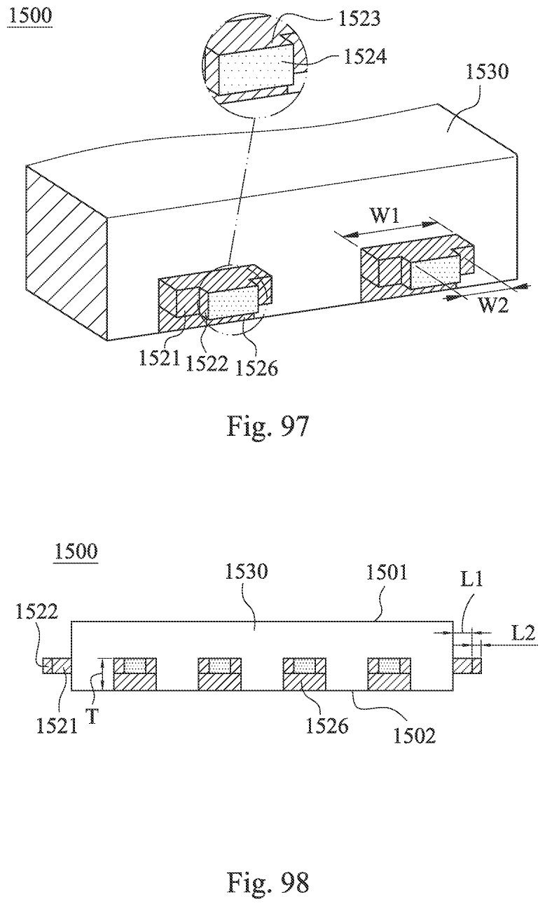

FIG. 95 is a top view of a package structure 1500 according to the 15th embodiment of the present disclosure. FIG. 96 is a bottom view of the package structure 1500 according to the 15th embodiment in FIG. 95. FIG. 97 is a partial schematic view of the package structure 1500 according to the 15th embodiment in FIG. 95. FIG. 98 is a side view of the package structure 1500 according to the 15th embodiment in FIG. 95. In FIGS. 95 to 98, the package structure 1500 has an upper surface 1501 and a lower surface 1502, and includes leadframe (its reference numeral is omitted), a semiconductor die (not shown) and a plastic package material 1530, wherein the leadframe is for carrying the semiconductor die, the plastic package material 1530 is disposed on the leadframe, and the semiconductor die is covered via the plastic package material 1530 to form the package structure 1500.

The leadframe includes a die pad 1510 and a plurality of leads 1520, wherein the semiconductor die is disposed on the die pad 1510 of the leadframe, the leads 1520 are disposed on four peripheral regions of the die pad 1510, and each of the leads 1520 includes a main body 1521, at least one extending portion 1522, a plurality of plating surfaces 1523, at least one non-plating surface 1524 and a plane portion 1526.

The extending portion 1522 is connected to the main body 1521, the plane portion 1526 is connected to the main body 1521, and the main body 1521, the extending portion 1522 and the plane portion 1526 are integrally formed, wherein the plating surfaces 1523 are disposed on the main body 1521, the extending portion 1522 and the plane portion 1526, and the non-plating surface 1524 is disposed on the extending portion 1522. The main body 1521 and the extending portion 1522 of each of the leads 1520 protrude a peripheral region of the plastic package material 1530, and the main body 1521 and the extending portion 1522 are farther from the lower surface 1502 of the package structure 1500 than the plane portion 1526 from the lower surface 1502 of the package structure 1500. Therefore, the leads 1520 which protrude an outer periphery of the plastic package material 1530 are favorable for enhancing the solderable area of sides of the package structure 1500. Moreover, the thermal cycle life of board level can be enhanced over 20% by the package structure 1500 compared with the package structure, of which the leads do not protrude the outer periphery of the plastic package material, of prior art.

According to the 15th embodiment, a number of the extending portion 1522 of each of the leads 1520 is one, a number of the plating surfaces 1523 of each of the leads 1520 is ten, a number of the non-plating surface 1524 of each of the leads 1520 is one, and each of the leads 1520 is a step-shaped lead.

According to the 15th embodiment, the package structure 1500 can be obtained by an etching step, a molding step, a laser step, a plating step and a singulation step, but the present disclosure is not limited thereto. In the etching step, a lower surface of the leadframe is etched. In the molding step, the plastic package material 1530 is disposed on and covers the semiconductor die. In the laser step, a portion of the plastic package material 1530 on an upper surface and the lower surface of the leadframe is removed via a laser beam. In the plating step, the plating surfaces 1523 are disposed on a surface of the leadframe without the plastic package material 1530 after the laser steps. In the singulation step, the package structure 1500 is formed. Moreover, a number of the laser steps can be more than two, and it depends on the energy and the parameters of the laser beam, but the aforementioned steps are not limited.

In FIG. 96, when a length of the package structure 1500 is L, a width of the package structure 1500 is W, and a maximum protruding length of each of the leads 1520 is Lmax, the following conditions are satisfied: W≤L; 0.01 W≤Lmax; and Lmax≤0.5 L. In particular, the plastic package material 1530 can be square or rectangle, and the maximum protruding length depends on the disposition of the circuit board, and is not limited thereto. Further, the maximum protruding lengths of the leads 1520 can be the same. Therefore, the solderable area of the leads 1520 at the sides of the package structure 1500 can be consistent. Moreover, the soldering difference is less easily generated when the package structure 1500 soldered on the circuit board (not shown), and the package structure 1500 can be firmly disposed on the circuit board.

In FIGS. 96 to 98, when an extending length of the main body 1521 is L1, an extending length of the extending portion 1522 is L2, a width of the main body 1521 is W1, a width of the extending portion 1522 is W2, a thickness of each of the leads 1520 is T, the length of the package structure 1500 is L, and the maximum protruding length of each of the leads 1520 is Lmax, the following conditions are satisfied: 0<L2≤0.5 L; 0.25 T≤W2<W1, and 0<Lmax=L1+L2. Therefore, the structural stability of the leads 1520 can be maintained, and the condition of insufficient soldering on sides of the leads is not easily happened.

Moreover, the portion of each of the leads 1520 close to the lower surface 1502 of the package structure 1500 does not protrude an edge of the plastic package material 1530. Therefore, according to the 15th embodiment, the POD does not need to be changed, and the process of redrawing the POD can be reduced.

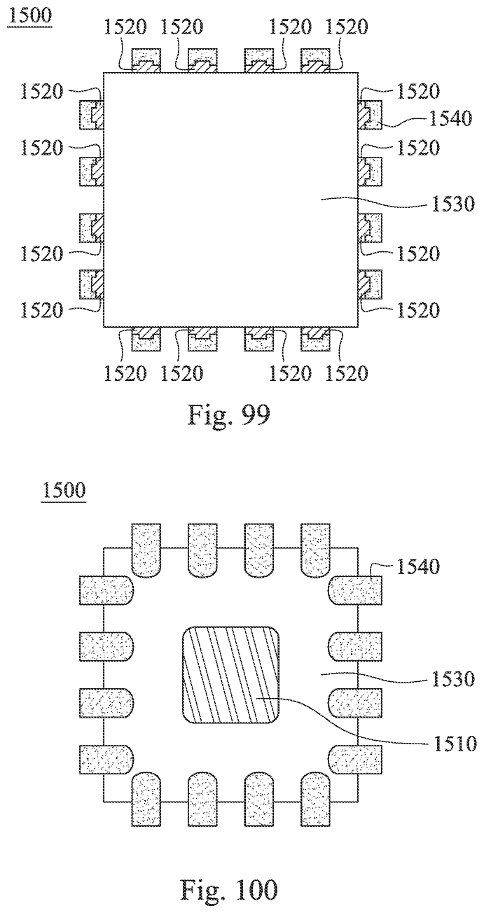

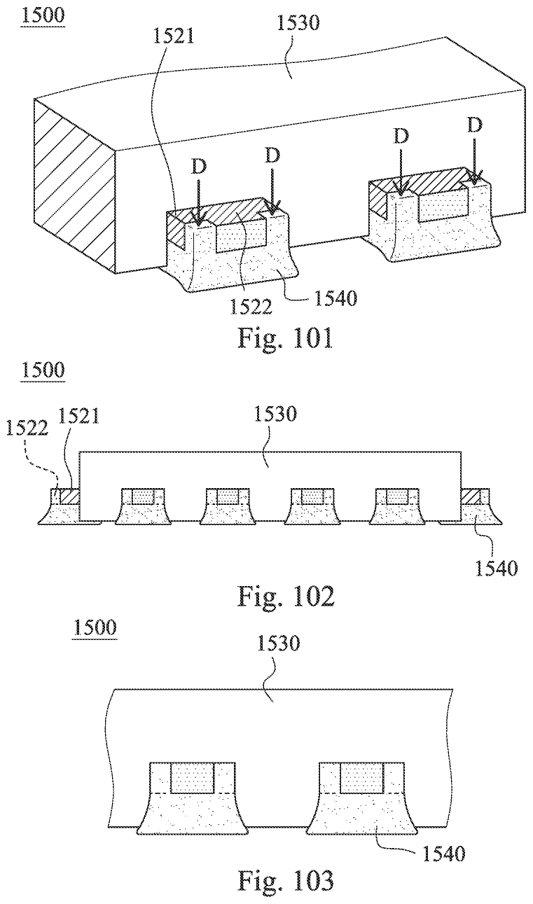

FIG. 99 is a top view of the package structure 1500 after soldering according to the 15th embodiment in FIG. 95. FIG. 100 is a bottom view of the package structure 1500 after soldering according to the 15th embodiment in FIG. 95. FIG. 101 is a partial side view of the package structure 1500 after soldering according to the 15th embodiment in FIG. 95. FIG. 102 is a side view of the package structure 1500 after soldering according to the 15th embodiment in FIG. 95. FIG. 103 is a partial side view of the package structure 1500 after soldering according to the 15th embodiment in FIG. 102. In FIGS. 99 to 103, soldering portions 1540 can be only disposed on the plating surfaces 1523, wherein the soldering portions 1540 are contacted with the main body 1521, the extending portion 1522 and the plane portion 1526, which the plating surfaces 1523 are disposed on. Therefore, the solderable area of a bottom of the package structure 1500 can be maintained, and the solderable area of the sides of the package structure 1500 can be simultaneously enhanced, so that the soldering strength between the package structure 1500 and the circuit board can be enhanced.

In FIG. 101, the inspectors can check the soldering condition from a detecting direction D via an AOI after the soldering process of the package structure 1500. In particular, the detecting direction D is a direction from the upper surface 1501 to the lower surface 1502 of the package structure 1500, and the inspectors can directly check the soldering condition from a top-down perspective. By operating the AOI from the top-down perspective, the detecting efficiency can be enhanced.

Further, all of other structures and dispositions according to the 15th embodiment are the same as the structures and the dispositions according to the 14th embodiment, and will not be described again herein.

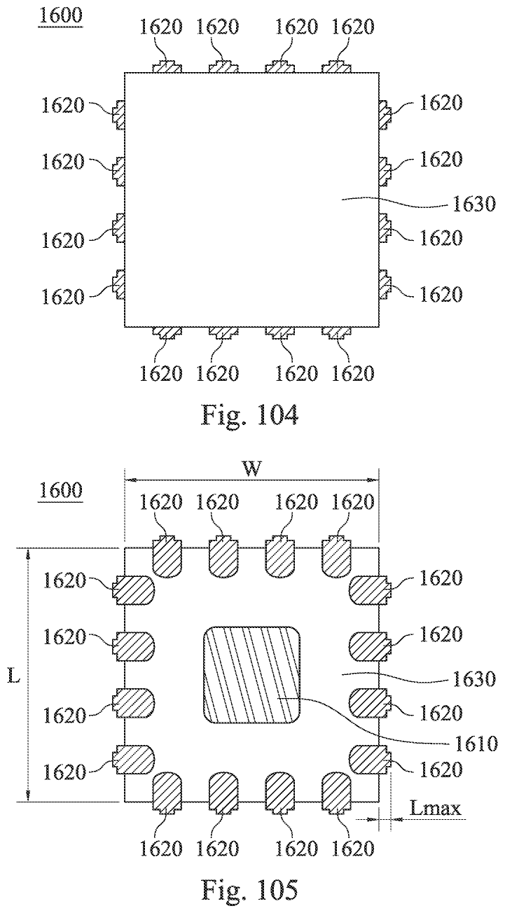

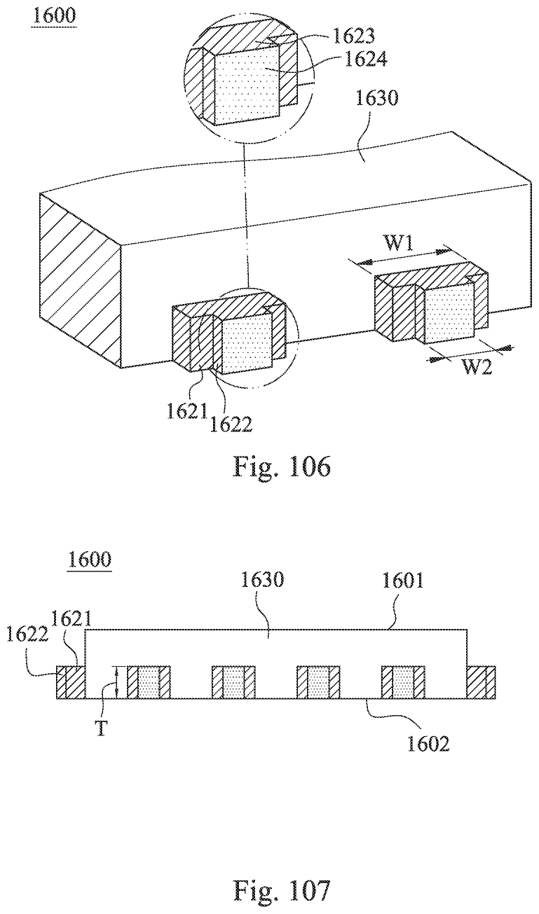

FIG. 104 is a top view of a package structure 1600 according to the 16th embodiment of the present disclosure. FIG. 105 is a bottom view of the package structure 1600 according to the 16th embodiment in FIG. 104. FIG. 106 is a partial schematic view of the package structure 1600 according to the 16th embodiment in FIG. 104. FIG. 107 is a side view of the package structure 1600 according to the 16th embodiment in FIG. 104. In FIGS. 104 to 107, the package structure 1600 has an upper surface 1601 and a lower surface 1602, and includes leadframe (its reference numeral is omitted), a semiconductor die (not shown) and a plastic package material 1630, wherein the leadframe is for carrying the semiconductor die, the plastic package material 1630 is disposed on the leadframe, and the semiconductor die is covered via the plastic package material 1630 to form the package structure 1600.

The leadframe includes a die pad 1610 and a plurality of leads 1620, wherein the semiconductor die is disposed on the die pad 1610 of the leadframe, the leads 1620 are disposed on four peripheral regions of the die pad 1610, and each of the leads 1620 includes a main body 1621, at least one extending portion 1622, a plurality of plating surfaces 1623 and at least one non-plating surface 1624.

The extending portion 1622 is connected to the main body 1621, and the main body 1621 and the extending portion 1622 are integrally formed, wherein the plating surfaces 1623 are disposed on the main body 1621 and the extending portion 1622, and the non-plating surface 1624 is disposed on the extending portion 1622. The main body 1621 and the extending portion 1622 of each of the leads 1620 protrude a peripheral region of the plastic package material 1630. Therefore, the leads 1620 which protrude an outer periphery of the plastic package material 1630 are favorable for enhancing the solderable area of sides of the package structure 1600. Moreover, the thermal cycle life of board level can be enhanced over 20% by the package structure 1600 compared with the package structure, of which the leads do not protrude the outer periphery of the plastic package material, of prior art.

According to the 16th embodiment, a number of the extending portion 1622 of each of the leads 1620 is one, a number of the plating surfaces 1623 of each of the leads 1620 is eight, a number of the non-plating surface 1624 of each of the leads 1620 is one, and each of the leads 1620 is a protruding lead.

According to the 16th embodiment, the package structure 1600 can be obtained by an etching step, a molding step, a laser step, a plating step and a singulation step, but the present disclosure is not limited thereto. In the etching step, a lower surface of the leadframe is etched. In the molding step, the plastic package material 1630 is disposed on and covers the semiconductor die. In the laser step, a portion of the plastic package material 1630 on an upper surface of the leadframe is removed via a laser beam. In the plating step, the plating surfaces 1623 are disposed on a surface of the leadframe without the plastic package material 1630 after the laser steps. In the singulation step, the package structure 1600 is formed. Moreover, a number of the laser steps can be more than two, and it depends on the energy and the parameters of the laser beam, but the aforementioned steps are not limited.

In FIG. 105, when a length of the package structure 1600 is L, a width of the package structure 1600 is W, and a maximum protruding length of each of the leads 1620 is Lmax, the following conditions are satisfied: W≤L; 0.01 W≤Lmax; and Lmax≤0.5 L. In particular, the plastic package material 1630 can be square or rectangle, and the maximum protruding length depends on the disposition of the circuit board, and is not limited thereto. Further, the maximum protruding lengths of the leads 1620 can be the same. Therefore, the solderable area of the leads 1620 at the sides of the package structure 1600 can be consistent. Moreover, the soldering difference is less easily generated when the package structure 1600 soldered on the circuit board (not shown), and the package structure 1600 can be firmly disposed on the circuit board.

In FIGS. 106 and 107, when a width of the main body 1621 is W1, a width of the extending portion 1622 is W2, and a thickness of each of the leads 1620 is T, the following condition is satisfied: 0.25 T≤W2<W1. Therefore, the structural stability of the leads 1620 can be maintained, and the condition of insufficient soldering on sides of the leads is not easily happened.

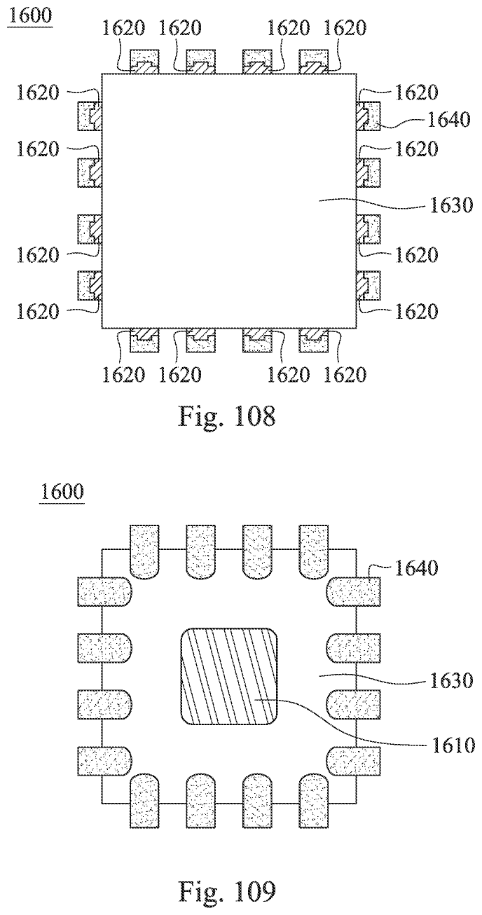

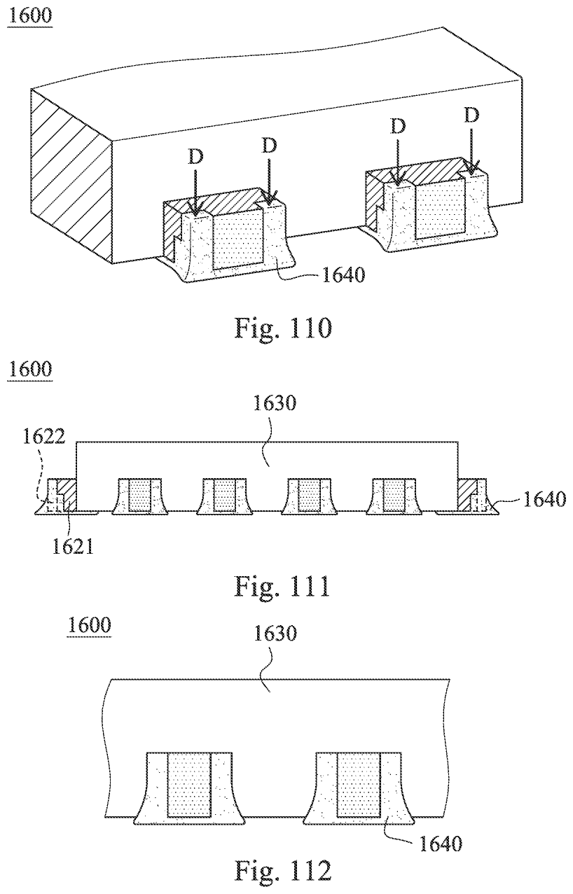

FIG. 108 is a top view of the package structure 1600 after soldering according to the 16th embodiment in FIG. 104. FIG. 109 is a bottom view of the package structure 1600 after soldering according to the 16th embodiment in FIG. 104. FIG. 110 is a partial side view of the package structure 1600 after soldering according to the 16th embodiment in FIG. 104. FIG. 111 is a side view of the package structure 1600 after soldering according to the 16th embodiment in FIG. 104. FIG. 112 is a partial side view of the package structure 1600 after soldering according to the 16th embodiment in FIG. 111. In FIGS. 108 to 112, soldering portions 1640 can be only disposed on the plating surfaces 1623, wherein the soldering portions 1640 are contacted with the main body 1621 and the extending portion 1622, which the plating surfaces 1623 are disposed on. Therefore, the solderable area of a bottom of the package structure 1600 can be maintained, and the solderable area of the sides of the package structure 1600 can be simultaneously enhanced, so that the soldering strength between the package structure 1600 and the circuit board can be enhanced.

In FIG. 110, the inspectors can check the soldering condition from a detecting direction D via an AOI after the soldering process of the package structure 1600. In particular, the detecting direction D is a direction from the upper surface 1601 to the lower surface 1602 of the package structure 1600, and the inspectors can directly check the soldering condition from a top-down perspective. By operating the AOI from the top-down perspective, the detecting efficiency can be enhanced.

Further, all of other structures and dispositions according to the 16th embodiment are the same as the structures and the dispositions according to the 14th embodiment, and will not be described again herein.

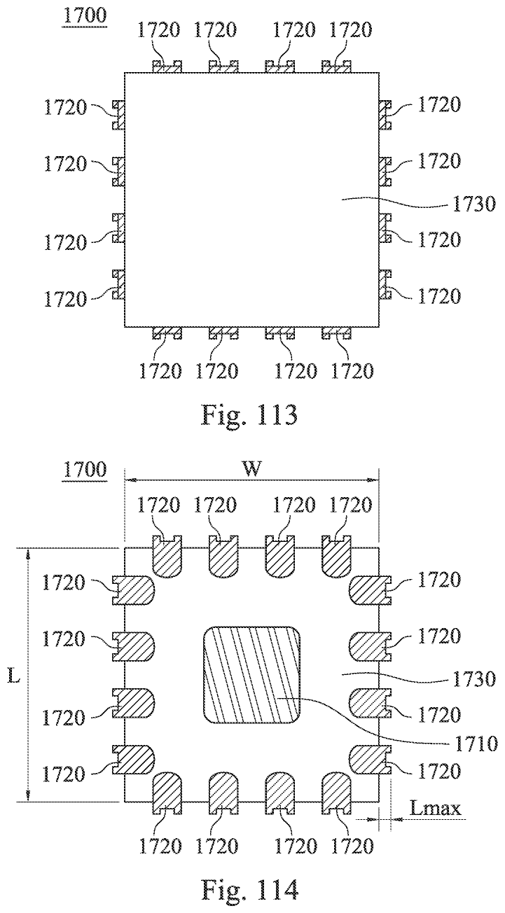

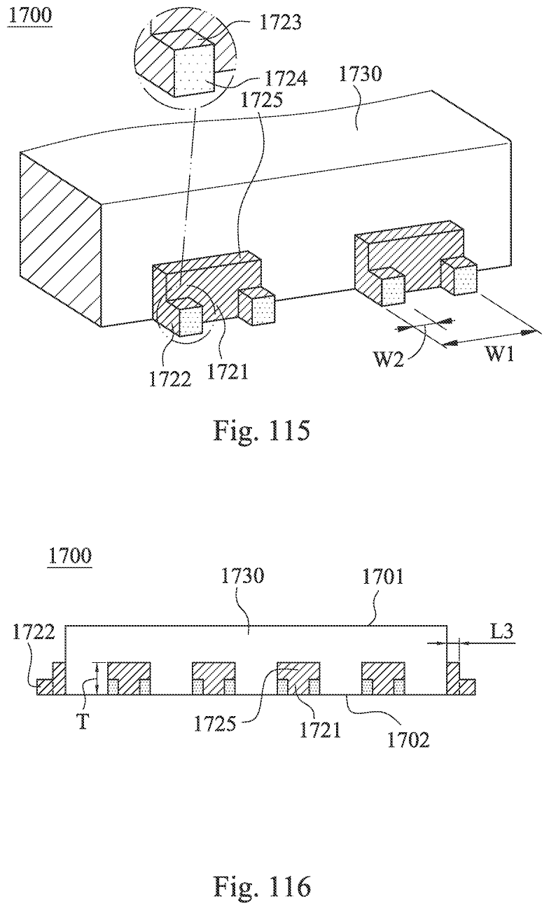

FIG. 113 is a top view of a package structure 1700 according to the 17th embodiment of the present disclosure. FIG. 114 is a bottom view of the package structure 1700 according to the 17th embodiment in FIG. 113. FIG. 115 is a partial schematic view of the package structure 1700 according to the 17th embodiment in FIG. 113. FIG. 116 is a side view of the package structure 1700 according to the 17th embodiment in FIG. 113. In FIGS. 113 to 116, the package structure 1700 has an upper surface 1701 and a lower surface 1702, and includes leadframe (its reference numeral is omitted), a semiconductor die (not shown) and a plastic package material 1730, wherein the leadframe is for carrying the semiconductor die, the plastic package material 1730 is disposed on the leadframe, and the semiconductor die is covered via the plastic package material 1730 to form the package structure 1700.

The leadframe includes a die pad 1710 and a plurality of leads 1720, wherein the semiconductor die is disposed on the die pad 1710 of the leadframe, the leads 1720 are disposed on four peripheral regions of the die pad 1710, and each of the leads 1720 includes a main body 1721, at least one extending portion 1722, a plurality of plating surfaces 1723, at least one non-plating surface 1724 and a protruding portion 1725.

The extending portion 1722 is connected to the main body 1721, the protruding portion 1725 is connected to the main body 1721, and the main body 1721, the extending portion 1722 and the protruding portion 1725 are integrally formed, wherein the plating surfaces 1723 are disposed on the main body 1721, the extending portion 1722 and the protruding portion 1725, and the non-plating surface 1724 is disposed on the extending portion 1722. The main body 1721, the extending portion 1722 and the protruding portion 1725 of each of the leads 1720 protrude a peripheral region of the plastic package material 1730, and the main body 1721 and the extending portion 1722 are closer to the lower surface 1702 of the package structure 1700 than the protruding portion 1725 to the lower surface 1702 of the package structure 1700. Therefore, the leads 1720 which protrude an outer periphery of the plastic package material 1730 are favorable for enhancing the solderable area of sides of the package structure 1700. Moreover, the thermal cycle life of board level can be enhanced over 20% by the package structure 1700 compared with the package structure, of which the leads do not protrude the outer periphery of the plastic package material, of prior art.

According to the 17th embodiment, a number of the extending portion 1722 of each of the leads 1720 is two, a number of the plating surfaces 1723 of each of the leads 1720 is nine, a number of the non-plating surface 1724 of each of the leads 1720 is two, and each of the leads 1720 is a step-shaped lead.

According to the 17th embodiment, the package structure 1700 can be obtained by an etching step, a molding step, a laser step, a plating step and a singulation step, but the present disclosure is not limited thereto. In the etching step, an upper surface of the leadframe is etched. In the molding step, the plastic package material 1730 is disposed on and covers the semiconductor die. In the laser step, a portion of the plastic package material 1730 on the upper surface of the leadframe is removed via a laser beam. In the plating step, the plating surfaces 1723 are disposed on a surface of the leadframe without the plastic package material 1730 after the laser steps. In the singulation step, the package structure 1700 is formed. Moreover, a number of the laser steps can be more than two, and it depends on the energy and the parameters of the laser beam, but the aforementioned steps are not limited.

In FIG. 114, when a length of the package structure 1700 is L, a width of the package structure 1700 is W, and a maximum protruding length of each of the leads 1720 is Lmax, the following conditions are satisfied: W≤L; 0.01 W≤Lmax; and Lmax≤0.5 L. In particular, the plastic package material 1730 can be square or rectangle, and the maximum protruding length depends on the disposition of the circuit board, and is not limited thereto. Further, the maximum protruding lengths of the leads 1720 can be the same. Therefore, the solderable area of the leads 1720 at the sides of the package structure 1700 can be consistent. Moreover, the soldering difference is less easily generated when the package structure 1700 soldered on the circuit board (not shown), and the package structure 1700 can be firmly disposed on the circuit board.

In FIGS. 114 to 116, when the length of the package structure 1700 is L, an extending length of the protruding portion 1725 is L3, a width of the main body 1721 is W1, a width of each of the extending portions 1722 is W2, and a thickness of each of the leads 1720 is T, the following conditions are satisfied: 0<L3≤0.5 L; and 0.25 T≤W2<W1. Therefore, the structural stability of the leads 1720 can be maintained, and the condition of insufficient soldering on sides of the leads is not easily happened so as to enhance the reliability.

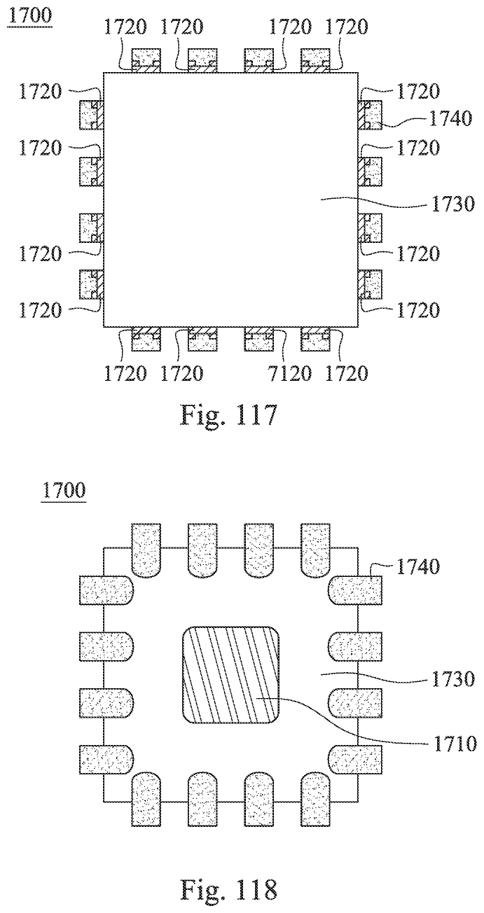

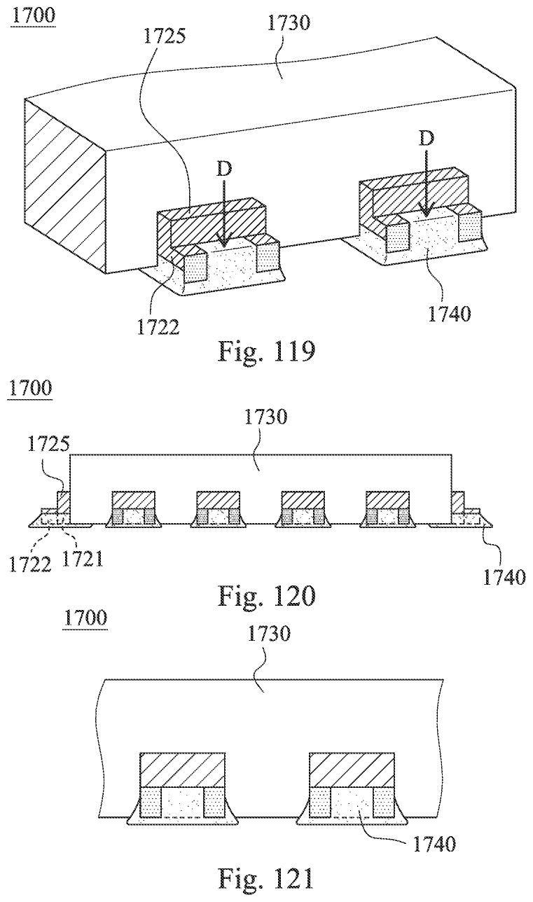

FIG. 117 is a top view of the package structure 1700 after soldering according to the 17th embodiment in FIG. 113. FIG. 118 is a bottom view of the package structure 1700 after soldering according to the 17th embodiment in FIG. 113. FIG. 119 is a partial side view of the package structure 1700 after soldering according to the 17th embodiment in FIG. 113. FIG. 120 is a side view of the package structure 1700 after soldering according to the 17th embodiment in FIG. 113. FIG. 121 is a partial side view of the package structure 1700 after soldering according to the 17th embodiment in FIG. 120. In FIGS. 117 to 121, soldering portions 1740 can be only disposed on the plating surfaces 1723, wherein the soldering portions 1740 are contacted with the main body 1721, the extending portions 1722 and the protruding portion 1725, which the plating surfaces 1723 are disposed on. Therefore, the solderable area of a bottom of the package structure 1700 can be maintained, and the solderable area of the sides of the package structure 1700 can be simultaneously enhanced, so that the soldering strength between the package structure 1700 and the circuit board can be enhanced.

In FIG. 119, the inspectors can check the soldering condition from a detecting direction D via an AOI after the soldering process of the package structure 1700. In particular, the detecting direction D is a direction from the upper surface 1701 to the lower surface 1702 of the package structure 1700, and the inspectors can directly check the soldering condition from a top-down perspective. By operating the AOI from the top-down perspective, the detecting efficiency can be enhanced.

Further, all of other structures and dispositions according to the 17th embodiment are the same as the structures and the dispositions according to the 14th embodiment, and will not be described again herein.

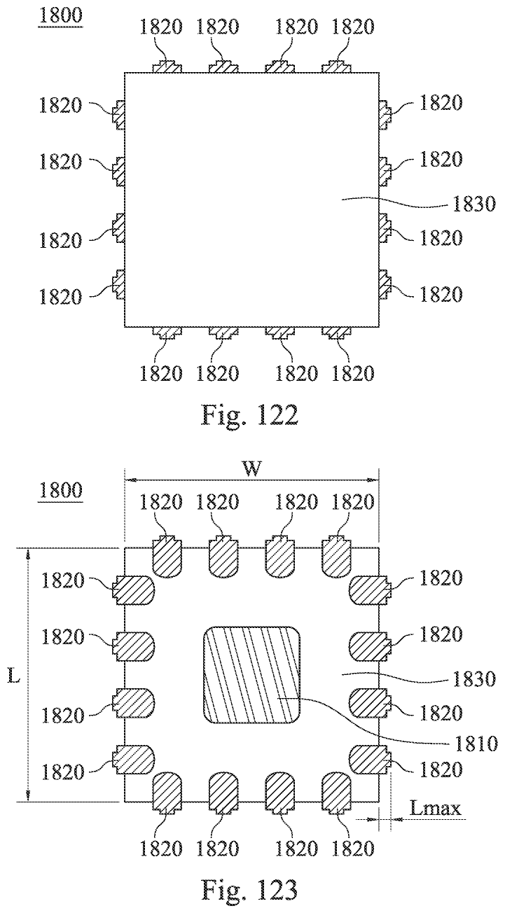

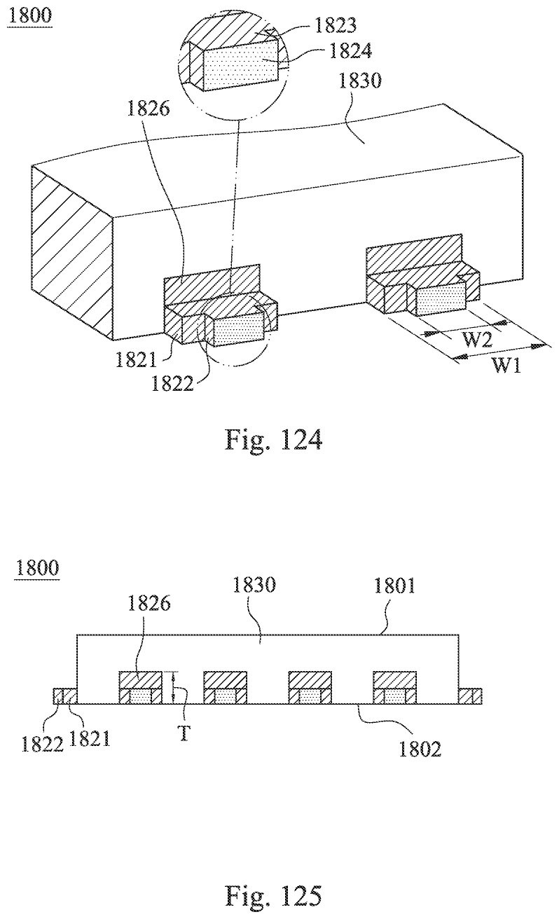

FIG. 122 is a top view of a package structure 1800 according to the 18th embodiment of the present disclosure. FIG. 123 is a bottom view of the package structure 1800 according to the 18th embodiment in FIG. 122. FIG. 124 is a partial schematic view of the package structure 1800 according to the 18th embodiment in FIG. 122. FIG. 125 is a side view of the package structure 1800 according to the 18th embodiment in FIG. 122. In FIGS. 122 to 125, the package structure 1800 has an upper surface 1801 and a lower surface 1802, and includes leadframe (its reference numeral is omitted), a semiconductor die (not shown) and a plastic package material 1830, wherein the leadframe is for carrying the semiconductor die, the plastic package material 1830 is disposed on the leadframe, and the semiconductor die is covered via the plastic package material 1830 to form the package structure 1800.

The leadframe includes a die pad 1810 and a plurality of leads 1820, wherein the semiconductor die is disposed on the die pad 1810 of the leadframe, the leads 1820 are disposed on four peripheral regions of the die pad 1810, and each of the leads 1820 includes a main body 1821, at least one extending portion 1822, a plurality of plating surfaces 1823, at least one non-plating surface 1824 and a plane portion 1826.

The extending portion 1822 is connected to the main body 1821, the plane portion 1826 is connected to the main body 1821, and the main body 1821, the extending portion 1822 and the plane portion 1826 are integrally formed, wherein the plating surfaces 1823 are disposed on the main body 1821, the extending portion 1822 and the plane portion 1826, and the non-plating surface 1824 is disposed on the extending portion 1822. The main body 1821 and the extending portion 1822 of each of the leads 1820 protrude a peripheral region of the plastic package material 1830, and the main body 1821 and the extending portion 1822 are closer to the lower surface 1802 of the package structure 1800 than the plane portion 1826 to the lower surface 1802 of the package structure 1800. Therefore, the leads 1820 which protrude an outer periphery of the plastic package material 1830 are favorable for enhancing the solderable area of sides of the package structure 1800. Moreover, the thermal cycle life of board level can be enhanced over 20% by the package structure 1800 compared with the package structure, of which the leads do not protrude the outer periphery of the plastic package material, of prior art.

According to the 18th embodiment, a number of the extending portion 1822 of each of the leads 1820 is one, a number of the plating surfaces 1823 of each of the leads 1820 is nine, a number of the non-plating surface 1824 of each of the leads 1820 is one, and each of the leads 1820 is a step-shaped lead.

According to the 18th embodiment, the package structure 1800 can be obtained by an etching step, a molding step, a laser step, a plating step and a singulation step, but the present disclosure is not limited thereto. In the etching step, an upper surface of the leadframe is etched. In the molding step, the plastic package material 1830 is disposed on and covers the semiconductor die. In the laser step, a portion of the plastic package material 1830 on the upper surface of the leadframe is removed via a laser beam. In the plating step, the plating surfaces 1823 are disposed on a surface of the leadframe without the plastic package material 1830 after the laser steps. In the singulation step, the package structure 1800 is formed. Moreover, a number of the laser steps can be more than two, and it depends on the energy and the parameters of the laser beam, but the aforementioned steps are not limited.

In FIG. 123, when a length of the package structure 1800 is L, a width of the package structure 1800 is W, and a maximum protruding length of each of the leads 1820 is Lmax, the following conditions are satisfied: W≤L; 0.01 W≤Lmax; and Lmax≤0.5 L. In particular, the plastic package material 1830 can be square or rectangle, and the maximum protruding length depends on the disposition of the circuit board, and is not limited thereto. Further, the maximum protruding lengths of the leads 1820 can be the same. Therefore, the solderable area of the leads 1820 at the sides of the package structure 1800 can be consistent. Moreover, the soldering difference is less easily generated when the package structure 1800 soldered on the circuit board (not shown), and the package structure 1800 can be firmly disposed on the circuit board.

In FIGS. 124 and 125, when a width of the main body 1821 is W1, a width of the extending portion 1822 is W2, and a thickness of each of the leads 1820 is T, the following condition is satisfied: 0.25 T≤W2<W1. Therefore, the structural stability of the leads 1820 can be maintained, and the condition of insufficient soldering on sides of the leads is not easily happened.

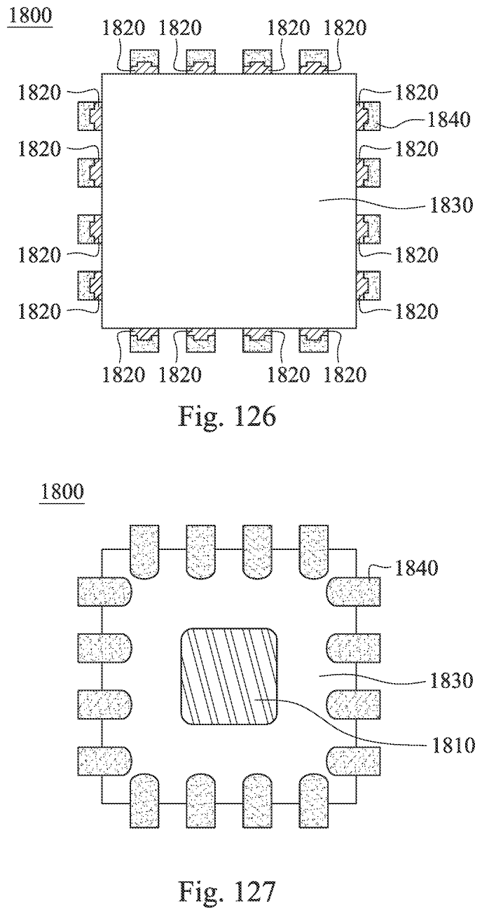

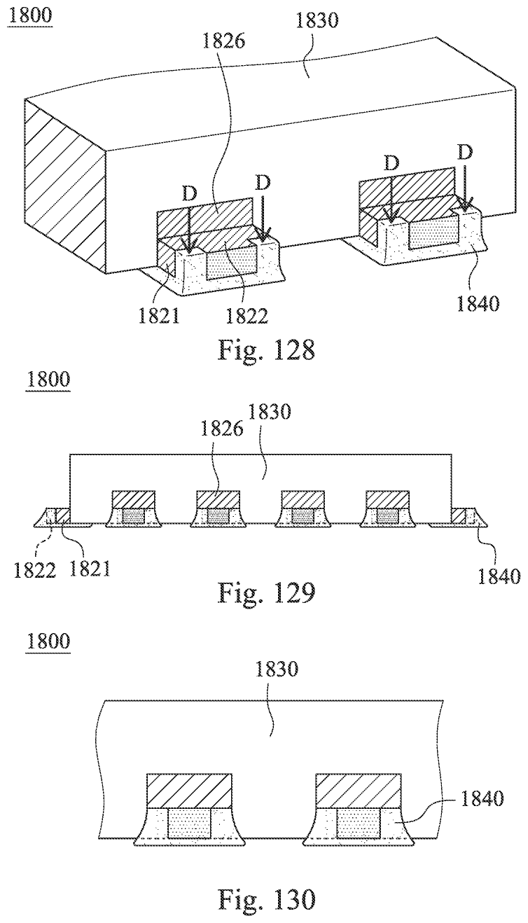

FIG. 126 is a top view of the package structure 1800 after soldering according to the 18th embodiment in FIG. 122. FIG. 127 is a bottom view of the package structure 1800 after soldering according to the 18th embodiment in FIG. 122. FIG. 128 is a partial side view of the package structure 1800 after soldering according to the 18th embodiment in FIG. 122. FIG. 129 is a side view of the package structure 1800 after soldering according to the 18th embodiment in FIG. 122. FIG. 130 is a partial side view of the package structure 1800 after soldering according to the 18th embodiment in FIG. 129. In FIGS. 126 to 130, soldering portions 1840 can be only disposed on the plating surfaces 1823, wherein the soldering portions 1840 are contacted with the main body 1821, the extending portion 1822 and the plane portion 1826, which the plating surfaces 1823 are disposed on. Therefore, the solderable area of a bottom of the package structure 1800 can be maintained, and the solderable area of the sides of the package structure 1800 can be simultaneously enhanced, so that the soldering strength between the package structure 1800 and the circuit board can be enhanced.

In FIG. 128, the inspectors can check the soldering condition from a detecting direction D via an AOI after the soldering process of the package structure 1800. In particular, the detecting direction D is a direction from the upper surface 1801 to the lower surface 1802 of the package structure 1800, and the inspectors can directly check the soldering condition from a top-down perspective. By operating the AOI from the top-down perspective, the detecting efficiency can be enhanced.

Further, all of other structures and dispositions according to the 18th embodiment are the same as the structures and the dispositions according to the 14th embodiment, and will not be described again herein.

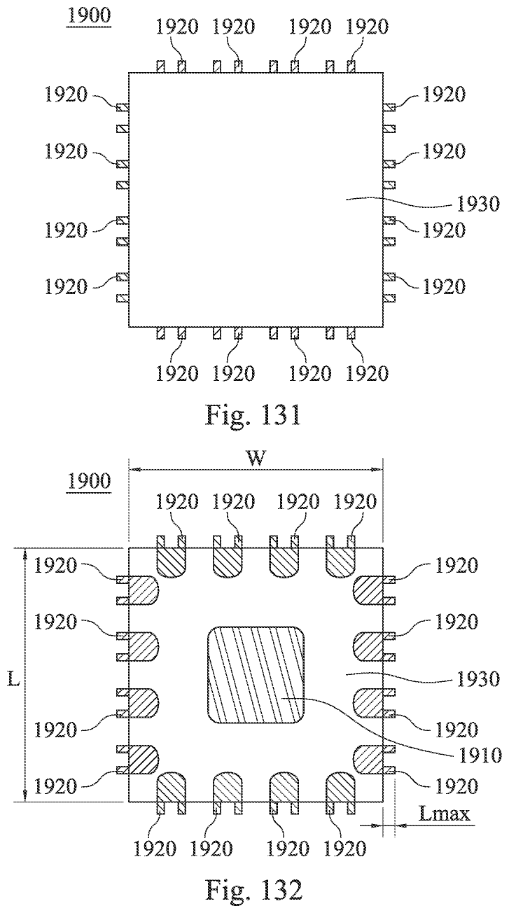

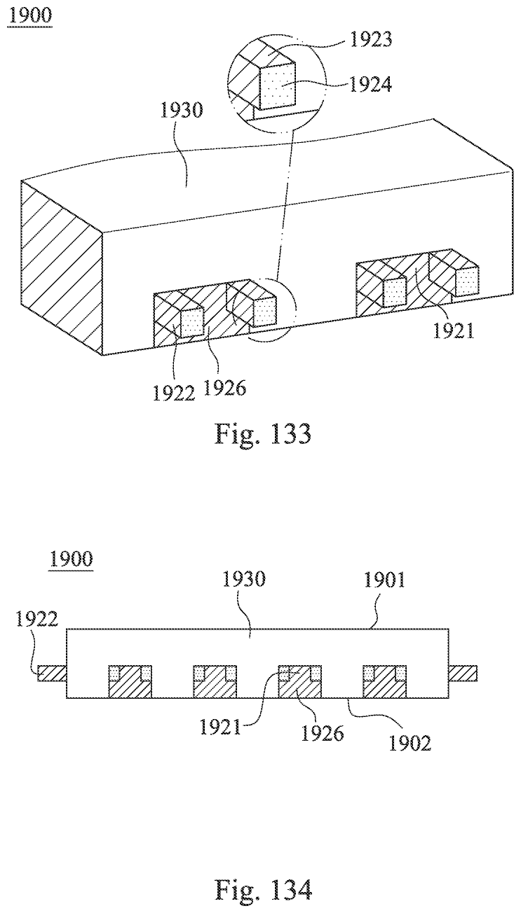

FIG. 131 is a top view of a package structure 1900 according to the 19th embodiment of the present disclosure. FIG. 132 is a bottom view of the package structure 1900 according to the 19th embodiment in FIG. 131. FIG. 133 is a partial schematic view of the package structure 1900 according to the 19th embodiment in FIG. 131. FIG. 134 is a side view of the package structure 1900 according to the 19th embodiment in FIG. 131. In FIGS. 131 to 134, the package structure 1900 has an upper surface 1901 and a lower surface 1902, and includes leadframe (its reference numeral is omitted), a semiconductor die (not shown) and a plastic package material 1930, wherein the leadframe is for carrying the semiconductor die, the plastic package material 1930 is disposed on the leadframe, and the semiconductor die is covered via the plastic package material 1930 to form the package structure 1900.

The leadframe includes a die pad 1910 and a plurality of leads 1920, wherein the semiconductor die is disposed on the die pad 1910 of the leadframe, the leads 1920 are disposed on four peripheral regions of the die pad 1910, and each of the leads 1920 includes a main body 1921, at least one extending portion 1922, a plurality of plating surfaces 1923, at least one non-plating surface 1924 and a plane portion 1926.

The extending portion 1922 is connected to the main body 1921, the plane portion 1926 is connected to the main body 1921, and the main body 1921, the extending portion 1922 and the plane portion 1926 are integrally formed, wherein the plating surfaces 1923 are disposed on the main body 1921, the extending portion 1922 and the plane portion 1926, and the non-plating surface 1924 is disposed on the extending portion 1922. The main body 1921 of each of the leads 1920 is aligned to a peripheral region of the plastic package material 1930, the extending portion 1922 of each of the leads 1920 protrudes the peripheral region of the plastic package material 1930, and the main body 1921 and the extending portion 1922 are farther from the lower surface 1902 of the package structure 1900 than the plane portion 1926 from the lower surface 1902 of the package structure 1900. Therefore, the leads 1920 which protrude an outer periphery of the plastic package material 1930 are favorable for enhancing the solderable area of sides of the package structure 1900. Moreover, the thermal cycle life of board level can be enhanced over 20% by the package structure 1900 compared with the package structure, of which the leads do not protrude the outer periphery of the plastic package material, of prior art. It should be mentioned that the condition that the main body 1921 is aligned to the peripheral region of the plastic package material 1930 means that the main body 1921 does not protrude the outer periphery of the plastic package material 1930.

According to the 19th embodiment, a number of the extending portion 1922 of each of the leads 1920 is two, a number of the plating surfaces 1923 of each of the leads 1920 is ten, a number of the non-plating surface 1924 of each of the leads 1920 is two, and each of the leads 1920 is a protruding lead.

According to the 19th embodiment, the package structure 1900 can be obtained by an etching step, a molding step, a laser step, a plating step and a singulation step, but the present disclosure is not limited thereto. In the etching step, a lower surface of the leadframe is etched. In the molding step, the plastic package material 1930 is disposed on and covers the semiconductor die. In the laser step, a portion of the plastic package material 1930 on an upper surface and the lower surface of the leadframe is removed via a laser beam. In the plating step, the plating surfaces 1923 are disposed on a surface of the leadframe without the plastic package material 1930 after the laser steps. In the singulation step, the package structure 1900 is formed. Moreover, a number of the laser steps can be more than two, and it depends on the energy and the parameters of the laser beam, but the aforementioned steps are not limited.

In FIG. 132, when a length of the package structure 1900 is L, a width of the package structure 1900 is W, and a maximum protruding length of each of the leads 1920 is Lmax, the following conditions are satisfied: W≤L; 0.01 W≤Lmax; and Lmax≤0.5 L. In particular, the plastic package material 1930 can be square or rectangle, and the maximum protruding length depends on the disposition of the circuit board, and is not limited thereto. Further, the maximum protruding lengths of the leads 1920 can be the same. Therefore, the solderable area of the leads 1920 at the sides of the package structure 1900 can be consistent. Moreover, the soldering difference is less easily generated when the package structure 1900 soldered on the circuit board (not shown), and the package structure 1900 can be firmly disposed on the circuit board.

Moreover, the portion of each of the leads 1920 close to the lower surface 1902 of the package structure 1900 does not protrude an edge of the plastic package material 1930. Therefore, according to the 19th embodiment, the POD does not need to be changed, and the process of redrawing the POD can be reduced.

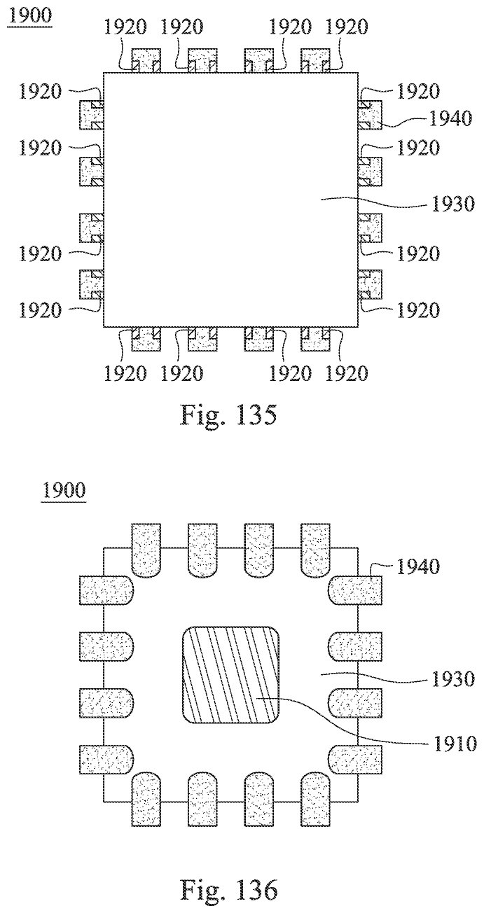

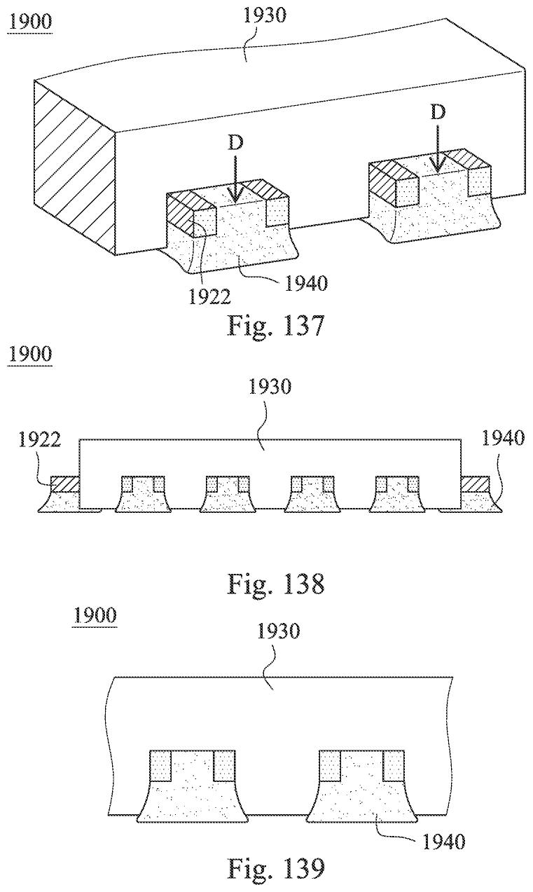

FIG. 135 is a top view of the package structure 1900 after soldering according to the 19th embodiment in FIG. 131. FIG. 136 is a bottom view of the package structure 1900 after soldering according to the 19th embodiment in FIG. 131. FIG. 137 is a partial side view of the package structure 1900 after soldering according to the 19th embodiment in FIG. 131. FIG. 138 is a side view of the package structure 1900 after soldering according to the 19th embodiment in FIG. 131. FIG. 139 is a partial side view of the package structure 1900 after soldering according to the 19th embodiment in FIG. 138. In FIGS. 135 to 139, soldering portions 1940 can be only disposed on the plating surfaces 1923, wherein the soldering portions 1940 are contacted with the main body 1921, the extending portions 1922 and the plane portion 1926, which the plating surfaces 1923 are disposed on. Therefore, the solderable area of a bottom of the package structure 1900 can be maintained, and the solderable area of the sides of the package structure 1900 can be simultaneously enhanced, so that the soldering strength between the package structure 1900 and the circuit board can be enhanced.

In FIG. 137, the inspectors can check the soldering condition from a detecting direction D via an AOI after the soldering process of the package structure 1900. In particular, the detecting direction D is a direction from the upper surface 1901 to the lower surface 1902 of the package structure 1900, and the inspectors can directly check the soldering condition from a top-down perspective. By operating the AOI from the top-down perspective, the detecting efficiency can be enhanced.

Further, all of other structures and dispositions according to the 19th embodiment are the same as the structures and the dispositions according to the 14th embodiment, and will not be described again herein.

In summary, according to the 14th to 19th embodiments, it is further favorable for enhancing the solderable area on the bottom via the package structure of the present disclosure, and the solderable area of the sides of the package structure can be simultaneously enhanced, so that the soldering strength between the package structure and the circuit board can be enhanced. Further, the package structure can be firmly disposed on the circuit board after soldering so as to enhance the thermal cycle life of board level. Moreover, the detecting efficiency can be enhanced during the detecting process after the soldering process.

The foregoing description, for purpose of explanation, has been described with reference to specific examples. It is to be noted that Tables show different data of the different examples; however, the data of the different examples are obtained from experiments. The examples were chosen and described in order to best explain the principles of the disclosure and its practical applications, to thereby enable others skilled in the art to best utilize the disclosure and various examples with various modifications as are suited to the particular use contemplated. The examples depicted above and the appended drawings are exemplary and are not intended to be exhaustive or to limit the scope of the present disclosure to the precise forms disclosed. Many modifications and variations are possible in view of the above teachings.

What is claimed is:

1. A package structure, comprising:
a leadframe, comprising:
a die pad; and
a plurality of leads disposed on four peripheral regions of the die pad, and each of the leads comprising:
a main body;
at least one extending portion connected to the main body,
and the main body and the at least one extending portion integrally formed; and
a plurality of plating surfaces disposed on the main body and the at least one extending portion;
a semiconductor die disposed on the die pad of the leadframe; and
a plastic package material disposed on the leadframe;
wherein the main body and the at least one extending portion of each of the leads protrude a peripheral region of the plastic package material.

2. The package structure of claim 1, wherein each of the leads further comprises at least one non-plating surface, and the at least one non-plating surface is disposed on the at least one extending portion.

3. The package structure of claim 1, wherein a length of the package structure is L, a width of the package structure is W, a maximum protruding length of each of the leads is Lmax, and the following conditions are satisfied:
W≤L;
0.01W≤L max; and
L max≤0.5L.

4. The package structure of claim 1, wherein a width of the main body is W1, a width of the at least one extending portion is W2, a thickness of each of the leads is T, and the following condition is satisfied:
0.25T≤W2<W1.

5. The package structure of claim 1, wherein a number of the plating surfaces is at least eight.

6. The package structure of claim 1, wherein each of the leads further comprises a protruding portion connected to the main body, the main body, the at least one extending portion and the protruding portion are integrally formed, and the plating surfaces are disposed on the protruding portion.

7. The package structure of claim 6, wherein the main body and the at least one extending portion are farther from a lower surface of the package structure than the protruding portion from the lower surface of the package structure.

8. The package structure of claim 7, wherein an extending length of the main body is L1, an extending length of the at least one extending portion is L2, a maximum protruding length of each of the leads is Lmax, a length of the package structure is L, and the following conditions are satisfied:
0<L2≤0.5L; and
0<L max=L1+L2.

9. The package structure of claim 6, wherein a length of the package structure is L, an extending length of the protruding portion is L3, and the following condition is satisfied:
0<L3≤0.5L.

10. The package structure of claim 6, wherein the main body and the at least one extending portion are closer to a lower surface of the package structure than the protruding portion to the lower surface of the package structure.

11. The package structure of claim 1, wherein each of the leads further comprises a plane portion connected to the main body, the main body, the at least one extending portion and the plane portion are integrally formed, and the plating surfaces are disposed on the plane portion.

12. The package structure of claim 11, wherein the main body and the at least one extending portion are farther from a lower surface of the package structure than the plane portion from the lower surface of the package structure.

13. The package structure of claim 12, wherein an extending length of the main body is L1, an extending length of the at least one extending portion is L2, a maximum protruding length of each of the leads is Lmax, a length of the package structure is L, and the following conditions are satisfied:
0<L2≤0.5L; and
0<L max=L1+L2.

14. The package structure of claim 11, wherein the main body and the at least one extending portion are closer to a lower surface of the package structure than the plane portion to the lower surface of the package structure.

15. A package structure, comprising:
a leadframe, comprising:
a die pad; and
a plurality of leads disposed on four peripheral regions of the die pad, and each of the leads comprising:
a main body;
at least one extending portion connected to the main body, and the main body and the at least one extending portion integrally formed; and
a plurality of plating surfaces disposed on the main body
and the at least one extending portion;
a semiconductor die disposed on the die pad of the leadframe; and
a plastic package material disposed on the leadframe;
wherein the main body of each of the leads is aligned to a peripheral region of the plastic package material, and the at least one extending portion of each of the leads protrudes the peripheral region of the plastic package material.

16. The package structure of claim 15, wherein each of the leads further comprises a plane portion connected to the main body, the main body, the at least one extending portion and the plane portion are integrally formed, and the plating surfaces are disposed on the plane portion.

17. The package structure of claim 15, wherein a length of the package structure is L, a width of the package structure is W, a maximum protruding length of each of the leads is Lmax, and the following conditions are satisfied:
W≤L;
0.01W≤L max; and
L max≤0.5L.
